(19) United States
(12) Patent Application Publication
(10) Pub. No.: US 2007/0072096 A1
(43) Pub. Date: Mar. 29, 2007

(54) Negative curable dye-containing composition, color filter, and method of manufacturing the same

(75) Inventors: Hideki Takakuwa, Shizuoka-ken (JP); Katsumi Araki, Shizuoka-ken (JP); Nobuo Seto, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/528,571

(22) Filed: Sep. 28, 2006

(30) Foreign Application Priority Data
Sep. 29, 2005 (JP) 2005-285434

(51) Int. Cl. G02B 5/20; G03F 7/00

(52) U.S. Cl. 430/7; 430/270.1

(57) ABSTRACT

The invention provides a negative curable dye-containing composition including at least one compound selected from amine and pyridine compounds, a phthalocyanine dye soluble in an organic solvent, a photopolymerization initiator, and a radical polymerizable monomer, a color filter formed by using the same, and a manufacturing method of the color filter.

### CROSS-REFERENCE TO RELATED APPLICATION

This application claims priority under 35 U.S.C. 119 from Japanese Patent Application No. 2005-285434, the disclosure of which is incorporated by reference herein.

### BACKGROUND OF THE INVENTION

1. Field of the Invention

The present invention relates to a negative curable dye-containing composition that is preferably used to form the colored image of a color filter used in a liquid crystal display device (LCD), a solid-state imaging device (for example, CCD, or CMOS), and other devices, a color filter produced by using the negative curable dye-containing composition, and a method of manufacturing the same.

2. Description of the Related Art

Examples of methods of fabricating a color filter used in a liquid crystal display device and a solid-state imaging device includes a dyeing method, a printing method, an electrodeposition method, and a pigment dispersion method.

In the pigment dispersion method, a color filter is produced by photolithography using a colored radiation-sensitive composition in which a pigment is dispersed in a photosensitive composition. Because a pigment is used in this method, a color filter produced by this method is stable optically and thermally. In addition, since patterning is conducted by photolithography, the pigment dispersion method has been widely employed to manufacture a color filter for a color display device having high positional precision, a large screen and high definition.

To manufacture a color filter by the pigment dispersion method, a radiation-sensitive composition is applied to a glass substrate with a spin coater or a roll coater, and dried to form a coating film, and the coating film is pattern-wise exposed to light and developed so as to form colored pixels. These operations are conducted for each color, and a color filter is obtained.

In the pigment dispersion method, for example, a negative photosensitive composition including an alkaline-soluble binder, a photopolymerizable monomer and a photopolymerization initiator is used.

Recently, higher definition has been required for color filters for solid-state imaging devices. However, it is hard to obtain color filters for solid-state imaging devices having improved resolution by using a conventional pigment dispersion method. This is because color unevenness may occur due to coarse pigment particles contained in the composition. Thus, the pigment dispersion method is not suitable for application for which a fine pattern is required, such as solid-state imaging devices.

Under such circumstances, it has been proposed to use a dye instead of a pigment (see, for example, Japanese Patent Application Laid-Open (JP-A) No. H06-75375). However, a curable dye-containing composition generally has inferior light fastness to that of a curable pigment-containing composition. Further, unlike color filters for liquid crystal display devices, color filters for solid-state imaging devices is required to have a film thickness of 1.5 μm or less. In order to attain this, it is necessary that the curable composition include a large amount of a dye. This results in insufficient adhesion between the resultant coating film and a substrate, causing the coating film to easily peel off in a developing process. To solve such a problem, it has been proposed to add an amine compound to a radical polymerizable negative curable composition (see, for example, JP-A No. 2004-139050).

Alternatively, it has been proposed to add an amine compound or a pyridine compound to a positive photosensitive resin composition. This can suppress drop of sensitivity of the composition (see, for example, JP-A No. 2002-196481).

Meanwhile, serious problems of thickening and gelation of negative curable compositions containing large amounts of a phthalocyanine dye compound and a radical polymerizable monomer over time have recently arised.

There is hence a need for a negative curable composition containing, as an organic solvent-soluble dye, a phthalocyanine dye and a large amount of a radical polymerizable monomer, but having suppressed gelation over time, and a color filter using the same, and a method of manufacturing the same.

There is also a need for a color filter obtained by using a negative curable dye-containing composition a dye, and having high transmittance, a broad development latitude, high resolution, and excellent light fastness, and a method of manufacturing a color filter having excellent resolution and heat resistance with high cost performance.

### SUMMARY OF THE INVENTION

Under such circumetances, the invention has been devised.

A first aspect of the invention provides a negative curable dye-containing composition including at least one compound selected from amine and pyridine compounds, a phthalocyanine dye soluble in an organic solvent, a photopolymerization initiator, and a radical polymerizable monomer.

A second aspect of the invention provides a color filter obtained by using the negative curable dye-containing composition.

A third aspect of the invention provides a method of manufacturing a color filter including: applying the negative curable dye-containing composition onto a support to form a coating, exposing the coating to light through a mask, and developing the coating to form a pattern.

### DETAILED DESCRIPTION OF THE INVENTION

The negative curable dye-containing composition of the invention, the color filter obtained by using the negative curable cye-containing composition, and the method of manufacturing the color filter will be described in detail below.

<<Negative Curable Dye-Containing Composition>>

The negative curable dye-containing composition of the invention contains at least one compound selected from amine and pyridine compounds, at least one phthalocyanine dye soluble in an organic solvent, at least one photopolymerization initiator, and at least one radical polymerizable monomer, and generally contains at least one solvent, and may further contain other component(s) such as at least one alkaline-soluble binder, and at least one cross-linking agent.

Each of these components will be specifically described below.

<At Least One Compound Selected from Amine and Pyridine Compounds>

The negative curable dye-containing composition of the invention contains at least one compound selected from amine and pyridine compounds, which may be called the amine compound in the invention and the pyridine compound in the invention hereinafter.

The amine compound in the invention is, for example, a compound represented by the following Formula (III).

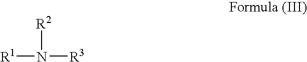

In Formula (III), R¹, R² and R³ independently represent a hydrogen atom, an alkyl group having 1 to 21 carbon atoms, an alkenyl group having 2 to 21 carbon atoms, an aryl group having 6 to 21 carbon atoms, or an aralkyl group having 7 to 21 carbon atoms, and these may have at least one substituent or may not have a substituent. R¹, R² and R³ may be bonded to each other via a carbon atom, a nitrogen atom, an oxygen atom, or a sulfur atom to form a single ring or a bicyclo ring.

The alkyl group having 1 to 21 carbon atoms and represented by R¹, R² or R³ may have at least one substituent or may not have a substituent, and preferably has 1 to 15 carbon atoms, and more preferably has 1 to 10 carbon atoms.

The alkyl group having 1 to 21 carbon atoms represented by R¹, R² or R³ may be linear, branched or cyclic. Examples thereof include a methyl group, an ethyl group, a n-propyl group, a n-butyl group, a n-amyl group, a n-hexyl group, a n-heptyl group, a n-octyl group, a n-nonyl group, a n-decyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a n-eicosanyl group, an iso-propyl group, a sec-butyl group, an iso-butyl group, a t-butyl group, a 1-methylbutyl group, a 1-ethylpropyl group, a 2-methylbutyl group, an iso-amyl group, a neopentyl group, a 1,2-dimethylpropyl group, a 1,1-dimethylpropyl group, a t-amyl group, a 1,3-dimethylbutyl group, a 3,3-dimethylbutyl group, a 2-ethylbutyl group, a 2-ethyl-2-methylpropyl group, linear and branched heptyl groups, a 1-methylheptyl group, a 2-ethylhexyl group, a 1,5-dimethylhexyl group, a t-octyl group, a branched nonyl group, a branched decyl group, a branched undecyl group, a branched dodecyl group, a branched tridecyl group, a branched tetradecyl group, a branched pentadecyl group, a branched hexadecyl group, a branched heptadecyl group, a branched octadecyl group, linear and branched nonadecyl groups, linear and branched eicosanyl groups, a cyclopropyl group, a cyclopropylmethyl group, a cyclobutyl group, a cyclobutylmethyl group, a cyclopentyl group, a cyclohexyl group, a cyclohexylmethyl group, a cycloheptyl group, a cyclooctyl group, a cyclohexylpropyl group, a cyclododecyl group, a norbornyl group, a bornyl group, a cis-miltanyl group, an isopinocamphenyl group, a noradamantyl group, an adamantyl group, an adamantylmethyl group, a 1-(1-adamantyl)ethyl group, a 3,5-dimethyladamantyl group, a quinuclidinyl group, a cyclopentylethyl group, and a bicyclooctyl group.

The alkyl group having 1 to 21 carbon atoms and represented by R¹, R² or R³ is preferably a methyl group, an ethyl group, a n-propyl group, a n-butyl group, a n-amyl group, a n-hexyl group, a n-heptyl group, a n-octyl group, a n-nonyl group, a n-decyl group, a n-undecyl group, a n-dodecyl group, a n-tridecyl group, a n-tetradecyl group, an iso-propyl group, a sec-butyl group, an iso-butyl group, a t-butyl group, a 1-methylbutyl group, a 1-ethylpropyl group, a 2-methylbutyl group, an iso-amyl group, a neopentyl group, a 1,2-dimethylpropyl group, a 1,1-dimethylpropyl group, a t-amyl group, a 1,3-dimethylbutyl group, a 3,3-dimethylbutyl group, a 2-ethylbutyl group, a 2-ethyl-2-methylpropyl group, a linear or branched heptyl group, a 1-methylheptyl group, a 2-ethylhexyl group, a 1,5-dimethylhexyl group, a t-octyl group, a branched nonyl group, a branched decyl group, a branched undecyl group, a branched dodecyl group, a branched tridecyl group, a branched tetradecyl group, a cyclopropyl group, a cyclopropylmethyl group, a cyclobutyl group, a cyclobutylmethyl group, a cyclopentyl group, a cyclohexyl group, a cyclohexylmethyl group, cycloheptyl group, a cyclooctyl group, a cyclohexylpropyl group, a cyclododecyl group, a norbornyl group, a bornyl group, a cis-miltanyl group, an isopinocamphenyl group, a noradamantyl group, an adamantyl group, an adamantylmethyl group, a 1-(1-adamantyl)ethyl group, a 3,5-dimethyladamantyl group, a quinuclidinyl group, a cyclopentylethyl group, or a bicyclo-octyl group.

The alkyl group having 1 to 21 carbon atoms and represented by R¹, R² or R³ is more preferably a methyl group, an ethyl group, a n-propyl group, a n-butyl group, a n-amyl group, a n-hexyl group, a n-heptyl group, a n-octyl group, a n-nonyl group, a n-decyl group, an iso-propyl group, a sec-butyl group, an iso-butyl group, a t-butyl group, a 1-methylbutyl group, a 1-ethylpropyl group, a 2-methylbutyl group, an iso-amyl group, a neopentyl group, a 1,2-dimethylpropyl group, a 1,1-dimethylpropyl group, a t-amyl group, a 1,3-dimethylbutyl group, a 3,3-dimethylbutyl group, a 2-ethylbutyl group, a 2-ethyl-2-methylpropyl group, a linear or branched heptyl group, a 1-methylheptyl group, a 2-ethylhexyl group, a 1,5-dimethylhexyl group, a t-octyl group, a branched nonyl group, a branched decyl group, a cyclopropyl group, a cyclopropylmethyl group, a cyclobutyl group, a cyclobutylmethyl group, a cyclopentyl group, a cyclohexyl group, a cyclohexylmethyl group, a cycloheptyl group, a cyclooctyl group, a cyclohexylpropyl group, a cyclododecyl group, a norbornyl group, a bornyl group, a noradamantyl group, an adamantyl group, an adamantylmethyl group, a 1-(1-adamantyl)ethyl group, a 3,5-dimethyladamantyl group, a cyclopentylethyl group, or a bicyclo-octyl group.

The alkyl group also preferably has at least one fluorine substituent. Typical examples of the alkyl group having at least one fluorine substituent include a trifluoromethyl group, a trifluoroethyl group, a pentafluoroethyl group, a heptafluoropropyl group, a nonafluorobutyl group, a tridecafluorohexyl group, a pentadecafluoroheptyl group, a heptadecafluorooctyl group, a tridecafluorooctyl group, a nonadecafluorononyl group, a heptadecafluorodecyl group, and a perfluorodecyl group. The alkyl group having at least one fluorine substituent is preferably a trifluoromethyl group, a pentafluoroethyl group, a heptafluoropropyl group, a nonafluorobutyl group, a tridecafluorohexyl group, or a pentadecafluoroheptyl group, and more preferably a trifluoromethyl group, a pentafluoroethyl group, a heptafluoropropyl group, a nonafluorobutyl group, or a tridecafluorohexyl group.

The alkenyl group having 2 to 21 carbon atoms and represented by R¹, R² or R³ may have at least one substituent or may not have a substituent, and preferably has 2 to 16 carbon atoms, and more preferably has 2 to 11 carbon atoms.

Typical examples of the alkenyl group having 2 to 21 carbon atoms and represented by R¹, R² or R³ include a vinyl group, an isopropenyl group, a 2-propenyl group, a 2-methyl-propenyl group, a 1-methyl-1-propenyl group, a 1-butenyl group, a 3-butenyl group, a 1-methyl-1-butenyl group, a 1,1-dimethyl-3-butenyl group, a 1-pentenyl group, a 2-pentenyl group, a 1-ethyl-1-pentenyl group, a 1-hexenyl group, a 1-heptenyl group, a 2,6-dimethyl-5-heptenyl group, a 9-decenyl group, a 1-cyclopentenyl group, a 2-cyclopetenyl methyl group, a cyclohexenyl group, a 1-methyl-2-cyclohexenyl group, a 1,4-dihydro-2-methylphenyl group, an octenyl group, a citronellyl group, an oleyl group, a geranyl group, a farnesyl group, and a 2-(1-cyclohexenyl)ethyl group.

The alkenyl group having 2 to 21 carbon atoms and represented by R¹, R² or R³ is preferably a vinyl group, an isopropenyl group, a 2-propenyl group, a 2-methyl-propenyl group, a 1-methyl-1-propenyl group, a 1-butenyl group, a 3-butenyl group, a 1-methyl-1-butenyl group, a 1,1-dimethyl-3-butenyl group, a 1-pentenyl group, a 2-pentenyl group, a 1-ethyl-1-pentenyl group, a 1-hexenyl group, a 1-heptenyl group, a 1-cyclopentenyl group, a 2-cyclopetenylmethyl group, a cyclohexenyl group, a 1-methyl-2-cyclohexenyl group, or a 1,4-dihydro-2-methylphenyl group, and more preferably a vinyl group, an isopropenyl group, a 2-propenyl group, a 2-methyl-propenyl group, a 1-methyl-1-propenyl group, a 1-butenyl group, a 3-butenyl group, a 1-methyl-1-butenyl group, a 1,1-dimethyl-3-butenyl group, a 1-pentenyl group, a 2-pentenyl group, a 1-ethyl-1-pentenyl group, a 1-hexenyl group, a 1-cyclopentenyl group, a 2-cyclopetenylmethyl group, a cyclohexenyl group, a 1-methyl-2-cyclohexenyl group, or a 1,4-dihydro-2-methylphenyl group.

The aryl group having 6 to 21 carbon atoms and represented by R¹, R² or R³ may have at least one substituent or may not have a substituent, and preferably has 6 to 18 carbon atoms, and more preferably has 6 to 15 carbon atoms.

Typical examples of the aryl group having 6 to 21 carbon atoms and represented by R¹, R² or R³ include a phenyl group, a naphthyl group, a biphenylenyl group, a acenaphthenyl group, a fluorenyl group, an anthracenyl group, an anthraquinolyl group, and a pyrenyl group. The aryl group having 6 to 21 carbon atoms and represented by R¹, R² or R³ is preferably a phenyl group, a naphthyl group, a biphenylenyl group, an acenaphthenyl group, a fluorenyl group, or an anthracenyl group, and more preferably a phenyl group, a naphthyl group, a biphenylenyl group, or a fluorenyl group.

The aralkyl group having 7 to 21 carbon atoms and represented by R¹, R² or R³ may have at least one substituent or may not have a substituent, and preferably has 7 to 19 carbon atoms, and more preferably has 7 to 16 carbon atoms.

Typical examles of the aralkyl group having 7 to 21 carbon atoms and represented by R¹, R² or R³ include a benzyl group, a diphenylmethyl group, a 1,2-diphenylethyl group, a phenyl-cyclopentylmethyl group, an α-methylbenzyl group, a phenylethyl group, an α-methyl-phenylethyl group, a β-methyl-phenylethyl group, a 3-phenylpropyl group, a 3,3-diphenylpropyl group, a 4-phenylbutyl group, a naphthylmethyl group, a styryl group, a sinnamyl group, a fluorenyl group, a 1-benzocyclobutenyl group, a 1,2,3,4-tetrahydronaphthyl group, an indanyl group, a piperonyl group, and a pyrenemethyl group.

The aralkyl group having 7 to 21 carbon atoms and represented by R¹, R² or R³ is preferably a benzyl group, a phenyl-cyclopentylmethyl group, an α-methylbenzyl group, a phenylethyl group, an α-methyl-phenylethyl group, a β-phenyl-phenylethyl group, a 3-phenylpropyl group, a 4-phenylbutyl group, a styryl group, a sinnamyl group, a fluorenyl group, a 1-benzocyclobutenyl group, or a 1,2,3,4-tetrahydronaphthyl group, and more preferably a benzyl group, an α-methylbenzyl group, a phenylethyl group, an α-methyl-phenylethyl group, a β-phenyl-phenylethyl group, a 3-phenylpropyl group, a styryl group, a sinnamyl group, a fluorenyl group, a 1-benzocyclobutenyl group, or a 1,2,3,4-tetrahydronaphthyl group.

The group represented by R¹, R² or R³ may contain at least one ether group. Preferably, such a group is, for example, a tetrahydrorofurfuryl group or a 2,5-dihydro-2,5-dimethoxyfurfuryl group.

As aforementioned, R¹, R², or R³ and the nitrogen atom that bonds to these groups R¹, R² and R³ may form a hetero ring. Typical examples of the hetero ring include a 2-methylaziridine ring, an azetidine ring, a pyrrolidine ring, a pyrroline ring, a piperidine ring, a 1,2,3,6-tetrahydropyridine ring, a hexamethyleneimine ring, a piperadine ring, an azabicyclooctane ring, a diazabicyclooctane ring, a decahydroquinoline ring, an oxazolidine ring, a morpholine ring, a thiazolidine ring, a thiomorpholine ring, an indoline ring, an isoindoline ring, a 1,2,3,4-tetrahydrocarbazole ring, a 1,2,3,4-tetrahydroquinoline ring, a 1,2,3,4-tetrahydroisoquinoline ring, an iminodibenzyl ring, a phenoxadine ring, a phenothiazine ring, and a phenazine ring.

The hetero ring formed by R¹, R² or R³ and the nitrogen atom is preferably a pyrrolidine ring, a pyrroline ring, a piperidine ring, a 1,2,3,6-tetrahydropyridine ring, a hexamethyleneimine ring, a piperadine ring, a diazabicyclooctane ring, a decahydroquinoline ring, an oxazolidine ring, a morpholine ring, a thiazolidine ring, or a thiomorpholine ring, and more preferably a pyrrolidine ring, a 3-pyrroline ring, a piperidine ring, a 1,2,3,6-tetrahydropyridine ring, a piperazine ring, a decahydroquinoline ring, an oxazolidine ring, a morpholine ring, a thiazolidine ring, or a thiomorpholine ring.

When the group represented by R¹, R² or R³, and the hetero ring formed by R¹, R² or R³ and the nitrogen atom have at least one substituent, typical examples of the substituent include an acyl group, an acylamino group, an acylaminocarbonylamino group, an aralkylaminocarbonylamino group, an arylaminocarbonylamino group, a methacryloylaminocarbonylamino group, an alkoxycarbonyl group, a trifluoromethyl group, a fluoro group, a chloro group, a bromo group, an iodo group, a hydroxy group, a nitro group, a methyl group, an ethyl group, a n-propyl group, an iso-propyl group, a n-butyl group, an iso-butyl group, a sec-butyl group, a t-butyl group, a pentyl group, a hexyl group, a heptyl group, an octyl group, a vinyl group, a methoxy group, an ethoxy group, a butoxy group, an isopropoxy group, a t-butoxy group, a cyclohexyloxy group, a vinyloxy group, a methylthio group, an ethylthio group, a pyrrolidinyl group, a piperidinyl group, a piperazinyl group, an amino group, a dimethylamino group, a diethylamino group, a phenyl group, an —SO₃M group, and a —COOM group. Here, M represents a hydrogen atom or a cation having at least one metal atom.

The substituent is preferably an acyl group (particularly, an acetyl group), an acylamino group, an acylaminocarbonylamino group, an alkoxycarbonyl group, a trifluoromethyl group, a fluoro group, a chloro group, a bromo group, a hydroxy group, a nitro group, a methyl group, an ethyl group, a n-propyl group, an iso-propyl group, a n-butyl group, an iso-butyl group, a sec-butyl group, a t-butyl group, a pentyl group, a hexyl group, a vinyl group, a methoxy group, an ethoxy group, a butoxy group, an isopropoxy group, a t-butoxy group, a cyclohexyloxy group, a vinyloxy group, a methylthio group, an ethylthio group, a pyrrolidinyl group, a piperidinyl group, a piperazinyl group, an amino group, a dimethylamino group, a diethylamino group, a phenyl group, or an —SO₃M group or a —COOM group where M represents a hydrogen atom or a cation having at least one metal atom, and more preferably an acyl group (particularly, an acetyl group), an acylamino group, an acylaminocarbonylamino group, an alkoxycarbonyl group, a trifluoromethyl group, a fluoro group, a chloro group, a bromo group, a hydroxy group, a nitro group, a methyl group, an ethyl group, a n-propyl group, an iso-propyl group, a n-butyl group, an iso-butyl group, a t-butyl group, a hexyl group, a vinyl group, a methoxy group, an ethoxy group, an isopropoxy group, a cyclohexyloxy group, a vinyloxy group, a methylthio group, an ethylthio group, a pyrrolidinyl group, a piperidinyl group, a piperazinyl group, an amino group, a dimethylamino group, a diethylamino group, a phenyl group, or an —SO₃M group or an —COOM group where M represents a hydrogen atom or a cation having at least one metal atom.

These substituents may further have at least one substituent that is similar to the above-described substituents.

The alkyl group, alkenyl group, aryl group, and aralkyl group represented by R¹, R² or R³, and the hetero ring formed by R¹, R² or R³ and the nitrogen atom may further have at least one substituent selected from the aforementioned examples of the group represented by R¹, R² or R³.

The amine compound represented by Formula (III) is preferably a compound where none of R¹, R² and R³ is a hydrogen atom, and, in other words, is preferably a tertiary aniline compound or an aliphatic tertiary amine compound.

When the at least one compound selected from the amine and pyridine compounds is a pyridine compound, the pyridine compounde is, for example, a compound represented by the following Formula (IV).

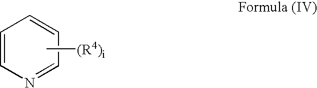

When the compound of Formula (IV) has plural R⁴s, each of R⁴s represents a hydrogen atom, a halogen atom, an alkyl group having 1 to 21 carbon atoms, an alkenyl group having 2 to 21 carbon atoms, an aryl group having 6 to 21 carbon atoms, an aralkyl group having 7 to 21 carbon atoms, a heterocyclic group having 2 to 21 carbon atoms, a cyano group, a hydroxyl group, a carboxyl group or a metal salt thereof, a nitro group, an amino group, an alkylamino group having 1 to 21 carbon atoms, an alkoxy group having 1 to 21 carbon atoms, an aryloxy group having 6 to 21 carbon atoms, an amide group having 1 to 21 carbon atoms, an arylamino group having 6 to 21 carbon atoms, an alkylthio group having 1 to 21 carbon atoms, an arylthio group having 6 to 21 carbon atoms, a carbamoyl group, an alkoxycarbonyl group having 2 to 21 carbon atoms, a heterocyclic oxy group having 2 to 21 carbon atoms, an acyloxy group having 2 to 21 carbon atoms, an aryloxycarbonyl group having 7 to 21 carbon atoms, a sulfonic group or a metal salt thereof, or an acyl group having 6 to 21 carbon atoms. Each of these groups may further have at least one substituent. Here, plural R⁴s may bond to each other via a carbon atom, a nitrogen atom, an oxygen atom or a sulfur atom to form a ring. In the formula, i is an integer of 0 to 5.

The alkyl group having 1 to 21 carbon atoms, the alkenyl group having 2 to 21 carbon atoms, the aryl group having 6 to 21 carbon atoms, and the aralkyl group having 7 to 21 carbon atoms that are represented by R⁴ have the same meanings as those of the alkyl group, the alkenyl group, the aryl group, and the aralkyl group represented by R¹, R² or R³ in the aforementioned amine compound.

The heterocyclic group having 2 to 21 carbon atoms and represented by R⁴ may have at least one substituent or may not have a substituent. The heterocyclic group preferably has 2 to 18 carbon atoms, and more preferably has 2 to 15 carbon atoms. Preferably, the heterocyclic group is a five- or six-membered ring.

Examples of the heterocyclic group represented by R⁴ include a 2-pyridyl group, a 2-thienyl group, and a 2-furyl group.

The alkoxy group having 1 to 21 carbon atoms and represented by R⁴ may have at least one substituent or may not have a substituent. The alkoxy group preferably has 1 to 15 carbon atoms, and more preferably has 1 to 10 carbon atoms. Examples of the substituent include alkoxy groups and a hydroxyl group.

Examples of the alkoxy group having 1 to 21 carbon atoms and represented by R⁴ include a methoxy group, an ethoxy group, an isopropoxy group, a methoxyethoxy group, a hydroxyethoxy group, and a 3-carboxypropoxy group.

The aryloxy group having 6 to 21 carbon atoms and represented by R⁴ may have at least one substituent or may not have a substituent. The aryloxy group preferably has 6 to 18 carbon atoms, and more preferably has 6 to 15 carbon atoms. The substituent is, for example, an alkoxy group.

Examples of the aryloxy group having 6 to 21 carbon atoms and represented by R⁴ include a phenoxy group, a p-methoxyphenoxy group, and an o-methoxyphenoxy group.

The amide group having 1 to 21 carbon atoms and represented by R⁴ may have at least one substituent or may not have a substituent. The amide group preferably has 1 to 15 carbon atoms, and more preferably has 1 to 10 carbon atoms.

Examples of the amide group having 1 to 21 carbon atoms and represented by R⁴ include an acetamide group, a propionamide group, a benzamide group, and a 3,5-disulfobenzamide group.

The arylamino group having 6 to 21 carbon atoms and represented by R⁴ may have at least one substituent or may not have a substituent. The arylamino group preferably has 6 to 18 carbon atoms, and more preferably has 6 to 15 carbon atoms. The substituent is, for example, a halogen atom.

Examples of the arylamino group having 6 to 21 carbon atoms and represented by R⁴ include an anilino group and a 2-chloroanilino group.

The alkylthio group having 1 to 21 carbon atoms and represented by R⁴ may have at least one substituent or may not have a substituent. The alkylthio group preferably has 1 to 15 carbon atoms, and more preferably has 1 to 10 carbon atoms.

Examples of the alkylthio group having 1 to 21 carbon atoms and represented by R⁴ include a methylthio group, and an ethylthio group.

The arylthio group having 6 to 21 carbon atoms and represented by R⁴ may have at least one substituent or may not have a substituent. The arylthio group preferably has 6 to 18 carbon atoms, and more preferably has 6 to 15 carbon atoms. The substituent is, for example, an alkyl group.

Examples of the arylthio group having 6 to 21 carbon atoms and represented by R⁴ include a phenylthio group and a p-tolylthio group.

The alkoxycarbonyl group having 2 to 21 carbon atoms and represented by R⁴ may have at least one substituent or may not have a substituent. The alkoxycarbonyl group preferably has 2 to 16 carbon atoms, and more preferably has 2 to 11 carbon atoms.

Examples of the alkoxycarbonyl group having 2 to 21 carbon atoms and represented by R⁴ include a methoxycarbonyl group, and an ethoxycarbonyl group.

The heterocyclic oxy group having 2 to 21 carbon atoms and represented by R⁴ may have at least one substituent or may not have a substituent. The heterocyclic oxy group is preferably a five- or six-membered ring. The substituent is, for example, a hydroxyl group. The heterocyclic oxy group preferably has 2 to 17 carbon atoms, and more preferably has 2 to 14 carbon atoms.

The heterocyclic oxy group having 2 to 21 carbon atoms and represented by R⁴ is, for example, a 2-tetrahydropyranyloxy group.

The acyloxy group having 2 to 21 carbon atoms and represented by R⁴ may have at least one substituent or may not have a substituent. The acyloxy group preferably has 2 to 16 carbon atoms, and more preferably has 2 to 11 carbon atoms.

The acyloxy group having 2 to 21 carbon atoms and represented by R⁴ is, for example, an acetoxy group.

The aryloxycarbonyl group having 7 to 21 carbon atoms and represented by R⁴ may have at least one substituent or may not have a substituent. The aryloxycarbonyl group preferably has 7 to 18 carbon atoms, and more preferably has 7 to 15 carbon atoms.

The aryloxycarbonyl group having 7 to 21 carbon atoms and represented by R⁴ is, for example, a phenoxycarbonyl group.

The Salt of sulfonic acid represented by R⁴ includes a cation having at least one metal atom. The cation preferably includes Na, K, Rb, or Cs, more preferably includes Na, K, or Rb, and still more preferably includes Na, or K.

The pyridine compound represented by Formula (IV) is preferably a compound having a substituent, which is other than a hydrogen atom, at 2-position.

The content of the at least one compound selected from the amine and pyridine compounds in the solid matter of the negtive curable dye-containing composition is preferably 0.05 to 10.0 mass %. The content is more preferably 0.07 to 5.0 mass %, and most preferably 0.1 to 3.0 mass %.

When the at least one compound selected from the amine and pyridine compounds is an amine compound, specific examples of the amine compound include the following compounds:

Methylamine, ethylamine, propylamine, butylamine, amylamine, hexylamine, heptylamine, octylamine, nonylamine, decylamine, undecylamine, dodecylamine, tridecylamine, tetradecylamine, pentadecylamine, hexadecylamine, octadecylamine, isopropylamine, sec-butylamine, isobutylamine, t-butylamine, 1-methylbutylamine, 1-ethylpropylamine, 2-methylbutylamine, isoamylamine, 1,2-dimetnylpropylamine, t-amylamine, 1,3-dimethylbutylamine, 3,3-dimethylbutylamine, 2-aminoheptane, 3-aminoheptane, 1-methylheptylamine, 2-ethylhexylamine, 1,5-dimethylhexylamine, t-octylamine, ethylenediamine, 1,3-diaminopropane, 1,2-diaminopropane, 1,4-diaminobutane, 1,2-diamino-2-methylpropane, 1,5-diaminopentane, 2,2-dimethyl-1,3-propanediamine, hexamethylenediamine, 1,7-diaminoheptane, 1,8-diaminooctane, 1,9-diaminononane, 1,10-diaminodecane, 1,12-diaminododecane, dimethylamine, N-ethylmethylamine, diethylamine, N-methylpropylamine, N-methylisopropylamine, N-ethylisopropylamine, dipropylamine, di-isopropylamine, N-methylbutylamine, N-ethylbutylamine, N-methyl-t-butylamine, N-t-butylisopropylamine, dibutylamine, di-sec-butylamine, di-isobutylamine, t-amyl-t-butylamine, dipentylamine, N-methylhexylamine, dihexylamine, t-amyl-t-octylamine, dioctylamine, bis(2-ethylhexyl)amine, didecylamine, N-methyloctadecylamine, trimethylamine, N,N-dimethylethylamine, N,N-diethylmethylamine, triethylamine, tripropylamine, N,N-dimethylisopropylamine, N,N-di-isopropylethylamine, N,N-dimethylbutylamine, N-methylbutylamine, tributylamine, tri-isobutylamine, tripentylamine, N,N-dimethylhexylamine, trihexylamine, N,N-dimethyloctylamine, N-methyldioctylamine, trioctylamine, tri-iso-occtylamine, tri-isododecylamine, N,N-dimethylundecylamine, N,N-dimethyldodecylamine, tridodecylamine, N-methyldi-octadecylamine, N,N,N′,N′-tetramethyldiaminomethane, N-methylethylenediamine, N-ethylethylenediamine, N-propylethylenediamine, N-isopropylethylenediamine, N,N′-dimethylethylenediamine, N,N-dimethylethylenediamine, N,N′-diethylethylenediamine, N,N-diethylethylenediamine, N,N′-di-isopropylethylenediamine, N,N-dibutylethylene diamine, N,N,N′-trimethylethylenediamine, N,N-dimethyl-N′-ethylethylenediamine, N,N-diethyl-N′-methylethylenediamine, N,N,N′-triethylethylenediamine, N,N,N′,N′-tetramethylethylenediamine, N,N,N′,N′-tetraethylethylenediamine, N-methyl-1,3-propanediamine, N-propane-1,3-propanediamine, N-isopropyl-1,3-propanediamine, 3-dimethylaminopropylamine, 3-diethylaminopropylamine, 3-dibutylaminopropylamine, N,N′-dimethyl-1,3-propanediamine, N,N′-diethyl-1,3-propanediamine, N,N′-di-isopropyl-1,3-propanediamine, N,N,N′-trimehyl-1,3-propanediamine, N,N,N′,N′-tetramethyl-1,3-propanediamine, N,N,N′,N′-tetraethyl-1,3-propanediamine, N,N,N′,N′-tetramethyl-1,3-butanediamine, N,N,2,2-tetramethyl-1,3-propanediamine, N,N,N′,N′-tetramethyl-1,4-butanediamine, 2-butyl-2-ethyl-1,5-pentanediamine, 2-amino-5-diethylaminopentane, N,N′-dimethyl-1,6-hexanediamine, N,N,N′,N′-tetramethyl-1,6-hexanediamine, N,N,N′,N′-tetrabutyl-1,6-hexanediamine, tris(dimethylamino)methane, diethylenetriamine, N-1-isopropyldiethylenetriamine, N,N,N′,N′-tetraethyldiethylenetriamine, N,N,N′,N′N″-pentamethyldiethylenetriamine, N-(2-aminoethyl)-1,3-propanediamine, 3,3′-diamino-N-methyldipropylamine, N-(3-aminopropyl)-1,3-propanediamine, 3,3′-iminobis(N,N-dimethylpropylamine), bis(hexamethylene)triamine, N,N′,N″-trimethylbis(hexamethylene)triamine, 4-(aminomethyl)-1,8-octanediamine, triethylenetetramine, 1,1,4,7,10,10-hexamethyltriethylenetetramine, N,N′-bis (3-aminopropyl)-ethylenediamine, N,N′-bis(2-aminoethyl)-1,3-propanediamine, N,N′-bis(3-aminopropyl)-1,3-propanediamine, tri(2-aminoethyl)amine, tetraethylenepentamine, pentaethylenehexamine, cyclopropylamine, (aminomethyl)cyclopropylamine, N-propylcyclopropanemethylamine, cyclobutylamine, cyclopentylamine, 5-amino-2,2,4-trimethyl-1-cyclopentanemethylamine, cyclohexylamine, N-methylcyclohexylamine, N-ethylcyclohexylamine, N-isopropylcyclohexylamine, N-t-butylcyclohexylamine, dicyclohexylamine, N,N-dimethylcyclohexylamine, N,N-diethylcyclohexylamine, N-methyldicyclohexylamine, N-ethyldicyclohexylamine, 2-methylcyclohexylamine, 4-methylcyclohexylamine, 4,4′-methylenebis(cyclohexylamine), 2,3-dimethylcyclohexylamine, 4,4′-methylenebis(2-methylcyclohexylamine), 1,2-diaminocyclohexane, 1,4-diaminocyclohexane, N,N′-bis(3,3-dimethylbutyl)-1,2-cyclohexanediamine, cyclohexanemethylamine, N,N-dimethylcyclohexanemethylamine, 1-cyclohexylethylamine, 1,3-cyclohexanebis(methylamine), N-cyclohexyl-1,3-propanediamine, 1,8-diamino-p-menthane, 5-amino-1,3,3-trimethylcyclohexanemethylamine, cycloheptylamine, cyclooctylamine, cyclododecylamine, 2-aminonorbornene, bornylamine, cis-miltanylamine, 3-noradamanthanamine, 1-adamanthanamine, 2-adamanthanamine, 1-adamanthanemethylamine, 1-(1-adamanthyl)ethylamine, allylamine, oleylamine, geranylamine, N-methylallylamine, N-ethyl-2-methylallylamine, diallylamine, triallylamine, tri(2-methylally)amine, N,N′-diethyl-2-butene-1,4-diamine, N,N,N′,N′-tetramethyl-2-butene-1,4-diamine, tetrakis(dimethylamino)ethylene, N-allycyclopentylamine, allylcyclohexylamine, 2-(1-cyclohexenyl)ethylamine, 6-(dimethylamino)fulvene, 2-fluoroethylamine, 2,2,2-trifluoroethylamine, 2-chloroethylamine, 2-bromoethylamine, 3-chloropropylamine, 3-bromopropylamine, 2,5-dichloroamylamine, bis(2-chloroethyl)amine, 2-dimethylaminoethyl chloride, 2-diethylaminoethyl chloride, tri(2-chloroethyl)amine, 3-dimethylaminopropyl chloride, 2-dimethylaminoisopropyl chloride, 2-di-isopropylaminoethyl chloride, 3-dimethylamino-2-methylpropyl chloride, perfluorotriethylamine, perfluorotributylamine, 2-methoxyethylamine, 3-methoxypropylamine, 3-ethoxypropylamine, 3-butoxyproplylamine, 2-amino-1-methoxypropane, 3-isopropoxypropylamine, 2,2′-oxybis(ethylamine), 2,2′-(ethylenedioxy)-bis(ethylamine), 4,9-dioxa-1,12-dodecanediamine, 4,7,10-trioxa-1,13 -tridecanediamine, bis(2-methoxyethyl)amine, tri[2-(2-methoxyethoxy)ethyl]-amine, 2,3-dimethoxy-1,4-bis(dimethylamino)butane, t-butoxybis(dimethylamino)methane, 3-amino-1-propanol vinyl ether, 2-(diethylamino)ethanol vinyl ether, tetrahydrofurfurylamine, 2,5-dihydro-2,5-dimethoxyfurfurylamine, N,N-dimethylforamide dimethylacetal, N,N-dimethylformamide dimethylacetal, N,N-dimethylformamide dipropylacetal, N,N-dimethylformamide di-isopropylacetal, N,N-dimethylformamide di-t-butylacetal, N,N-dimethylformamide dineopentylacetal, N,N-dimethylformamide dicyclohexylacetal, aminoacetaldehyde dimethylacetal, aminoacetaldehyde diethylacetal, methylaminoacetaldehyde dimethylacetal, N,N-dimethylacetamide dimethylacetal, dimethylaminoacetaldehyde diethylacetal, diethylamino acetaldehyde diethylacetal, 4-aminobutylaldehyde diethylacetal, N,N-bis(2,2-diethoxyethyl)-methylamine, 2-methylaminomethyl-1,3-dioxolane, ethanolamine, 3-amino-1-propanol, 2-amino-1-propanol, 1-amino-2-propanol, 4-amino-1-butanol, 2-amino-1-butanol, 2-amino-2-methyl-1-propanol, 5-amino-1-pentanol, 2-amino-1-pentanol, 2-amino-3-methyl-1-butanol, 6-amino-1-hexanol, isoleucinol, leucinol, t-leucinol, 6-amino-2-methyl-2-heptanol, cerinol, 1-amino-1-cyclopentanemethanol, 2-amino-3-cyclohexyl-1-propanol, 2-aminocyclohexanol, 4-aminocyclohexanol, 1-aminomethyl-1-cyclohexanol, 3-aminomethyl-3,5,5-trimethylcyclohexanol, 2-(2-aminoethoxy)ethanol, 2-(methylamino)ethanol, 2-(ethylamino)ethanol, 2-(propylamino)ethanol, 2-(t-butylamino)ethanol, diethanolamine, diisopropanolamine, N,N-dimethylethanolamine, N,N-diethylethanolamine, 2-(diisopropylamino)ethanol, 2-(dibutylamino)ethanol, 3-dimethylamino-1-propanol, 3-diethylamino-1-propanol, 1-dimethylamino-2-propanol, 1-diethylamino-2-propanol, 2-dimethylamino-2-methyl-1-propanol, 5-diethylamino-2-pentanol, N-methyldiethanolamine, N-ethyldiethanolamine, N-butyldiethanolamine, triethanolamine, 1-(N,N-bis (2-hydroxyethyl)amino]-2-propanol, triisopropanolamine, 3-amino-1,2-propanediol, 3-(dimethylamino)-1,2-propanediol, 3-(diethylamino)-1,2-propanediol, 3-dipropylamino-1,2-propanediol, 3-diisopropylamino-1,2-propanediol, cerinol, 2-amino-2-methyl-1,3 -propanediol, 2-amino-2-ethyl-1,3-propanediol, tri(hydroxymethyl)aminomethane, 2,2-bis(hydroxymethyl)-2,2′,2″-nitrilotrimethanol, 1,3-diamino-2-hydroxypropane, 2-(2-aminoethylamino)-ethanol, 2-{[2-(dimethylamino)ethyl]-methylamino }ethanol, 1,3-bis(dimethylamino)-2-propanol, N,N′-bis(2-hydroxyethyl)-ethylenediamine, N,N,N′,N′-tetrakis(2-hyroxypropyl)-ethylenediamine, 1,3-bis[tri(hydroxymethyl)-methylamino]propane, 2-[2-(dimethylamino)ethoxy]ethanol, pentrol, 1-amino-1-deoxy-D-dorbitol, N-methyl-D-glucamine, 1-deoxy-1-(methylamino)-D-galactitol, 1-deoxy-1-(octylamino)-D-glucitol, D-galactosamine, D-glucosamine, D-mannosamine, di-β-D-xylopyranosilamine, 2-aminoethanethiol, 2-(butylamino)ethanethiol, 2-dimethylaminoethanethiol, 2-diethylaminoethanethiol, 1-amino-2-methyl-2-propanethiol, 2-(ethylthio)ethylamine, methioninol, 2-methylaziridine, 1-aziridineethanol, azetidine, pyrrolidine, 1-methylpyrrolidine, 1-butylpyrrolidine, 2,5-dimethylpyrrolidine, 1-pyrrolidino-1-cyclopentene, 1-pyrrolidino-1-cyclohexene, 1-(2-chloroethyl)pyrrolidine, 2-(2-chloroethyl)-1-methylpyrrolidine, 1-(2-hydroxyethyl)pyrrolidine, 3-pyrrolidino-1,2-propanediol, 3-pyrrolidinol, 1-methyl-3-pyrrolidinol, 1-ethyl-3-pyrrolidinol, 2-pyrrolidinemethanol, 1-methyl-2-pyrrolidinemethanol, 1-methyl-2-pyrrolidineethanol, 2-(methoxymethyl)-pyrrolidine, 3-aminopyrrolidine, 2-(aminomethyl)-pyrrolidine, 1-(2-aminoethyl)pyrrolidine, 2-(2-aminoethyl)-1-methylpyrrolidine, 1-(2-pyrrolidinylmethyl)-pyrrolidine, 3-pyrroline, 2-methyl-1-pyrroline, 2,5-dimethyl-3-pyrroline, piperidine, 1,2,3,6-tetrahydropyridine, 1-methylpiperidine, 1-ethylpiperidine, dipiperidinomethane, 1-ethylpiperidine, 2-methylpiperidine, 2-ethylpiperidine, 3-methylpiperidine, 1,1′-methylenebis(3-methylpiperidine), 4-methylpiperidine, 4-(1-pyrrodinyl)piperidine, 4-piperidinopiperidine, 4,4′-dipiperidine, 4,4′-ethylenedipiperidine, 4,4′-trimethylenedipiperidine, 4,4′-trimethylenebis(1-methylpiperidine), 3,3-dimethylpiperidine, 2,6-dimethylpiperidine, 3,5-dimethylpiperidine, 2,2,6,6-tetramethylpiperidine, 1,2,2,6,6-penthamethylpiperidine, 4-bromopiperidine, 1-(2-chloroethyl)piperidine, 1-(3-chloropropyl)piperidine, 3-chloromethyl-1-methylpiperidine, 4-chloro-1-methylpiperidine, 1-piperidineacetaldehyde diethylacetal, 1,4-dioxa-8-azaspiro[4.5]decane, 1-piperidineethanol, 3-piperidino-1,2-propanediol, 2-piperidinemethanol, 1-methyl-2-piperidinemethanol, 2-piperidineethanol, 3-hydroxypiperidine, 3-hydroxy-1-methylpiperidine, 1-ethyl-3-hydroxypiperidine, 3-piperidinemethanol, 1-methyl-3-piperidinemethanol, 4-hydroxypiperidine, 4-hydroxy-1-methylpiperidine, 4,4′-trimethylenebis(1-piperidineethanol), 2,2,6,6-tetramethyl-4-piperidinol, 7,7,9,9-tetramethyl-1,4-dioxa-8-azaspiro[4.5]decane-2-methanol, 4-piperidone, 1-(2-aminoethyl)piperidine, 1-(3-aminopropyl)-2-pipecoline, 3-aminopiperidine, 1-methyl-4-(methylamino)-piperidine, 4-(aminomethyl)piperidine, 3-(4-aminobutyl)piperidine, 4-amino-2,2,6,6-tetramethylpiperidine, 4-dimethylamino-2,2,6,6-tetramethylpiperidine, N,N′-bis(2,2,6,6-tetramethyl-4-piperidinyl)-1,6-hexanediamine, 1-methyl-1,2,3,6,-tetrahydropyridine, hexamethyleneimine, 2-(hexamethyleneimino)ethyl chloride, heptamethyleneimine, 2-methyl-2-imidazoline, 4,4-dimethyl-2-imidazoline, 2-methylthio-2-imidazoline, piperazine, 1-methylpiperazine, 1-ethylpiperazine, 1,4-dimethylpiperazine, 2-methylpiperazine, 2,6-dimethylpiperazine, 2,5-dimethylpiperazine, 4-(dimethylamino)-1,2,2,6,6-pentamethylpiperidine, 1-(2-hydroxyethyl)piperazine, 1,4-bis(2-hydroxyethyl)piperazine, 1-[2-(2-hydroxyethoxy)ethyl]piperazine, 1-(2-aminoethyl)piperazine, 1,4-bis(3-aminopropyl)piperazine, hexetidine, 1,4,5,6-tetrahydropyrimidine, homopiperazine, 1-methylhomopiperazine, 1,3,5-trimehylhexahydro-1,3,5-triazine, 1,3,5-triethylhexahydro-1,3,5-triazine, acetylaldehyde ammonia trimer, 1,4,7-triazacyclononane, 1,4,7-trimethyl-1,4,7-triazacyclononane, 1,5,9-triazacyclododecane, 1,5,9-trimethyl-1,5,9-triazacyclododecane, 1,4,8,11-tetraazacyclotetradecane, 1,4,8,11-tetramethyl-1,4,8,11-tetraazacyclotetradecane, 1,4,8,12-tetraazacyclopentadecane, tropane, quinuclidine, 3-chloroquinuclidine, 3-quinuclidinol, 2-methylene-3-quinuclidinone, 3-aminoquinuclidine, 1,3,3-trimethyl-6-azabicyclo[3.2.1]octane, decahydroquinoline, 1,4-diazabicyclo[2.2.2]octane, 1,8-diazabicyclo[5.4.0]undecene, 1,3,4,6,7,8-hexahydro-2H-pyrimide[1,2-A]pyrimidine, 1,3,4,6,7,8-hexahydro-1-methyl-2H-pyrimido[1,2-A]pyrimidine, hexamethylentetramine, 4,4-dimethyloxazolidine, 4-ethyl-2-methyl-2-(3-methylbutyl)oxazolidine, morpholine, 4-methylmorpholine, 4-ethylmorpholine, 2,6-dimethylmorpholine, 4-(1-cyclopentene-1-yl) morpholine, 1-morpholino-1-cyclohexene, 1-morpholino-1-cycloheptene, 4-(2-chloroethyl)morpholine, 4-(2-hydroxyethyl)morpholine, 3-morpholino-1,2-propanediol, 4-(2-aminoethyl)morpholine, 4-[2-(dimethylamino)ethyl]morpholine, 4-(3-aminopropyl)morpholine, 5-ethyl-1-aza-3,7-dioxabicyclo[3.3.0]octane, 1-aza-3,7-dioxabicyclo[3.3.0]octane-5-methanol, 2-(aminomethyl)-15-crown-5,2-(aminoethyl)-18-crown-6,1-aza-12-crown-4,1-aza-15-crown-5,1-aza-18-crown-6,1,4,10-trioxa-7,13-diazacyclopentadecane, 1,4,10,13-tetraoxa-7,16-diazacyclooctadecane, 4,7,13,18-tetraoxa-1,10-diazabicyclo[8.5.5]eicosane, 4,7,13,16,21 -pentaoxa-1,10-diazabicyclo[8.8.5]tricosane, 4,7,13,16,21,24-hexaoxa-1,10-diazabicyclo[8.8.8]hexacosane, thizolidine, thiomorpholine, glycine, iminodiacetic acid, sodium iminodiacetate, ethylenediamine-N,N′-diacetic acid, methyliminodiacetic acid, N-(2-hydroxyethyl)-iminodiacetic acid, nitrilotriacetic acid, N-(2-hydroxyethyl)ethylenediaminetriacetic acid, ethylenediaminetetraacetic acid, N,N′-bis(2-carboxyethyl)-N,N′-ethylenediglycine, 1,2-diaminopropane-N,N,N′N′-tetraacetic acid, 1,6-diaminohexane-N,N,N′,N′-tetraacetic acid, 1,2-diaminocyclohexane-N,N,N′,N′-tetraacetic acid, triethylenetetraminehexaacetic acid, 1,3-diamino-2-hydroxypropane-N,N,N′,N′-tetraacetic acid, ethylenebis(octaethylenenitrilo)tetraacetic acid, diethylenetriaminepentaacetic acid, sarcosine, N,N-dimethylglycine, trisine, bisine, bisine sodium salt, alanine, α-aminocyclohexanepropanoic acid, 3-chloroalanine, N,N-dipropylalanine, 2-aminoisobutyric acid, 2-(methylamino)isobutyric acid, 2-aminobutyric acid, valine, t-leucine, norvaline, 2-amino-4-pentenic acid, isoleucine, leucine, norleucine, 2,3-diaminopropanoic acid, 2-aminocapric acid, β-alanine, 3-(diethylamino)propanoic acid, 3-aminoisobutyric acid, 3-aminobutyric acid, 4-aminobutyric acid, 4-(methylamino)butyric acid, 4-(dimethylamino)butyric acid, 5-aminovaleric acid, 6-aminocaproic acid, 7-aminoheptanoic acid, 8-aminocapric acid, 11-aminoundecanoic acid, 12-aminododecanoic acid, serine, isoserine, homoserine, cannabanine, threonine, 4-amino-3-hydroxybutanoic acid, muramic acid, 5-hydroxylycine, 1-amino-1-cyclopropanecarboxylic acid, 1-amino-1-cyclopentanecarboxylic acid, 1-amino-1-cyclohexanecarboxylic acid, 4-(aminoethyl)-cyclohexanecarboxylic acid, 5-amino-1,3-cyclohexadiene-1-carboxylic acid, 2-amino-2-norbornanecarboxylic acid, 2-azetidinecarboxylic acid, 3-azetidinecarboxylic acid, proline, N-methylproline, 3-hydroxyproline, 4-hyroxyproline, chinic acid, 3,4-dehydroproline, 3-azabicyclo[3.1.0]hexane-2-carboxylic acid, pipecholinic acid, nipecotinic acid, isonipecotinic acid, 1-piperidinepropanoic acid, 2,3-diaminopropanoic acid, 2,4-diaminobutanoic acid, omithine, 2-methylornithine, lycine, aspartic acid, N-methylaspartic acid, glutamic acid, 2-methylglutamic acid, 2-aminoadipic acid, 3-aminoadipic acid, 2,6-diaminopimellic acid, octopine, γ-carboxyglutamic acid, cysteine, penicilamine, homocysteine, S-methylcysteine, methionine, ethionine, S-carboxymethylcysteine, lanthionine, cystine, thiazoline-4-carboxylic acid, 1,4,8,11-tetraazacyclotetradecane-1,4,8,11-tetraacetic acid, aniline, N-methylaniline, N-ethylaniline, N-butylaniline, diphenylamine, N-phenylbenzylamine, 1,2-dianilinoethane, N-allylaniline, N,N-dimethylaniline, N-ethyl-N-methylaniline, N,N-diethylaniline, N,N-dibutylaniline, 1-phenylpiperidine, triphenylamine, N-benzyl-N-ethylaniline, 2-anilinoethanol, 2-(N-ethylaminilino)ethanol, N-phenyldiethanolamine, N-(ethoxymethyl)-N-methylaniline, o-toluidine, 2,2′-ethylenedianiline, N-ethyl-o-toluidine, N,N-dimethyl-o-toluidine, 2-ethylaniline, 2-propylaniline, 2-isopropylaniline, 2-butylaniline, 2-sec-butylaniline, 2-t-butylaniline, 2-fluoroaniline, 2-(trifluoromethyl)aniline, 2-(2-chloro-1,1,2-trifluoroethylthio)aniline, 2-chloroaniline, 2-bromoaniline, 2-iodoaniline, o-anisidine, o-phenetidine, 2-aminophenol, 2-aminobenzyl alcohol, 2-aminophenethyl alcohol, 2-aminothiophenol, 2-(methylmercapto)aniline, 2-aminophenyl disulfide, 2-isopropenylaniline, m-toluidine, N,N-dimethyl-m-toluidine, N-ethyl-m-toluidine, 3-ethylaniline, 3-fluoroaniline, 3-(trifluoromethyl)aniline, 3-chloroaniline, 3-bromoaniline, 3-iodoaniline, m-anisidine, m-phenetidine, 3-(trifluoromethoxy)aniline, 3-(1,1,2,2,-tetrafluoroethoxy)aniline, 3-aminophenol, 3-(1-hydroxyethyl)aniline, 3-aminothiophenol, 3-(methylmercapto)aniline, N,N-diethyl-m-toluidine, 3-dimethylaminophenol, 3-diethylaminophenol, 2-(N-ethyl-m-toluidino)ethanol, p-toluidine, N,N-dimethyl-p-toluidine, 4,4′-ethylenedianiline, 4-ethylaniline, 4-propylaniline, 4-isopropylaniline, 4-butylaniline, 4-sec-butylaniline, 4-t-butylaniline, 4-t-butyl-N,N-dimethylaniline, 4-pentylaniline, 4-hexylaniline, 4-heptylaniline, 4-octylaniline, 4-decylaniline, 4-dodecylaniline, 4-tetradodecylaniline, 4-hexadecylaniline, 4-cyclohexylaniline, 3,3′-methylenedianiline, 4,4′-methylenedianiline, 4,4′-methylenebis(3-chloro-2,6-diethylaniline), 4,4′-diaminostilbene, 4-fluoroaniline, 4-(trifluoromethyl)aniline, 4-chloroaniline, 4-chloro-N-methylaniline, 4-bromoaniline, 4-bromo-N,N-dimethylaniline, 4-iodoaniline, p-anisidine, N-methyl-p-anisidine, p-phenetidine, 4-butoxyaniline, 4-pentyloxyaniline, 4-hexyloxyaniline, 4-(trifluoromethoxy)aniline, 4,4′-oxydianiline, 4″,4′″-(hexafluoroisopropylidene)bis(4-phenoxyaniline), N′.N-diglycidyl-4-glycidyloxyaniline, 4-aminophenol, 4-aminothiophenol, 4-(methylmercapto)aniline, 4,4′-thiodianiline, 4-aminophenyl disulfide, 2,2′-(p-tolylimino)diethanol, N,N,N′,N′-tetramethylbenzidine, 4-methylaminophenol, 4-aminophenethyl alcohol, 4-(dimethylamino)phenethyl alcohol, 2,3 -dimethylaniline, N-ethyl-2,3-xylidine, 1-amino-5,6,7,8-tetrahydronaphthalene, 2,6-dimethylaniline, 6-ethyl-o-toluidine, 2,6-diethylaniline, 2-isopropyl-6-methylaniline, 2,6-di-isopropylaniline, 2,6-di-isopropyl-N,N-dimethylaniline, 3-fluoro-2-methylaniline, 3-chloro-2-methylaniline, 2-chloro-6-methylaniline, 2,6-difluoroaniline, 2,3-difluoroaniline, 2,6-dichloroaniline, 2,3-dichloroaniline, 2,6-dibromoaniline, 2-methoxy-6-methylaniline, 3-fluoro-o-anisidine, 2-amino-3-methylbenzyl alcohol, 3-amino-2-methylbenzyl alcohol, 2-amino-m-cresol, 2,3-diaminophenol, 3,4-dimethylaniline, 5-aminoindane, 2,5-dimethylaniline, 2,4-dimethylaniline, o-tolidine, 4,4′-ethylene-di-m-toluidine, 2,5-di-t-butylaniline, 3-fluoro-4-methylaniline, 2-fluoro-4-methylaniline, 5-fluoro-2-methylaniline, 2-fluoro-5-methylaniline, 4-fluoro-2-methylaniline, 2,5-bis(trifluoromethyl)aniline, 2-fluoro-6-(trifluoromethyl)aniline, 2-fluoro-3-(trifluoromethyl)aniline, 4-bromo-N,N-dimethyl-3-(trifluoromethyl)aniline, 2,4-difluoroaniline, 3-chloro-4-fluoroaniline, 3,4-difluoroaniline, 2,5-difluoroaniline, 4-chloro-2-fluoroaniline, 2-chloro-4-fluoroaniline, 2-bromo-4-fluoroaniline, 4-bromo-2-fluoroaniline, 2-fluoro-4-iodoaniline, 2-chloro-4-aminotoluene, 2-chloro-4-methylaniline, 2-chloro-5-methylaniline, 5-chloro-2-methylaniline, 4-chloro-2-methylaniline, 3,4-dichloroaniline, 2,4-dichloroaniline, 2,5-dichloroaniline, 4-bromo-2-methylaniline, 4-bromo-3-methylaniline, 3-bromo-4-methylaniline, 2-bromo-4-methylaniline, 4-bromo-2-chloroaniline, 2,4-dibromoaniline, 2,5-dibromoaniline, 4-fluoro-2-(trifluoromethyl)aniline, 4-fluoro-3-(trifluoromethyl)aniline, 2-fluoro-5-(trifluoromethyl)aniline, 4-chloro-3-(trifluoromethyl)aniline, 4-chloro-2-(trifluoromethyl)aniline, 4-bromo-2-(trifluoromethyl)aniline, 4-bromo-3-(trifluoromethyl)aniline, 2-bromo-5-(trifluoromethyl)aniline, 2-chloro-5-(trifluoromethyl)aniline, 5,5′-(hexafluoropropylidene)-di-o-toluidine, 4-methoxy-2-methylaniline, 2-methoxy-5-methylaniline, 5-methoxy-2-methylaniline, 5-t-butyl-o-anisidine, 2-methoxy-5-(trifluoromethyl)aniline, 6-chloro-m-anisidine, 4-aminoveratrole, 3,4-(methylenedioxy)aniline, N-ethyl-3,4-(methylenedioxy)aniline, 1,4-benzodioxane-6-amine, 4′-aminobenzo-15-crown-5,2,4-dimethoxyaniline, 4-aminoresorsinol, 2,5-dimethoxyaniline, 5-amino-2-methoxyphenol, 3-amino-o-cresol, 2-amino-p-cresol, 2-amino-4-t-butylphenol, 2-amino-4-t-amylphenol, 6-amino-m-cresol, 4-amino-m-cresol, 2-amino-5-methylbenzyl alcohol, 3-amino-4-methylbenzenzyl alcohol, 2-amino -4-chlorophenol, 4-amino-3-chlorophenol, 2-amino-5-chlorobenzyl alcohol, 5-chloro-o-anisidine, 3-fluoro-p-anisidine, 3-chloro-p-anisidine, 2-amino-4-(trifluoromethyl)benzenethiol, 3,5-dimethylaniline, N,N,3,5-tetramethylaniline, 3,5-di-t-butylaniline, 3,5-bis(trifluoromethyl)aniline, 3,5-difluoroaniline, 3,5-dichloroaniline, 3,5-dimethoxyaniline, 3-methoxy-5-(trfluoromethyl)aniline, 2,4,6-trimethylaniline, N,N,2,4,6-pentamethylaniline, 4,4′-methylenebis(2,6-dimethylaniline), 4,4′-methylenbis(2,6-diethylaniline), 4,4′-methylenebis(2,6-di-isopropylaniline), 4,4′-methylenebis(2,6-di-isopropyl-N,N-dimethylaniline), 2,4,6-tri-t-butylaniline, 2,4,6-tri-t-butyl-N-methylaniline, 2-chloro-4,6-dimethylaniline, 2,6-dichloro-3-methylaniline, 3-chloro-2,4-difluoroaniline, 2,3,4-trichloroaniline, 2,3,4-trifluoroaniline, 2,3,6-trifluoroaniline, 2,4,6-trifluoroaniline, 2,6-dibromo-4-methylaniline, 3-chloro-2,6-diethylaniline, 4-bromo-2,6-dimethylaniline, 2-chloro-3,5-difluoroaniline, 4-bromo-2,6-difluoroaniline, 2-bromo-4-chloro-6-fluoroaniline, 2,4-dibromo-6-fluoroaniline, 2,6-dibromo-4-fluoroaniline, 2,6-dichloro-4-(trifluoromethyl)aniline, 4-chloro-2,6-dibromoaniline, 2,6-di-t-butyl-4-(dimethylaminomethyl)phenol, 4-amino-2,6-dichlorophenol, 3,4,5-trichloroaniline, 3,4,5-trimethoxyaniline, 3,3′,5,5′-tetramethylbenzidine, 2-bromo-4,6-difluoroaniline, 2,4,6-trichloroaniline, 2,6-dichloro-4-(trifluoromethoxy)aniline, 2-bromo-3,5-bis(trifluoromethyl)aniline, 2,4,6-tribromoaniline, 2-chloro-4-fluoro-5-methylaniline, 2,4,5-trifluoroaniline, 2,4,5-trichloroaniline, 4-chloro-2-methoxy-5-methylaniline, 4-amino-2,5-dimethylphenol, 4-amino-2,6-dibromophenol, 3,5-dichloro-2,6-diethylaniline, 2,3,5,6-tetrachloroaniline, 2,3,5,6-tetrafluoroaniline, 2,3,4,5-tetrafluoroaniline, 2,3,4,6-tetrafluoroaniline, 2-bromo-4,5,6-trifluoroaniline, 6-amino-2,4-dichloro-3-methylphenol, 2,3,5,6-tetrafluoro-4-(trifluoromethyl)aniline, 2,3,4,5,6-pentafluoroaniline, 4,4′-diaminooctafluorobiphenyl, 4-methoxy-3-biphenylamine, 4-bromo-2,3,5,6-tetrafluoroaniline, 1,2-phenylenediamine, N-methyl-1,2-phenylenediamine, 2,3-diaminotoluene, 3,4-diaminotoluene, 3,3′-diaminobenzidine, 4-chloro-1,2-phenylenediamine, 4-methoxy-1,2-phenylenediamine, 4,5-dimethyl-1,2-phenylenediamine, 1,2,4,5-benzenetetramine, 4,5-dichloro-1,2-phenylenediamine, N-phenyl-1,2-phenylenediamine, 1,3-phenylenediamine, N,N-dimethyl-1,3-phenylenediamine, 2,6-diaminotoluene, 2,4-diaminotoluene, 2,4,6-trimethyl-1,3-phenylenediamine, 4-methoxy-1,3-phenylenediamine, 2,4-diaminophenol, 4-(2-hydroxyethylthio)-1,3-phenylenediamine, 1,4-phenylenediamine, N,N-dimethyl-1,4-phenylenediamine, N,N-diethyl-1,4-phenylenediamine, N,N,N′,N′-tetramethyl-1,4-phenylenediamine, N,N′-diphenyl-1,4-phenylenediamine, 2,5-diaminotoluene, 2,5-dimethyl-1,4-phenylenediamine, 2-chloro-1,4-phenylenediamine, 2,5-dichloro-1,4-phenylenediamine, 2-mehoxy-1,4-phenylenediamine, 2,3,5,6-tetramethyl-1,4-phenylenediamine, 2-aminobiphenyl, 4-aminobiphenyl, 2,4,6-triphenylaniline, 2-amino-4-phenylphenol, 5-phenyl-o-anisidine, N,N′-diphenylbenzidine, N-phenyl-1,4-phenylenediamine, N-methyl-4,4′-methylenediamine, 4,4′-methylenebis(N,N-dimethylaniline), 4,4′-methylenebis(N,N-diglycidylaniline), 4,4′-vinylidenebis(N,N-dimethylaniline), 3,3′-(hexafluoroisopropylidene)dianiline, 4,4′-(hexafluoroisopropylidene)dianiline, 2-benzylaniline, 4-triethylaniline, 2′,5′-dimethoxy-4-stilbene, 2-phenoxyaniline, 3-phenoxyaniline, 4-phenoxyaniline, 3,3′-dimethoxybenzidine, 3-benzyloxyaniline, 4-benzyloxyaniline, 3-methyldiphenylamine, 3-mehoxydiphenylamine, 3-hydroxydiphenylamine, N-phenyl-1,4-phenylenediamine, 4,4′-diaminodiphenylamine, tri(4-bromophenyl)amine, 4-amino-2,6-diphenylphenol, N-(4-methoxyphenyl)-1,4-phenylenediamine, 1-aminonaphthalene, N-ethyl-1-naphtylamine, N,N-dimethyl-1-naphthylamine, N-(1-naphthyl)ethylenediamine, N-phenyl-1-naphthylamine, N-phenyl-2-naphthylamine, N-(4-hydroxyphenyl)-2-naphthylamine, 2-aminonaphthalene, 3,3′-dimethylnaphthylidene, 1-amino-4-chloronaphthalene, 1-amino-4-bromonaphthalene, 1-amino-2-naphthol, 4-amino-1-naphthol, 5-amino-1-naphthol, 2,2′-dithiobis(1-naphthylamine), 3-amino-2-naphthol, 2,3-diaminonaphthalene, 1,5-diaminonaphthalene, 1,8-diaminonaphthalene, 1,8-bis(dimethylamino)naphthalene, 1,1′-binaphthyl-2,2′-diamine, 1-aminofluorene, 2-aminofluorene, 2-(dimethylamino)fluorene, 2,7-diaminofluorene, 3,7-diamino-2-methoxyfluorene, 2-amino-7-bromofluorene, 2-amino-9-hydroxyfluorene, 2-amino-3-bromo-9-hydroxyfluorene, 1-aminoanthracene, 2-aminoanthracene, 9-aminophenanthrene, 9,10-diaminophenanthrene, 1-aminopyrene, 6-aminochrysene, benzylamine, α-methylbenzylamine, N,α-dimethylbenzylamine, N-benzyl-α-methylbenzylamine, N,N-dimethyl-1-phenethylamine, aminodiphenylmethane, triphenylamine, 1,2-diphenylethylamine, 2,2-diphenylethylamine, 2-amino-1,2-diphenylethanol, phenethylamine, 2-amino-3-phenyl-1-propanol, 2-phenylcyclopropylamine, 3-phenyl-1-propylamine, 3,3-diphenylpropylamine, 1-methyl-3-phenylpropylamine, 4-phenylbutylamine, N-phenylethylenediamine, 1,2-diphenylethylenediamine, 1,2-bis(4-methoxyphenyl)ethylenediamine, 4-(2,4-di-t-amylphenoxy)butylamine, 2-amino-1-phenylethanol, 2-phenylglycinol, 2-amino-3-phenyl-1-propanol, ephedrine, 2-(dibutylamino)-1-phenyl-1-propanol, N-methylephedrine, 2-amino-1,1-diphenyl-1-propanol, N-benzylmethylamine, N-ethylbenzylamine, N-isopropylbenzylamine, N-butylbenzylamine, N-(t-butyl)benzylamine, dibenzylamine, N,N′-dibenzylethylenediamine, N-methylphenethylamine, N-benzyl-2-phenethylamine, β-methylphenethylamine, N′-benzyl-N,N-dimethylethylenediamine, N-benzylethanolamine, 2-(benzylamino)cyclohexanemethanol, α-(methylaminomethyl)benzyl alcohol, 2-amino-1-phenyl-1,3-propanediol, 2-amino-3-methoxy-1-phenyl-1-propanol, 3-(N-benzyl-N-methylamino)-1,2-propanediol, N,N-dimethylbenzylamine, N,N,N′,N′-tetrabenzylmethanediamine, N-methyldiphenethylamine, tribenzylamine, N,N∝,N″-tribenzyltri(2-aminoethyl)amine, N-(2-chloroethyl)dibenzylamine, N-benzyl-N-methylmethanolamine, 3-(dibenzylamino)-1-propanol, 2-(dibenzylamino)-3-phenyl-1-propanol, N-ethyl-3,3′-diphenyldipropylamine, 2-methylbenzylamine, 1-aminoindane, 1,2,3,4-tetrahydro-1-naphthylamine, 2-aminoindane, 2-(trifluoromethyl)benzylamine, 2-fluorobenzylamine, 2-fluorophenethylamine, 2-chlorobenzylamine, 2-(2-chlorophenyl)ethylamine, 2-bromobenzylamine, 2-methoxybenzylamine, 2-methoxyphenethylamine, 2-ethoxybenzylamine, 2-[2-(aminoethyl)phenylthio]benzyl alcohol, 2-aminobenzylamine, 3-methylbenzylamine, 3-(trifluoromethyl)benzylamine, m-xylenediamine, 3-fluorobenzylamine, 3-fluorophenthylamine, 3-chlorobenzylamine, 2-(3-chlorophenyl)ethylamine, 3-bromobenzylamine, 3-iodobenzylamine, N,N′-dimethyl-1,2-bis [3-(trifluoromethyl)phenyl]-1,2-ethanediamine, 3-methoxy-N,N-dimethylbenzylamine, 3-methoxyphenethylamine, 4-methylbenzylamine, p-xylenediamine, 4-(trifluoromethyl)benzylamine, α,4-dimethylbenzylamine, 2-(p-tolyl)ethylamine, 4-fluorobenzylamine, 4-fluorophenethylamine, 4-chlorobenzylamine, 4-bromobenzylamine, 4-bromo-N,N-di-isopropylbenzylamine, 4-bromophenethylamine, 4-fluoro-α-methylbenzylamine, 4-fluorophenethylamine, 4-fluoro-α,α-dimethylphenethylamine, 2-(4-chlorophenyl)ethylamine, 4-methoxybenzylamine, 4-methoxyphenethylamine, 4-(fluoromethoxy)benzylamine, 4-aminobenzylamine, 4-(hexadecylamino)benzylamine, 4-(dimethylamino)benzylamine, 2-(4-aminophenyl)ethylamine, thiramine, α-(1-aminoethyl)-4-hydroxybenzyl alcohol, 4-chlorophenylalanylol, 3,5-(trifluoromethyl)benzylamine, 3-fluoro-5-(trifluoromethyl)benzylamine, 2,6-difluorobenzylamine, 2,4-difluorobenzylamine, 2,5-difluorobenzylamine, 3,4-difluorobenzylamine, 2,4-dichlorobenzylamine, 3,4-dichlorobenzylamine, 2,4-dichlorophenethylamine, 2,3-dimethoxybenzylamine, 3,5-dimethoxybenzylamine, 2,4-dimethoxybenzylamine, 2,5-dimethoxyphenethylamine, 3,4-dimethoxybenzylamine, 3,4-dimethoxyphenethylamine, N-methyl-3,4-dimethoxybenzylamine, 2-bromo-4,5-dimethoxyphenethylamine, piperonylamine, 1-piperonylpiperazine, 4-hydroxy-3-methoxybenzylamine, 3-(ethylamino)-p-cresol, α-ethyl-3-hydroxy-4-methylphenethylamine, 4-methyl-2-(piperidinomethyl)phenol, 3,4-dihydroxybenzylamine, 3-hydroxythiramine, 3-o-methyldopamine, 4-o-methyldopamine, 3,4-dibenzyloxyphenethylamine, 1-(3,4-dichlorophenyl)-2-isopropylaminoethanol, 4-amino-α-diethylamino-o-cresol, dehyroabiethylamine, 3,4,5-trimethoxybenzylamine, 5-hydroxydopamine, 2,4,6-trimethoxybenzylamine, N-(3-methoxypropyl)-3,4,5-trimethoxybenzylamine, 4-(diethylaminomethyl)-2,5-dimethylphenol, 2,3,6-tri (dimethylaminomethyl)phenol, 6-hydroxydopamine, 1-amino-2-indanol, 1-naphthalenemethylamine, N-methyl-1-naphthalenemethylamine, 1-(1-naphthyl)-ethylamine, 9-aminofluorene, 9-(methylaminomethyl)anthracene, 1-pyrenemethylamine, 1-(diphenylmethyl)azetidine, 1-benzyl-3-pyrroline, 1-benzyl-3-pyrrolidinol, 1-[2-(4-bromophenoxy)ethyl]pyrrolidine, 1-benzyl-2-pyrrolidinemethanol, α,α-diphenyl-2-pyrrolidinemethanol, 1-(3,4-dihydro-2-naphthyl)pyrrolidine, 2-(anilomethyl)pyrrolidine, 4-amino-1-benzylpiperidine, 4-benzylpiperidine, 4-phenyl-1,2,3,6-tetrahydropyridine, 1-methyl-4-phenyl-1,2,3,6-tetrahydropyridine, 4-(4-chlorphenyl)-1,2,3,6-tetrahydropyridine, 4-hydroxy-4-phenylpiperidine, 4-(4-bromophenyl)-4-piperidinol, 1-benzyl-4-hydroxypiperidine, 4-(4-chlorophenyl)-4-hydroxypiperidine, 4-diphenylmethoxy-1-methylpiperidine, 1-phenylpiperazine, 1-benzylpiperazine, trans-1-cinnamylpiperazine, 1-(o-tolyl)piperazine, 1-(2-fluorophenyl)piperazine, 1-(2,3-xylyl)piperazine, 1-(2-chlorophenyl)piperazine, 1-(2-methoxyphenyl)piperazine, 1-(2-ethoxyphenyl)piperazine, 1-[3-(trifluoromethyl)phenyl]piperazine, 1-(3-chlorophenyl)piperazine, 1-(3-chlorophenyl)-4-(3-chloropropyl)piperazine, 1-(4-fluorophenyl)piperazine, 1-(4-chlorophenyl)piperazine, 1-(4-methoxyphenyl)piperazine, 1,3,5-tribenzylhexahydro-1,3,5-triazine, 4-phenylmorpholine, 4-morpholinoaniline, 2,5-dimethyl-4-(morpholinomethyl)phenol, 2,5-diethoxy-4-morpholinoaniline, N,N′-dibenzyl-1,4,10,13-tetraoxa-7,16-diazacyclooctadecane, 5-amino-2,2-dimethyl-4-phenyl-1,3-dioxane, indoline, 2-methylindoline, 1,2,3,4-tetrahydrocarbazole, 2,3-dimethylindoline, 3-amino-1H-isoindole, 2′-methyl-2′,3′,10,11-tetrahydrospiro[5H-diazabicyclo[A,D]cycloheptene-5,1′-[1H]-isoindole], 1′,3′-dihydro-1′,3′,3′-trimethyl-6-nitrospiro [2H-1-benzopyran-2,2′-(2H)-indole], 6-bromo-1′,3′-dihydro-1′,3′,3′-trimethyl-8-nitrospiro[2H-1-benzopyran-2,2-(2H)-indole], indole-2-carboxylic acid, 1,2,3,4-tetrahydroquinoline, 6-fluoro-1,2,3,4-tetrahydro-2-methyl quinoline, 1,2,3,4-tetrahydroisoquinoline, 6,7-dimethoxy-1,2,3,4-tetrahydroisoquinoline, 1-methyl-6,7-dihydroxy-1,2,3,4-tetrahydroisoquinoline, julolidine, 8-hydroxyjulolidine, iminodibenzyl, 5,10-dihydro-5,10-dimethylphenadine, phenoxazine, phenothiazine, 10-methylphenothiazine, 2-chlorophenothiazine, 2-(trifluoromethyl)phenothiazine, Troger's base, laudanosine, 2-phenylglycine, 2,2-diphenylglycine, N-benzylglycine, N-benzyliminodiacetic acid, N-phenylglycine, N,N′-ethylenebis[2-(2-hydroxyphenyl)glycine], N-(4-hydroxyphenyl)glycine, N-(2-carboxyphenyl)glycine, phenylalanine, N,N-dimethylphenylalanine, α-methyl-phenylalanine, β-methyl-phenylalanine, homophenylalanine, S-benzylcysteine, S-trithylcysteine, 2-fluorophenylglycine, 2-fluorophenylalanine, 3-fluorophenylalanine, 4-fluorophenyalanine, 4-chlorophenylalanine, 4-bromophenylalanine, 4-iodophenylalanine, 3,3′,5-tri-iodotyronine, tyroxine, m-tyrosine, 4-hydroxyphenyleneglycine, tyrosine, O-methyltyrosine, 3-fluorotyrosine, 3-iodotyrosine, 3-nitrotyrosine, 3,5-di-iodotyrosine, 3,4-dihydroxyphenylalanine, 3-(2,4,5-trihyroxyphenyl)alanine, 3-aminotyrosine, 4-aminophenylalanine, 4-nitrophenylalanine, 3,5-dinitrotyrosine, α-methyltyrosine, O-benzyltyrosine, 3-(3,4-dihydroxyphenyl)-2-methylalanine, 3-phenylserine, 2,2′-(ethylenedioxy)dianiline-N,N,N′,N′-tetraacetic acid, 2-phenyl-N-(trifluoroacetyl)glycine, N-trithylglycine, N-α-benzoylarginine, carbobenzyloxyglycine, N-acetylphenylalanine, N-(4-aminobenzoyl)-β-alanine, carbobenzyloxyalanine, N-carbobenzyloxy-2-methylalanine, N-carbobenzyloxy-N,2-dimethylalanine, N-carbobenzyloxyisoleucine, N-carbobenzyloxyleucine, N-carbobenzyloxyserine, N-carbobenzyloxythreonine, N-(γ-glutamyl)phenylalanine, N2-carbobenzyloxyarginine, N-α-benzoylarginine ethyl ester, phenylalanine-2-naphthylamide, 4-aminophenylalanine, and 1,2,3,4-tetrahydro-3-isoquinolinecarboxylic acid.

When the at least one compound selected from the amine and pyridine compounds is a pyridine compound, specific examples of the pyridine compound include the following compounds:

Pyridine, 2,2′-dipyridyl, 4,4′-dimethyl-2,2′-dipyridyl, 2,4′-dipyridyl, 4,4′-dipyridyl, 2,2′:6′,2″-terpyridine, 2-picoline, 2-ethylpyridine, 2-propylpyridine, 2-vinylpyridine, 2-(3-pentenyl)pyridine, 1,2-bis(2-pyridyl)ethylene, 2-phenylpyridine, 3-phenylpyridine, 2-benzylpyridine, 3-picoline, 3-ethylpyridine, 3-butylpyridine, 3-benzylpyridine, 4-picoline, 4-ethylpyridine, 4-isopropylpyridine, 4-t-butylpyridine, 4-(1-butylpentyl)pyridine, 1,2-bis(4-pyridyl)ethane, 4,4′-trimethylenedipyridine, trans-1-(2-pyridyl)-2-(4-pyridyl)ethylene, trans-1,2-bis(4-pyridyl)ethylene, 4-vinylpyridine, 5-(4-pyridyl)-2,7-nonadiene, 4-(3-cyclohexene-1-yl)pyridine, 4-phenylpyridine, 2-(p-tolyl)pyridine, 3-methyl-2-phenylpyridine, 4,4′-diphenyl-2,2′-dipyridyl, 4-benzylpyridine, 4-(3-phenylpropyl)pyridine, 2,6-rutidine, 2,6-di-t-butylpyridine, 5,6,7,8-tetrahydroisoquinoline, 2,3-cycloheptenopyridine, 2,3-cyclododecenopyridine, 2,3-rutidine, 2,4-rutidine, 3,4-rutidine, 2,5-rutidine, 5-ethyl-2-methylpyridine, 3,5-rutidine, 3-methyl-5,6,7,8-tetrahyroquinoline, 2,4,6-collidine, 2,6-di-t-butyl-4-methylpyridine, 2,4,6-tri-t-butylpyridine, diphenyl-2-pyridylmethane, diphenyl-4-pyridylmethane, 2-fluroropyridine, 2-chloropyridine, 2-bromopyridine, 2-bromo-5-methylpyridine, 2-picolyl chloride, 3-fluoropyridine, 3-chloropyridine, 3-bromopyridine, 3-picolyl chloride, 4-chloropyridine, 4-bromopyridine, 4-picolyl chloride, 6-chloro-2-picoline, 2-chloro-5-(trifluoromethyl)pyridine, 2,3-dichloropyridine, 2,6-difluoropyridine, 2,6-dichloropyridine, 2,6-bis(chloromethyl)pyridine, 6-chloro-2,2′-bipyridine, 3,5-dichloropyridine, 2,5-dichloropyridine, 2,6-dibromopyridine, 2,6-bis(bromomethyl)pyridine, 2,5-dibromopyridine, 3,5-dibromopyridine, 4′-chloro-2,2,′:6′,2″-terpyridine, 3-chloro-2-fluoro-5-(trifluoromethyl)pyridine, 2,3-dichloro-5-(trifluoromethyl)pyridine, 2,3,5-trichloropyridine, 2,3,5,6-tetrafluoropyridine, 2,3,5,6-tetrafluoro-4-methylpyridine, pentafluoropyridine, 3-chloro-2,4,5,6-tetrafluoropyridine, pentachloropyridine, 4-bromo-2,3,5,6-tetrafluoropyridine, 2-methoxypyridine, 2-(2-isopropoxyethyl)pyridine, 2-(2-propoxyethyl)pyridine, 2-butoxypyridine, 2,6-dimethoxypyridine, 2-chloro-6-methoxypyridine, 2-pyridylcarbinol, 2-(2-hydroxyethyl)pyridine, 2-pyridinepropanol, 3-pyridylcarbinol, 3-pyridinepropanol, 4-pyridylcarbinol, 4-pyridinepropanol, 2,3-di-2-pyridyl-2,3-butanediol, 2,3-di-3-pyridyl-2,3-butanediol, 2-hydroxypyridine, 2-hydroxy-4-methylpyridine, 2-hydroxy-6-methylpyridine, 6-methyl-2-pyridinemethanol, 6-methyl-2-pyridinepropanol, 2-[3-(6-methyl-2-pyridyl)-propoxy]ethanol, 3-hydroxy-2-methylpyridine, 6-chloro-2-pyridinol, 5-chloro-2-pyridinol, 3-chloro-5-(trifluoromethyl)2-pyridonol, 3 -methoxy-2(1H)-pyridone, 4-benzyloxy-2(1H)-pyridone, 2,3-dihydroxypyridine, 2,6-dihydroxypyridine, 5-chloro-2,3-pyridinediol, 4-hydroxypyridine, 3-hydroxypyridine, 2,2′-dipyridine-3,3′-diol, 2,4-dihyroxypyridine, 5-hydroxy-2-methylpyridine, 5-chloro-3-pyridinol, 2-chloro-3-pyridinol, 2-bromo-3-pyridinol, 6-iodo-2-picoline-5-ol, 2,6-pyridinedimethanol, 3-hydroxy-2-(hydroxymethyl)pyridine, 2,6-rutidine-α-2,3-diol, pyridoxine, 2-mercaptopyridine, 4-mercaptopyridine, 2,3,5,6-tetrachloro-4-pyridinethiol, 2-aminopyridine, 2-anilinopyridine, 2-benzylaminopyridine, 2,2′-dipyridylamine, 2-(4-methoxybenzylamino)-pyridine, 2-(methylamino)pyridine, 2-dimethylaminopyridine, 1-(2-pyridyl)piperazine, 2-(aminomethyl)pyridine, 2-(aminoethyl)pyridine, 2-(2-methylaminoethyl)pyridine, 2-(2-piperidinoethyl)pyridine, 2-[4-(dimethylamino)styryl]pyridine, 4-aminopyridine, 4-dimethylaminopyridine, 4-(ethylaminomethyl)pyridine, 4-(aminomethyl)pyridine, 4-[4-(dimethylamino)styryl]pyridine, 4-pyrrolidinopyridine, 4-(4-methylpiperidino)-pyridine, 3-aminopyridine, 3-(aminomethyl)pyridine, nicotine, anabasine, 3-(pyrrole-1-yl-methyl)pyridine, 2-amino-6-picoline, 2-amino-3-picoline, 3-amino-2-chloropyridine, 2,6-diaminopyridine, 2,3-diaminopyridine, 1′,3′-dihydrospiro[cyclohexane-1,2′-[2H]imidazo[4,5-B]pyridine], 2-amino-3-hydroxypyridine, 2-amino-3-benzyloxypyridine, 2-(dimethylaminomethyl)-3-hydroxypyridine, 2,6-bis [(4S)-isopropyl-2-oxazoline-2-yl]pyridine, 2-benzylamino-4-methylpyridine, 2-amino-5-picoline, 2-amino-4-picoline, 2-benzylamino-6-methylpyridine, 3,4-diaminopyridine, 2-amino-5-chloropyridine, 2-amino-5-bromopyridine, 5-amino-2-chloropyridine, 5-amino-2-methoxypyridine, 2-amino-4,6-dimethylpyridine, 2-amino-3 -chloro-5 -(trifluoromethyl)pyridine, 2-amino-3,5-dichloropyridine, 2-amino-3,5-dibromopyridine, 4-amino-2,3,5 -trichloropyridine, 4-amino-2,3,5,6-tetrafluoropyridine, 4-(dimethylamino)-2,3,5,6-tetrafluoropyridine, 4-amino-3-chlro-2,5,6-trifluropyridine, 4-amino-3,5-dichloro-2,6-difluoropyridine, 3-amino-2,6-dimethoxypyridine, 4-(4-nitrobenzyl)pyridine, 2-chloro-3-nitropyridine, 2-chloro-5-nitropyridine, 2-bromo-5-nitropyridine, 2-hydroxy-3-nitropyridine, 3-ethoxy-2-nitropyridine, 2-methoxy-5-nitropyridine, 2-chloro-4-methyl-3-nitropyridine, 2-chloro-6-methoxy-3-nitropyridine, 2-amino-3-nitropyridine, 2-amino-5-nitropyridine, 2-(2-aminoethylamino)-5-nitropyridine, 3-hydroxy-2-nitropyridine, 2-amino-5-bromo-3-nitropyridine, 2,6-dichloro-3-nitropyridine, 2-hydroxy-4-methyl-3-nitropyridine, 2-chloro-3,5-dinitropyridine, 2-amino-4-ethyl-3-nitropyridine, 2-hydroxy-5-nitropyridine, 2-hydroxy-4-methyl-5-nitropyridine, 2-chloro-4-methyl-5-nitropyridine, 2-amino-4-methyl-5-nitropyridine, 3-hydroxy-6-methyl-2-nitropyridine, 2-(benzylthio)-3-nitropyridine, 2,2′-dithiobis(5-nitropyridine), 2-acetylpyridine, 2-benzoylpyridine, di-2-pyridyl ketone, 2-methyl-1,2-di-3-pyridyl-1-propanone, 3-acetylpyridine, 3-benzoylpyridine, 4-acetylpyridine, 4-benzoylpyridine, 4-(4-chlorobenzoyl)pyridine, 2,6-diacetylpyridine, 3,5-diacetyl-2,6-dimethylpyridine, 3-acetyl-2,6-bis(t-butylamino)-4-methylpyridine, 2-pyridinecarboxyaldehyde, 3-pyridinecarboxyaldehyde, 4-pyridinecarboxyaldehyde, 6-methyl2-pyridinecarboxyaldehyde, 2,6-pyridinedicarboxyaldehyde, picolinic acid, 2-pyridylacetic acid, nicotinic acid, sodium nicotinate, 3-pyridineacetic acid, 2,2′-bipyridine-4,4′-dicarboxylic acid, trans-3-(3-pyridyl)acrylic acid, isonicotinic acid, 4-pyridineacetic acid, (4-pyridylthio)acetic acid, 2-methylnicotinic acid, 6-methylnicotinic acid, 2-chloronicotinic acid, 5-bromonicotinic acid, 6-chloronicotinic acid, 2-chloro-6-methylnicotinic acid, 2,6-dichloronicotinic acid, 5,6-dichloronicotinic acid, 6-hydroxypicolinic acid, 6-hydroxynicotinic acid, 3-hydroxypicolinic acid, 2-hydroxynicotinic acid, 2-hydroxy-6-methylpyridine-3-carboxylic acid, 5-chloro-6-hydroxynicotinic acid, 2,6-dimethoxynicotinic acid, 2-mercaptonicotinic acid, 6-mercaptonicotinic acid, 2-(methylthio)nicotinic acid, 6,6′--dithiodinicotinic acid, citradinic acid, 2-aminonicotinic acid, 6-aminonicotinic acid, N-[5-(trifluoromethyl)-2-pyridyl]valine, 4-amino-3,5,6-trichloropicolinic acid, 3-benzoyl-2-pyridinecarboxylic acid, 2,3-pyridinedicarboxylic acid, 2,4-pyridinedicarboxylic acid, 3,4-pyridinedicarboxylic acid, 2,5-pyridinedicarboxylic acid, 3,5-pyridinedicarboxylic acid, 2,6-pyridinedicarboxylic acid, 6-methyl-2,3-pyridinedicarboxylic acid, 2,6-dimethyl-3,5-pyridinedicarboxylic acid, methyl 2-pyridylacetate, ethyl 2-pyridylacetate, 2-(trifluoroacetoxy)pyridine, 3-acetoxypyridine, ethyl picolinate, methyl nicotinate, di-2-pyridyl thionocarbonate, ethyl nicotinate, isopropyl nicotinate, butyl nicotinate, hexyl nicotinate, benzyl nicotinate, methyl 6-methylnicotinate, ethyl 2-methylnicotinate, ethyl 3-pyridylacetate, diethyl(6-methyl-2-pyridylaminomethylene) malonate, dimethyl 2,6-pyridinedicarbonate, diethyl 3,4-pyridinedicarbonate, diethyl 2,6-dimethyl-3,5-pyridinedicarbonate, dibutyl 2,6-pyridinedicarbonate, methyl isonicotinate, ethyl isonicotinate, ethyl 4-pyridylacetate, 2,3-pyridinedicarboxylic acid anhydride, 3,4-pyridinedicarboxylic acid anhydride, picolinamide, nicotinamide, 6-methylnicotinamide, thionicotinamide, N-methylnicotinamide, N-methyl-N-(2-pyridyl)formamide, N,N-diethylnicotinamide, isonicotinamide, thioisonicotinamide, N-(hydroxymethyl)nicotinamide, N-(2-hydroxyethyl)isonicotinamide, N,N-bis (2-hydroxyethyl)isonicotinamide, 6-chloronicotinamide, 2-chloronicotinamide, 3-hydroxypicolinamide, 6-aminonicotinamide, 3,4-pyridinedicarboxyamide, 3,4-pyridinedicarboxyimide, methyl 3-pyridylcarbamate, 1-(3-pyridyl methyl)urea, 1,3-bis(3-pyridylmethyl)-2-thiourea, 2H-pyrido[3,2B]-1,4-oxazine-3(4H)-one, 2-cyanopyridine, 2-pyridylacetonitrile, 3-cyanopyridine, 3-pyridylacetonitrile, 4-cyanopyridine, 4-pyridylacetonitrile, 3-(3-pyridylmethylamino)-propionitrile, 3,4-pyridinedicarbonitrile, 2-chloro-6-methyl-3-pyridinecarbonitrile, 3-cyano-4,6-dimethyl-2-hydroxypyridine, 2,6-dihydroxy-4-methyl-3-pyridinecarbonitrile, 2,3,5,6-tetrafluoro-4-pyridinecarbonitrile, 3-pyridinesulfonic acid, 2-pyridineethanesulfonic acid, 3-pyridylhydroxymethanesulfonic acid, and 4-pyridineethanesulfonic acid.

<Phthalocyanine Dye Soluble in Organic Solvent>

The negative curable dye-containing composition of the invention contains at least one phthalocyanine dye soluble in an organic solvent as at least one coloring agent. Any phthalocyanine dye soluble in an organic solvent may be used in the invention without limitation.

Examples of the phthalocyanine dye soluble in an organic solvent include those described in JP-A Nos. H05-333207, H06-51115 and H06-194828. The phthalocyanine dye soluble in an organic solvent is preferably a dye compound represented by the following Formula (I) or (II).

[Dye Compound Represented by Formula (I)]

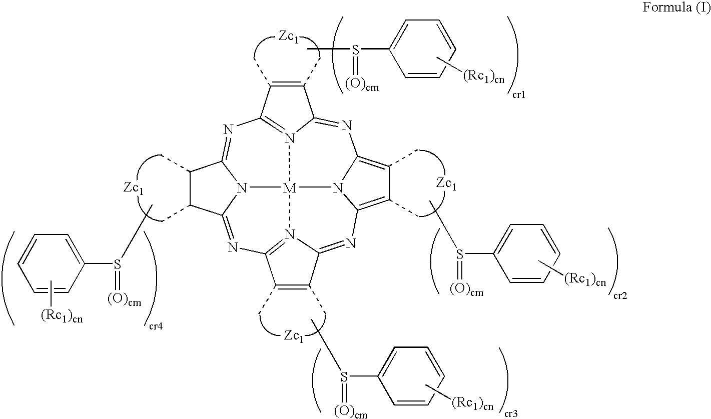

In Formula (I), Rc₁ represents a halogen atom, an aliphatic group, an aryl group, a heterocyclic group, a cyano group, a carboxyl group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a heterocyclic oxy group, an aliphatic oxycarbonyloxy group, an N-alkylacylamino group, a carbamoylamino group, a sulfamoylamino group, an aliphatic oxycarbonylamino group, an aryloxycarbonylamino group, an aliphatic sulfonylamino group, an arylsulfonylamino group, an aliphatic thio group, an arylthio group, an aliphatic sulfonyl group, an arylsulfonyl group, a sulfamoyl group, a sulfo group, an imide group, or a heterocyclic thio group. Zc₁ denotes a nonmetallic atomic group that, together with carbon atoms, form a six-membered ring and four Zc₁s may be the same or different. M denotes two hydrogen atoms, a divalent metal atom, a divalent metal oxide, a divalent metal hydroxide, or a divalent metal chloride. cm is 0, 1 or 2, cn is 0 or an integer of 1 to 5, and four cns may be the same or different. However, one of the cns is an integer of 1 to 5, and plural Rc₁s in the molecule may be the same or different. cr1, cr2, cr3, and cr4 each represent 0 or 1, and satisfy the relation of cr1+cr2+cr3+cr4≧1.

In Formula (I), the term “aliphatic” means groups having a linear, branched, or cyclic, saturated or unsaturated aliphatic moiety, and examples of such groups include alkyl groups, alkenyl groups, cycloalkyl groups, and cycloalkenyl groups. These groups may not have a substituent or may have at least one substituent. The term “aryl” means monocyclic or condensed cyclic, substituted or unsubstituted groups. The term “heterocyclic” means monocyclic or condensed cyclic, saturated or unsaturated, substituted or unsubstituted, monocyclic or condensed cyclic groups having at least one hetero atom (for example, a nitrogen atom, a sulfur atom, or an oxygen atom) therein.

In Formula (I), the term “substituent” may be any group that can be substituted for a hydrogen atom of the compound of Formula (I). Examples thereof include an aliphatic group, an aryl group, a heterocyclic group, an acyl group, an imide group, an azo group, an acyloxy group, an acylamino group, an aliphatic oxy group, an aryloxy group, a heterocyclic oxy group, an aliphatic oxycarbonyl group, an aryloxycarbonyl group, a heterocyclic oxycarbonyl group, a carbamoyl group, an aliphatic sulfonyl group, an arylsulfonyl group, a heterocyclic sulfonyl group, an aliphatic sulfonyloxy group, an arylsulfonyloxy group, a heterocyclic sulfonyloxy group, a sulfamoyl group, an aliphatic sulfonamide group, an arylsulfonamide group, a heterocyclic sulfonamide group, an amino group, an aliphatic amino group, an arylamino group, a heterocyclic amino group, an aliphatic oxycarbonylamino group, an aryloxycarbonylamino group, a heterocyclic oxycarbonylamino group, an aliphatic sulfinyl group, an arylsulfinyl group, an aliphatic thio group, an arylthio group, a heterocyclic thio group, a hydroxy group, a cyano group, a sulfo group, a carboxyl group, an aliphatic oxyamino group, an aryloxyamino group, a carbamoylamino group, a sulfamoylamino group, a halogen atom, a sulfamoylcarbamoyl group, a carbamoylsulfamoyl group, a dialiphatic oxyphosphinyl group, and a diaryloxyphosphinyl group.

In Formula (I), Rc₁ represents a halogen atom, an aliphatic group, an aryl group, a heterocyclic group, a cyano group, a carboxyl group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a heterocyclic oxy group, an aliphatic oxycarbonyloxy group, an N-alkylacylamino group, a carbamoylamino group, a sulfamoylamino group, an aliphatic oxycarbonylamino group, an aryloxycarbonylamino group, an aliphatic sulfonylamino group, an arylsulfonylamino group, an aliphatic thio group, an arylthio group, an aliphatic sulfonyl group, an arylsulfonyl group, a sulfamoyl group, a sulfo group, an imide group, and a heterocyclic thio group.

Examples of the halogen atom represented by Rc₁ include a fluorine atom, a chlorine atom, and a bromine atom.

The aliphatic group represented by Rc₁ may have at least one substituent, or may not have a substituent. The aliphatic group may be saturated or unsaturated, and may be cyclic. The aliphatic group preferably has 1 to 15 carbon atoms in total. Examples thereof include a methyl group, an ethyl group, a vinyl group, an allyl group, an ethinyl group, an isopropenyl group, and a 2-ethylhexyl group.

The aryl group represented by Rc₁ may have at least one substituent, or may not have a substituent. The aryl group preferably has 6 to 16 carbon atoms in total, and more preferably has 6 to 12 carbon atoms in total. Examples thereof include a phenyl group, a 4-nitrophenyl group, a 2-nitrophenyl group, a 2-chlorophenyl group, a 2,4-dichlorophenyl group, a 2,4-dimethylphenyl group, a 2-methylphenyl group, a 4-methoxyphenyl group, a 2-methoxyphenyl group, and a 2-methocycarbonyl-4-nitrophenyl group.

The heterocyclic group represented by Rc₁ may be saturated or unsaturated, and preferably has 1 to 15 carbon atoms in total, and more preferably has 3 to 10 carbon atoms in total. Examples thereof include a 3-pyridyl group, a 2-pyridyl group, a 2-pyrimidinyl group, a 2-pyrazinyl group, and a 1-piperidyl group. The heterocyclic group may have at least one substituent.

The carbamoyl represented by Rc₁ may have at least one substituent, or may not have a substituent. The carbamoyl group preferably has 1 to 16 carbon atoms in total, and more preferably has 1 to 12 carbon atoms in total. Examples thereof include a carbamoyl group, a dimethylcarbamoyl group, and a dimethoxycarbamoyl group.

The aliphatic oxycarbonyl group represented by Rc₁ may have at least one substituent, or may not have a substituent. The aliphatic oxycarbonyl group may be saturated or unsaturated, or may be cyclic. The aliphatic oxycarbonyl group preferably has 2 to 16 carbon atoms in total, and more preferably has 2 to 10 carbon atoms in total. Examples thereof include a methoxycarbonyl group and a butoxycarbonyl group.

The aryloxycarbonyl group represented by Rc₁ may have at least one substituent, or may not have a substituent. The aryloxycarbonyl group preferably has 7 to 17 carbon atoms in total, and more preferably has 7 to 15 carbon atoms in total. The aryloxycarbonyl group is, for example, a phenoxycarbonyl group.

The acyl group represented by Rc₁ may be an aliphatic carbonyl group or an aryl carbonyl group, and may have at least one substituent, and may be saturated or unsaturated, and may be cyclic. The acyl group preferably has 2 to 15 carbon atoms in total, and more preferably has 2 to 10 carbon atoms in total. Examples thereof include an acetyl group, a pivaloyl group, and a benzoyl group.

The aliphatic oxy group represented by Rc₁ may have at least one substituent, or may not have a substituent. The aliphatic oxy group may be saturated or unsaturated, and may be cyclic. The aliphatic oxy group preferably has 1 to 12 carbon atoms in total, and more preferably has 1 to 10 carbon atoms in total. Examples thereof include a methoxy group, an ethoxyethoxy group, a phenoxyethoxy group, and a thiophenoxyethoxy group.

The aryloxy group represented by Rc₁ may have at least one substituent, or may not have a substituent. The aryloxy group preferably has 6 to 18 carbon atoms in total, and more preferably has 6 to 14 carbon atoms in total. Examples thereof include a phenoxy group, and a 4-methylphenoxy group.

The acyloxy group represented by Rc₁ may have at least one substituent, or may not have a substituent. The acyloxy group preferably has 2 to 14 carbon atoms in total, and more preferably has 2 to 10 carbon atoms in total. Examples thereof include an acetoxy group, a methoxyacetoxy group, and a benzoyloxy group.

The carbamoyloxy group represented by Rc₁ may have at least one substituent, or may not have a substituent. The carbamoyloxy group preferably has 1 to 16 carbon atoms in total, and more preferably has 1 to 12 carbon atoms in total. Examples thereof include a dimethylcarbamoyloxy group, and a di-isopropylcarbamoyloxy group.

The heterocyclic oxy group represented by Rc₁ may have at least one substituent, or may not have a substituent. The heterocyclic oxy group preferably has 1 to 15 carbon atoms in total, and more preferably has 3 to 10 carbon atoms in total. Examples thereof include a 3-pyridyloxy group, a 3-pyridyloxy group, and an N-methyl-2-piperidyloxy group.

The aliphatic oxycarbonyloxy group represented by Rc₁ may have at least one substituent, or may not have a substituent. The aliphatic oxycarbonyloxy grou may be saturated or unsaturated, and may be cyclic. The liphatic oxycarbonyloxy group preferably has 2 to 16 carbon atoms in total, and more preferably has 2 to 10 carbon atoms in total. Examples thereof include a methoxycarbonyloxy group, and a t-butoxycarbonyloxy group.

The N-alkylacylamino group represented by Rc₁ may have at least one substituent, or may not have a substituent. The N-alkylacylamino group preferably has 3 to 15 carbon atoms in total, and more preferably has 3 to 12 carbon atoms in total. Examples thereof include an N-methylacetylamino group, an N-ethoxyethylbenzoylamino group, and an N-methylmethoxyacetylamino group.

The carbamoylamino group represented by Rc₁ may have at least one substituent, or may not have a substituent. The carbamoylamino group preferably has 1 to 16 carbon atoms in total, and more preferably has 1 to 12 carbon atoms in total. Examples thereof include an N,N-dimethylcarbamoylamino group, and an N-methyl-N-methoxyethylcarbamoylamino group.

The sulfamoylamino group represented by Rc₁ may have at least one substituent, or may not have a substituent. The sulfamoylamino group preferably has 0 to 16 carbon atoms in total, and more preferably has 0 to 12 carbon atoms in total. Examples thereof include an N,N-dimethylsulfamoylamino group, and an N,N-diethylsulfamoylamino group.

The aliphatic oxycarbonylamino group represented by Rc₁ may have at least one substituent, or may not have a substituent. The aliphatic oxycarbonylamino group preferably has 2 to 15 carbon atoms in total, and more preferably has 2 to 10 carbon atoms in total. Examples thereof include a methoxycarbonylamino group, and a methoxyethoxycarbonylamino group.

The aryloxycarbonylamino group represented by Rc₁ may have at least one substituent, or may not have a substituent. The aryloxycarbonylamino group preferably has 7 to 17 carbon atoms in total, and more preferably has 7 to 15 carbon atoms in total. Examples thereof include a phenoxycarbonylamino group, and a 4-methoxycarbonylamino group.

The aliphatic sulfonylamino group represented by Rc₁ may have at least one substituent, or may not have a substituent. The aliphatic sulfonylamino group may be saturated or unsaturated, and may be cyclic. The aliphatic sulfonylamino group preferably has 1 to 12 carbon atoms in total, and more preferably has 1 to 8 carbon atoms in total. Examples thereof include a methanesulfonylamino group, and a butanesulfonylamino group.

The arylsulfonylamino group represented by Rc₁ may have at least one substituent, or may not have a substituent. The arylsulfonylamino group preferably has 6 to 15 carbon atoms in total, and more preferably has 6 to 12 carbon atoms in total. Examples thereof include a benzenesulfonylamino group, and a 4-toluenesulfonylamino group.

The aliphatic thio group represented by Rc₁ may have at least one substituent, or may not have a substituent. The aliphatic thio group may be saturated or unsaturated, and may be cyclic. The aliphatic thio group preferably has 1 to 16 carbon atoms in total, and more preferably has 1 to 10 carbon atoms in total. Examples thereof include a methylthio group, an ethylthio group, and an ethoxyethylthio group.

The arylthio group represented by Rc₁ may have at least one substituent, or may not have a substituent. The arylthio group preferably has 6 to 22 carbon atoms in total, and more preferably has 6 to 14 carbon atoms in total. Examples thereof include a phenylthio group, and a 2-t-butylthio group.

The aliphatic sulfonyl group represented by Rc₁ may have at least one substituent, or may not have a substituent. The aliphatic sulfonyl group preferably has 1 to 15 carbon atoms in total, and more preferably has 1 to 8 carbon atoms in total. Examples thereof include a methanesulfonyl group, a butanesulfonyl group, and a methoxyethanesulfonyl group.

The arylsulfonyl group represented by Rc₁ may have at least one substituent, or may not have a substituent. The arylsulfonyl group preferably has 6 to 16 carbon atoms in total, and more preferably has 6 to 12 carbon atoms in total. Examples thereof include a benzenesulfonyl group, a 4-t-butylbenzenesulfonyl group, a 4-toluenesulfonyl group, and a 2-toluenesulfonyl group.

The sulfamoyl group represented by Rc₁ may have at least one substituent, or may not have a substituent. The sulfamoyl group preferably has 0 to 16 carbon atoms in total, and more preferably has 0 to 12 carbon atoms in total. Examples thereof include a sulfamoyl group, and a dimethylsufamoyl group.

The imide group represented by Rc₁ may be further condensed. The imide group preferably has 3 to 22 carbon atoms in total, and more preferably has 3 to 15 carbon atoms in total. Examples thereof include a succinic acid imide group, and a phthalic acid imide group.

The heterocyclic thio group represented by Rc₁ may have at least one substituent, or may not have a substituent. The heterocyclic thio group is preferably a five- to seven-membered cyclic group, and preferably has 1 to 20 carbon atoms in total, and more preferably has 1 to 12 carbon atoms in total. Examples thereof include a 3-furylthio group, and a 3-pyridylthio group.

In Formula (I), Zc₁ denotes a nonmetallic atomic group necessary to form, together with carbon atoms, a six-membered ring, and four Zc₁s may be the same or different. The six-membered ring to be formed may be either an aryl ring or a hetero ring, and may be condensed. Such a condensed ring may further have at least one substituent. Examples of the six-membered ring include a benzene ring, a pyridine ring, a cyclohexene ring, and a naphthlalene ring. The six-membered ring is preferably a benzene ring.

In Formula (I), M denotes two hydrogen atoms, a divalent metal atom, a divalent metal oxide, a divalent metal hydroxide, or a divalent metal chloride. Examples of M include VO, TiO, Zn, Mg, Si, Sn, Rh, Pt, Pd, Mo, Mn, Pb, Cu, Ni, Co, Fe, AlCl, InCl, FeCl, TiCl₂, SnCl₂, SiCl₂, GeCl₂, Si(OH)₂, and H₂. M is preferably VO, Zn, Mn, Cu, Ni, or Co.

In Formula (I), cm is 0, 1 or 2 and is preferably 0, and cn is 0 or an integer of 1 to 5 and is preferably 0 or 1. Four cns in the molecule may be the same or different. Here, one of cns is an integer of 1 to 5. When the compound of Formula (I) has plural Rc₁s, the plural Rc₁s in the molecule may be the same or different.

cr1, cr2, cr3, and cr4 independently represent 0 or 1, and satisfy the relation of cr1+cr2+cr3+cr4≧1. Preferably, the sum of cr1, cr2, cr3 and cr4 is 3 or 4.

The dye compound represented by Formula (I) is preferably a dye represented by the following Formula (I-1) (phthalocyanine dye in the invention) to more effectively exhibit the effect of the invention.

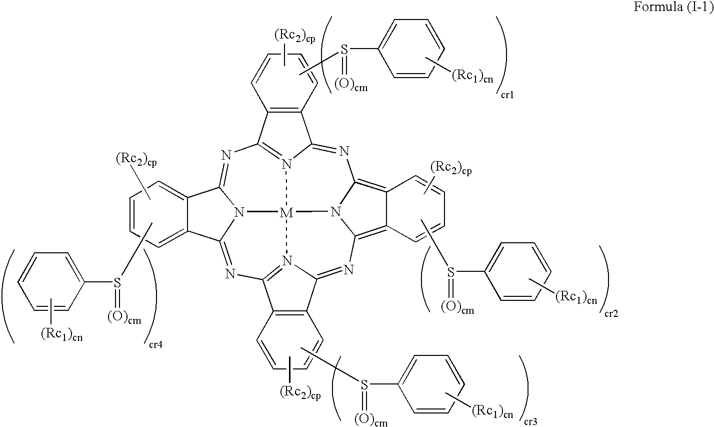

In Formula (I-1), Rc₂ is a substituent, and the substituent is any of groups that can be substituted for a hydrogen atom of the compound of Formula (I-1). Examples thereof include those disclosed in the explanations for the aforementioned substituent. The substituent is preferably an aliphatic group, an aryl group, a heterocyclic group, an N-alkylacylamino group, an aliphatic oxy group, an aryloxy group, a heterocyclic oxy group, an aliphatic oxycarbonyl group, an aryloxycarbonyl group, a heterocyclic oxycarbonyl group, a carbamoyl group, an aliphatic sulfonyl group, a sulfamoyl group, an aliphatic sulfonamide group, an arylsulfonamide group, an aliphatic amino group, an arylamino group, an aliphatic oxycarbonylamino group, an aryloxycarbonylamino group, an aliphatic thio group, an arylthio group, a hydroxy group, a cyano group, a sulfo group, a carboxyl group, a carbamoylamino group, a sulfamoylamino group, or a halogen atom, and more preferably an aliphatic group, an N-alkylacylamino group, an aliphatic oxy group, an aliphatic oxycarbonyl group, an aliphatic sulfonyl group, an aliphatic thio group, an arylthio group, a sulfo group, a carboxyl group, or a halogen atom.

In Formula (I-1), cp is an integer of 0 to 4, and preferably 0 or 1. Here, the sum of cp and cr1, that of cp and cr2, that of cp and cr3, and that of cp and cr4 may be independently an integer of 0 to 4. When the compound of Formula (I-1) has plural Rc₂s in the molecule, the plural Rc₂s may be the same or different.

Rc₁, M, cm, cn, and cr1, cr2, cr3, and cr4 in Formula (I-1) have the same meanings as in Formula (I), and preferred examples thereof are also the same as in Formula (I).

The dye compound represented by Formula (I-1) is preferably a dye represented by the following Formula (I-2) (phthalocyanine dye in the invention) to more effectively exhibit the effect of the invention.

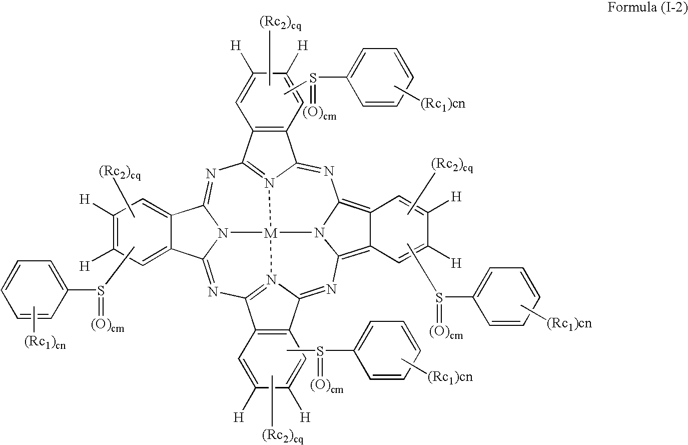

Rc₁, Rc₂, M, cm, and cn in Formula (I-2) have the same meanings as in Formulae (I) and (I-1j), and preferred examples thereof are also the same as in Formulae (I) and (I-1). In Formula (I-2), cq is 0 or 1. A phthalocyanine skeleton has a structure in which four benzene rings are condensed with the outer side of a tetraazaporphyrin skeleton, and each of the benzene rings has four sites (carbon atoms) into each of which a substituent can be introduced. In Formula (I-2), hydrogen atoms are bonded to sites (β-positions) far from the tetra-azaporphyrin skeleton of each of the benzene rings.

In Formula (I-2), to more effectively exhibit the effect of the invention, Rc₁ is preferably a halogen atom, an aliphatic group, a cyano group, a carbamoyl group, an aliphatic oxycarbonyl group, an aryloxycarbonyl group, a hydroxy group, an aliphatic oxy group, a carbamoyloxy group, a heterocyclic oxy group, an aliphatic oxycarbonyloxy group, a carbamoylamino group, a sulfamoylamino group, an aliphatic oxycarbonylamino group, an aliphatic sulfonylamino group, an arylsulfonylamino group, an aliphatic thio group, an arylthio group, an aliphatic sulfonyl group, an arylsulfonyl group, a sulfamoyl group, an imide group, or a sulfo group, and is more preferably an aliphatic group, a carbamoyl group, an aliphatic oxycarbonyl group, an aryloxycarbonyl group, an aliphatic oxy group, an aliphatic oxycarbonyloxy group, a carbamoylamino group, a sulfamoylamino group, an aliphatic oxycarbonylamino group, an aliphatic sulfonylamino group, an arylsulfonylamino group, an aliphatic sulfonyl group, an arylsulfonyl group, a sulfamoyl group, an imide group, or a sulfo group, and is most preferably a carbamoyl group, an aliphatic oxycarbonyl group, an aliphatic oxy group, an aliphatic oxycarbonyloxy group, a carbamoylamino group, an aliphatic oxycarbonylamino group, an arylsulfonyl group, an imide group, or an aliphatic sulfonyl group.

To more effectively exhibit the effect of the invention, Rc₂ is preferably an aliphatic group, an N-alkylacylamino group, an aliphatic oxy group, an aliphatic oxycarbonyl group, an aliphatic sulfonyl group, an aliphatic thio group, an arylthio group, a sulfo group, a carboxyl group, or a halogen atom, and more preferably an aliphatic group or a halogen atom. To more effectively exhibit the effect of the invention, cq is preferably 0. Also, to more effectively exhibit the effect of the invention, M is preferably VO, Mn, Co, Ni, Cu, Zn or Mg, more preferably VO, Co, Cu or Zn, and most preferably Cu. cm is preferably 0. cn is preferably 1 or 2, and more preferably 1.

To still more effectively exhibit the effect of the invention, the compound of Formula (I-2) is preferably a compound where Rc₁ is a halogen atom, an aliphatic group, a cyano group, a carbamoyl group, an aliphatic oxycarbonyl group, an aryloxycarbonyl group, a hydroxy group, an aliphatic oxy group, a carbamoyloxy group, a heterocyclic oxy group, an aliphatic oxycarbonyloxy group, a carbamoylamino group, a sulfamoylamino group, an aliphatic oxycarbonylamino group, an aliphatic sulfonylamino group, an arylsulfonylamino group, an aliphatic thio group, an arylthio group, an aliphatic sulfonyl group, an arylsulfonyl group, a sulfamoyl group, an imide group, or a sulfo group, M is VO, Co, Cu, or Z, cq is 0, cm is 0, and cn is 1, and is more preferably a compound where Rc₁ is an aliphatic group, a carbamoyl group, an aliphatic oxycarbonyl group, an aryloxycarbonyl group, an aliphatic oxy group, an aliphatic oxycarbonyloxy group, a carbamoylamino group, a sulfamoylamino group, an aliphatic oxycarbonylamino group, an aliphatic sulfonylamino group, an arylsulfonylamino group, an aliphatic sulfonyl group, an arylsulfonyl group, a sulfamoyl group, an imide group, or a sulfo group, M is VO, Co, Cu, or Zn, cq is 0, cm is 0, and cn is 1.

From the viewpoint of the effect of the invention, the compound of Formula (I-2) is most preferably a compound where Rc₁ is a carbamoyl group, an aliphatic oxycarbonyl group, an aliphatic oxy group, a carbamoylamino group, an aliphatic oxycarbonylamino group, an aliphatic sulfonyl group, an arylsulfonyl group, or an imide group, M is Cu, cq is 0, cm is 0, and cn is 1.

Specific examples of the dye represented by Formulae (I) to (I-2) are shown below (exemplary compounds C-1 to C-59). However, the invention is not limited by these examples.

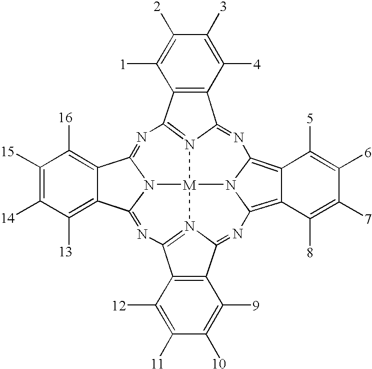

| | | Substituents at 1- or 4- | Substituents |
|---|---|---|---|
| Ex. Comp. | M | position, 5- or 8- position, 9- or 12- position, and 13- or 16- position *1 | at 2-, 3-, 6-, 7-, 10-, 11-, 14- and 15- positions |
| C-1 | Cu | 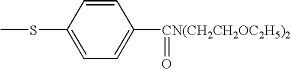 | H |
| C-2 | Cu | 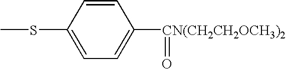 | H |
| C-3 | Cu | 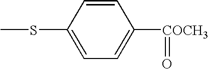 | H |
| C-4 | Cu | 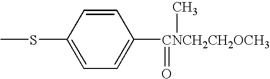 | H |
| C-5 | Cu | 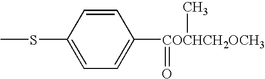 | H |
| C-6 | Cu | 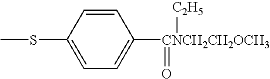 | H |
| C-7 | Cu | 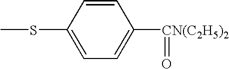 | H |
| C-8 | Cu | 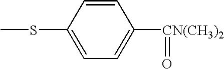 | H |
| C-9 | Cu | 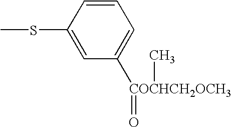 | H |
| C-10 | Cu | 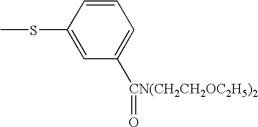 | H |
| C-11 | Cu | 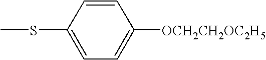 | H |
| C-12 | Cu | 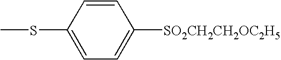 | *2 |
| C-13 | Cu | 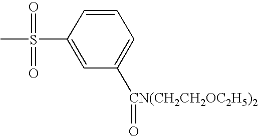 | H |
| C-14 | Cu | 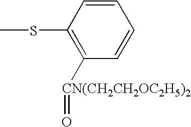 | H |
| C-15 | Cu | 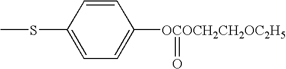 | *3 |
| C-16 | Cu | 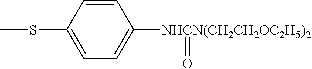 | H |
| C-17 | Cu | 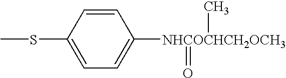 | H |
| C-18 | Cu | 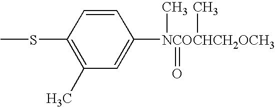 | H |
| C-19 | Cu | 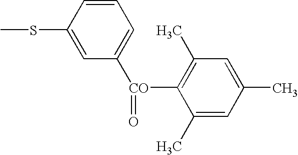 | H |
| C-20 | Cu | 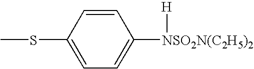 | H |
| C-21 | Cu | 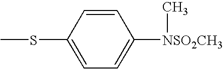 | H |
| C-22 | Cu | 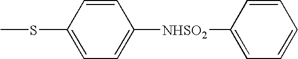 | H |
| C-23 | Cu | 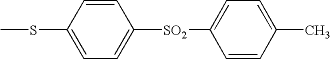 | H |
| C-24 | Cu | 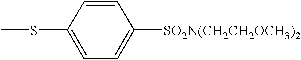 | H |
| C-25 | Cu | 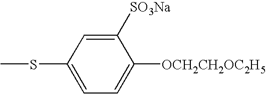 | H |
| C-26 | V═O | 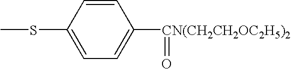 | H |
| C-27 | Co | 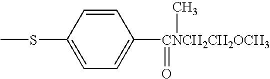 | H |
| C-28 | Co | 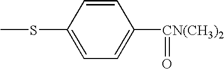 | H |
| C-29 | Zn | 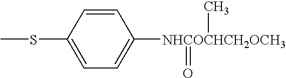 | H |
| C-30 | V═O | 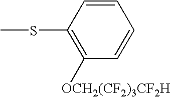 | H |
| C-31 | Cu | 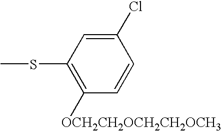 | H |
| C-32 | Cu | 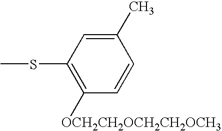 | H |
| C-33 | Cu | 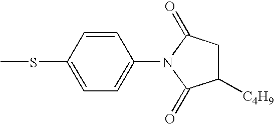 | H |
| C-34 | Cu | 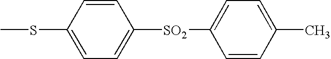 | H |
| C-35 | Cu | 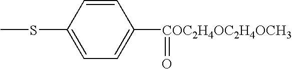 | H |
| C-41 | Cu | 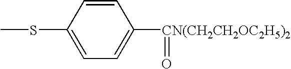 | H |
| C-42 | Cu | 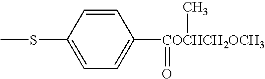 | H |
| C-43 | Cu | 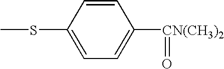 | H |
| C-44 | Cu | 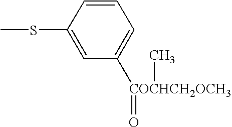 | H |
| C-45 | Co | 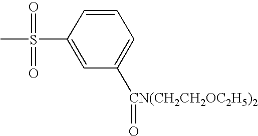 | H |
| C-46 | Zn | 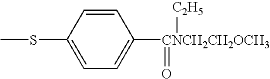 | H |
| C-47 | V═O | 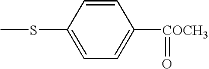 | H |
| C-48 | Cu | 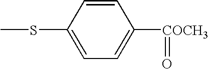 | *4 |
| C-49 | Cu | 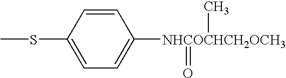 | H |

Note)
*1 Hydrogen atoms are present at the remaining four positions.
*2 CH₃ groups are present at one of 2- and 3-positions, and one of 6- and 7-positions, and one of 10- and 11-positions, and one of 14- and 15-positions, and hydrogen atoms are present at the remaining four positions.
*3 CH₃ groups are present at one of 2- and 3-positions, and one of 6- and 7-positions, and one of 10- and 11-positions, and one of 14- and 15-positions, and hydrogen atoms are present at the remaining four positions.
*4 CH₃ groups are present at one of 1- and 4-positions, and one of 5- and 8-positions, and one of 9- and 12-positions, and one of 13- and 16-positions, and hydrogen atoms are present at the remaining four positions.

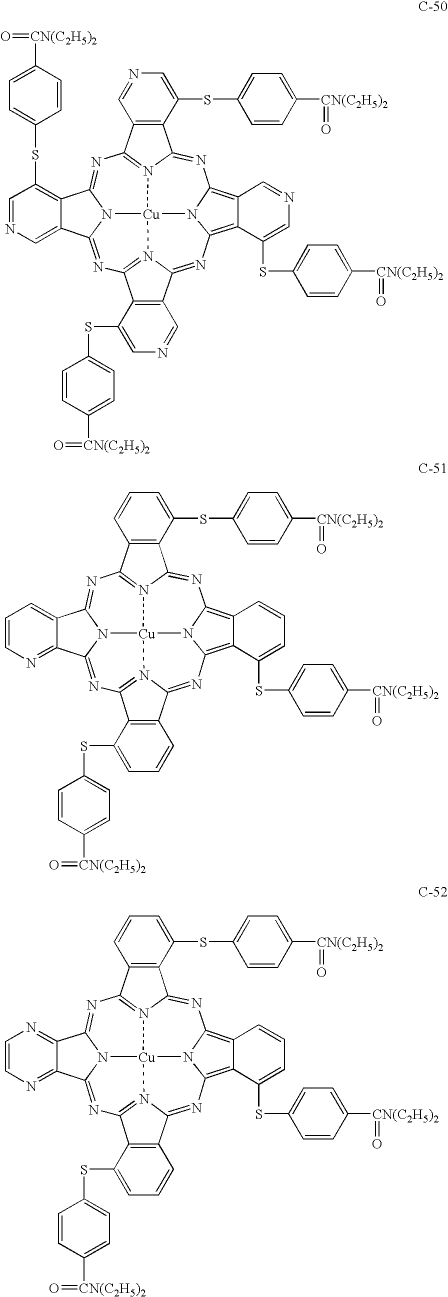 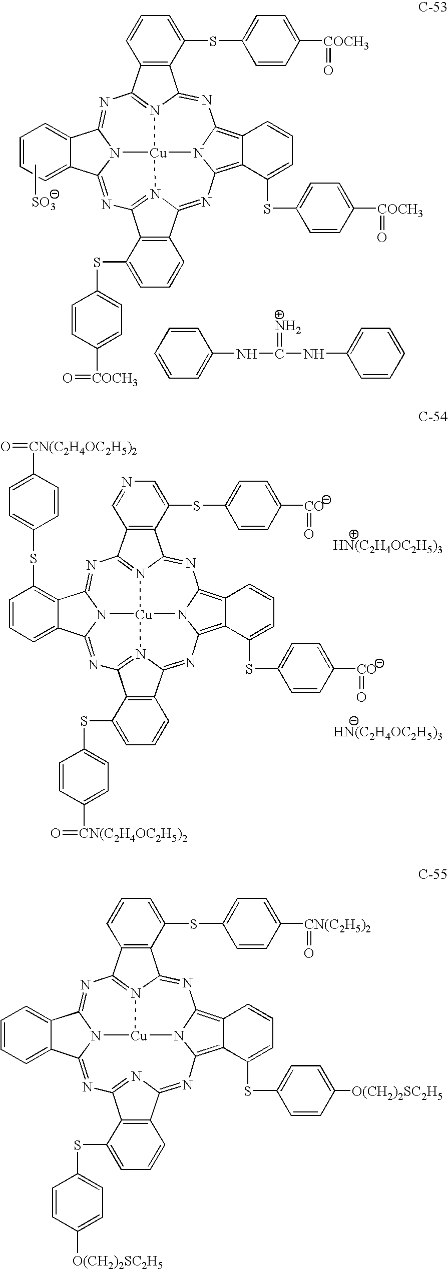 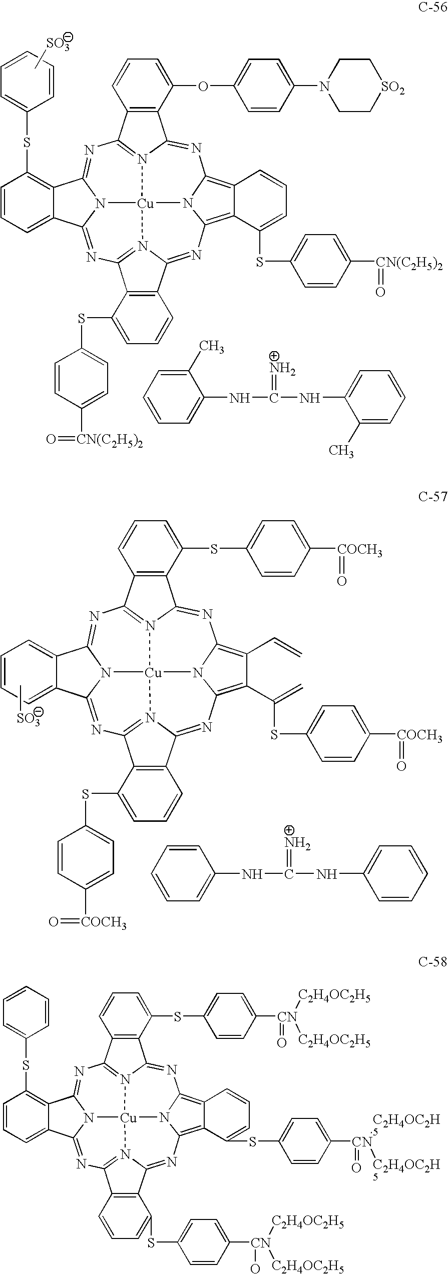 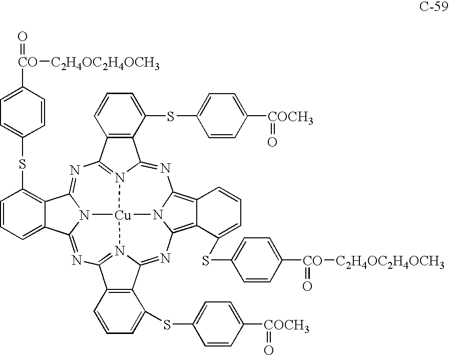 [Dye compound represented by Formula (II)]

Hereinafter, a dye compound represented by Formula (II) will be explained. The dye compound represented by Formula (II) is a phthalocyanine dye that is soluble in an organic solvent and that has a good molar extinction coefficient ε and a good color value. The dye compound has both high light fastness and high heat resistance unlike existing dyes, and may be easily soluble in water or a solvent as required.

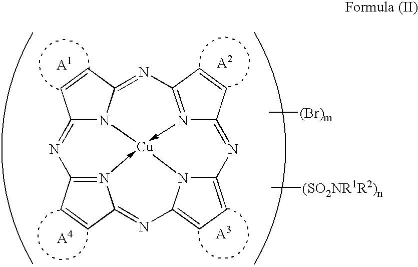

In Formula (II), ring A¹, ring A², ring A³, and ring A⁴ independently represents the following aromatic ring, and may have at least one substituent. In this case, a condensed and/or substituted ring has multiple isomers having different directions along which the aromatic ring is condensed and different substituting positions of the substituent(s).

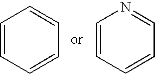

At least one of ring A¹, ring A², ring A³, and ring A⁴ is the following aromatic ring.

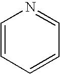

Specific examples of the basic skeleton of Formula (II) include the following five structures shown in Formulae (3) to (7). These structures may have at least one substituent. The nitrogen atom contained in each ot these structures may be shifted from the position shown to other position of the structure. In these cases, condensed and/or substituted rings each have position isomers having different directions along which the pyridine ring is condensed, and different positions of the nitrogen atom. Moreover, such condensed and/or substituted rings each have isomers having different substituting positions of the substituent(s) such as a bromine atom.

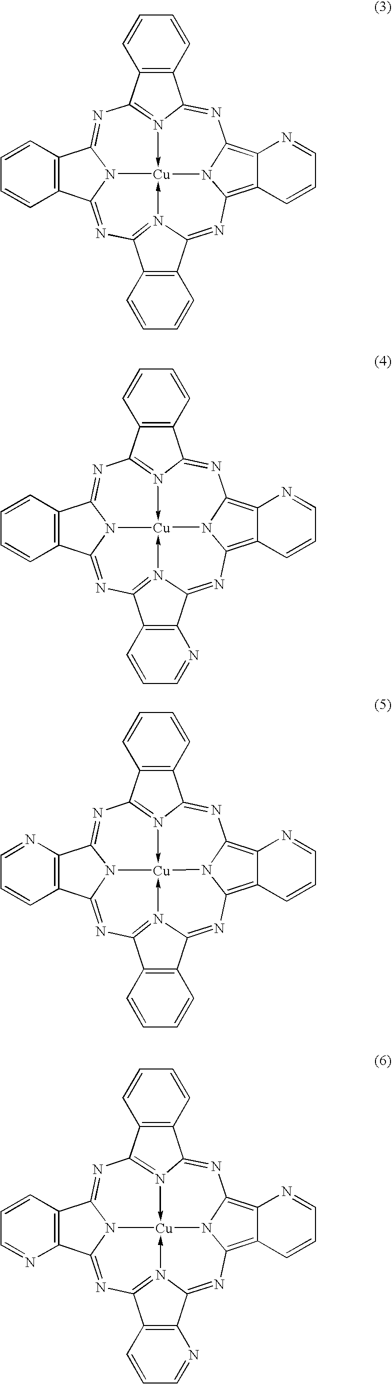

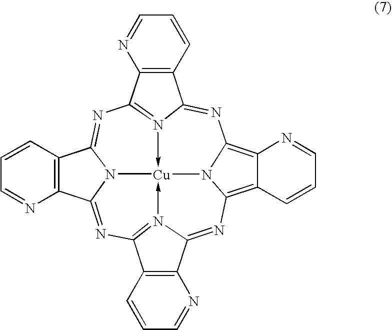

In Formula (II), R¹ and R² independently represent a hydrogen atom, or a substituted or unsubstituted alkyl group. However, both R¹ and R² do not represent hydrogen atoms. m is an integer of 1 to 8, and n is an integer of 1 to 4.

The unsubstituted alkyl group represented by R¹ or R² preferably has 1 to 12 carbon atoms, and may be linear or branched. Examples thereof include a methyl group, an ethyl group, a n-propyl group, an isopropyl group, a n-butyl group, an isobutyl group, a n-hexyl group, a 2-ethylhexyl group, a n-octyl group, and a n-dodecyl group. The unsubstituted alkyl group is preferably a linear or branched alkyl group having 4 to 12 carbon atoms.

The substituted alkyl group represented by R¹ or R² preferably contains at least one oxygen atom each of which is in the form of an ether bond, a carbonyl bond, or an ester bond. The substituted alkyl group is preferably a linear, branched, or cyclic substituted alkyl group having 2 to 12 carbon atoms and containing 1 to 4 oxygen atoms in the above-described form(s). Examples thereof include a methoxyethyl group, an ethoxymethyl group, a butoxymethyl group, a methoxyethyl group, an ethoxyethyl group, a 3-methoxypropyl group, a 3-ethoxypropyl group, a 3-butoxypropyl group, a methoxyethoxyethyl group, an ethoxyethoxyethyl group, a butoxyethoxyethyl group, a methoxyethoxyethoxyethyl group, an ethoxyethoxyethoxyethyl group, a butoxyethoxyethoxyethyl group, an acetylmethyl group, an acetylethyl group, a propionylmethyl group, a propionylethyl group, a tetrahydrofurfuryloxymethyl group, a 2,2-dimethyl-1,3-dioxolane-4-methoxymethyl group, a 2-(1,3-dioxolane)ethoxymethyl group, a 2-(1,3-dioxane)ethoxymethyl group, a methoxycarbonylmethyl group, an ethoxycarbonylethyl group, a propoxycarbonylethyl group, a butoxycarbonylethyl group, a pentoxycarbonylbutyl group, a 1-(butoxymethyl)ethyl group, a 1-(methoxymethyl)propyl group, a 1-(ethoxymethyl)propyl group, a 1-(butoxymethyl)propyl group, a 1-(2-methoxy-ethoxy-methyl)propyl group, a 1-(2-ethoxy-ethoxy-methyl)propyl group, a 1-(2-methoxy-2-ethoxy-2-ethoxymethyl)ethyl group, a 1-(2-ethoxy-2-ethoxy-2-ethoxymethyl)ethyl group, a 1-(2-butoxy-2-ethoxy-2-ethoxymethyl)ethyl group, a 1-(2-methoxy-2-ethoxy-2-ethoxymethyl)propyl group, a 1-(2-ethoxy-2-ethoxy-2-ethoxymethyl)propyl group, a 1-(2-propoxy-2-ethoxy-2-ethoxymethyl)propyl group, a 1-(2-butoxy-2-ethoxy-2-ethoxymethyl)propyl group, a 1-(2-methoxy-2-ethoxy-2-ethoxymethyl)butyl group, a 1-(2-ethoxy-2-ethoxy-2-ethoxymethyl)butyl group, a 1-(2-propoxy-2-ethoxy-2-ethoxymethyl)butyl group, a 1-(2-methoxy-2-ethoxy-2-ethoxymethyl)pentyl group, a 1-(2-ethoxy-2-ethoxy-2-ethoxymethyl)pentyl group, a 1-(2-methoxy-2-ethoxy-2-ethoxy-2-ethoxymethyl)ethyl group, a 1-(2-ethoxy-2-ethoxy-2-ethoxy-2-ethoxymethyl)ethyl group, a 1-(2-methoxy-2-ethoxy-2-ethoxy-2-ethoxymethyl)propyl group, a 1-(2-ethoxy-2-ethoxy-2-ethoxy-2-ethoxymethyl)propyl group, a 1-(2-methoxy-2-ethoxy-2-ethoxy-2-ethoxymethyl)butyl group, a 1-(2-methoxy-2-ethoxy-2-ethoxy-2-ethoxyethyl)ethyl group, a 1-(2-ethoxy-2-ethoxy-2-ethoxy-2-ethoxyethyl)ethyl group, a 1-(2-methoxy-2-ethoxy-2-ethoxy-2-ethoxyethyl)propyl group, a 1,1-di(methoxymethyl)methyl group, a 1,1-di(ethoxymethyl)methyl group, a 1,1-di(propoxymethyl)methyl group, a 1,1-di(butoxymethyl)methyl group, a 1,1-di(2-methoxy-ethoxymethyl)methyl group, a 1,1-di(2-ethoxy-ethoxymethyl)methyl group, a 1,1-di(2-propoxy-ethoxymethyl)methyl group, and a 1,1-di(2-butoxy-ethoxymethyl)methyl group.

Each of R¹ and R² is preferably a hydrogen atom, or an unsubstituted alkyl group, or a substituted alkyl group containing at least one oxygen atom each of which is in the form of an ether bond, a carbonyl bond, or an ester bond. Here, both R¹ and R² do not represent hydrogen atoms.

Each of R¹ and R² is more preferably a hydrogen atom, or an unsubstituted alkyl group having 1 to 12 carbon atoms, or a substituted alkyl group having 2 to 12 carbon atoms and containing 1 to 4 oxygen atoms each of which is in the form of an ether bond, a carbonyl bond, or an ester bond. Here, both R¹ and R² do not represent hydrogen atoms. From the viewpoint of high solubility in a polar organic solvent, at least one of R¹ and R² is preferably a substituted alkyl group having 2 to 12 carbon atoms and containing 1 to 4 oxygen atoms each of which is in the form of an ether bond, a carbonyl bond, or an ester bond.

In particular, the compound of Formula (II) is preferably a tetraazaporphyrin compound where at least one of R¹ and R² is a substituted alkyl group represented by the following Formula (2).

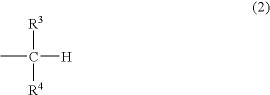

In Formula (2), R³ and R⁴ independently represent a hydrogen atom, an unsubstituted alkyl group, an alkyl group containing at least one oxygen atom each of which is in the form of an ether bond, a carbonyl bond or an ester bond, an alkylcarbonyl group, or an alkoxycarbonyl group. However, at least one of R³ and R⁴ is an alkyl group containing at least one oxygen atom each of which is in the form of an ether bond, a carbonyl bond or an ester bond.

The unsubstituted alkyl group represented by R³ or R⁴ preferably has 1 to 8 carbon atoms, and examples thereof include a methyl group, an ethyl group, a propyl group, an isopropyl group, a butyl group, an isobutyl group, a pentyl group, a hexyl group, and an octyl group.

The substituted alkyl group represented by R³ or R4 and containing at least one oxygen atom each of which is in the form of an ether bond, a carbonyl bond or an ester bond preferably has 2 to 10 carbon atoms and preferably contains 1 to 4 oxygen atoms. Examples thereof include a methoxymethyl group, an ethoxymethyl group, a propoxymethyl group, a butoxymethyl group, a methoxyethoxymethyl group, an ethoxyethoxymethyl group, a propoxyethoxymethyl group, a butoxyethoxymethyl group, a methoxyethoxyethoxymethyl group, an ethoxyethoxyethoxymethyl group, a propoxyethoxyethoxymethyl group, a butoxyethoxyethoxymethyl group, a methoxyethoxyethoxyethoxymethyl group, an ethoxyethoxyethoxyethoxymethyl group, a propoxyethoxyethoxyethoxymethyl group, a butoxyethoxyethoxyethoxymethyl group, an acetylmethyl group, a propionylmethyl group, a tetrahydrofurfuryloxymethyl group, a 2,2-dimethyl-1,3-dioxolane-4-methoxymethyl group, a 2-(1,3-dioxolane)ethoxymethyl group, a 2-(1,3-dioxane)ethoxymethyl group, a methoxycarbonylmethyl group, an ethoxycarbonylmethyl group, a propoxycarbonylmethyl group, a butoxycarbonylmethyl group, and a pentoxycarbonylmethyl group.

Each of the alkylcarbonyl group and the alkoxycarbonyl group represented by R³ or R⁴ preferably has 2 to 10 carbon atoms in total. Examples thereof include an acetyl group, a propionyl group, a propylcarbonyl group, a methoxycarbonyl group, an ethoxycarbonyl group, a propoxycarbonyl group, a butoxycarbonyl group, and a pentoxycarbonyl group.

In Formula (II), m is an integer of 1 to 8, preferably 1 to 6, and, from the viewpoint of high absorbance, more preferably 1 to 4. n is an integer of 1 to 4, preferably 2 or 3, and more preferably 2.

Examples of the tetraazaporphyrin compound represented by Formula (II) include a part or all of the multiple isomers for the aforementioned structures.

Exemplary compounds 1 to 157 of the tetraazaporphyrin compound represented by Formula (II) are shown below. However, the invention is not limited by these examples.

| Ex. Comp. No. | No. of 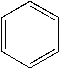 | No. of 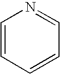 | m | n | R¹ | R² |
|---|---|---|---|---|---|---|
| 1 | 3 | 1 | 1 | 1 | H | —C₂H₄OC₂H₅ |
| 2 | 3 | 1 | 2 | 2 | H | —C₂H₄OC₂H₅ |
| 3 | 3 | 1 | 3 | 3 | H | —C₂H₄OC₂H₅ |
| 4 | 3 | 1 | 1 | 4 | H | —C₂H₄OC₂H₅ |
| 5 | 3 | 1 | 1 | 1 | —C₂H₄OC₂H₅ | —C₂H₄OC₂H₅ |
| 6 | 3 | 1 | 1 | 1 | H | —C₃H₆OC₄H₉ |
| 7 | 3 | 1 | 1 | 2 | H | —C₃H₆OC₄H₉ |
| 8 | 3 | 1 | 1 | 3 | H | —C₃H₆OC₄H₉ |
| 9 | 3 | 1 | 1 | 4 | H | —C₃H₆OC₄H₉ |
| 10 | 3 | 1 | 1 | 1 | —C₂H₄OCH₃ | —C₂H₄OCH₃ |
| 11 | 3 | 1 | 1 | 2 | —C₂H₄OCH₃ | —C₂H₄OCH₃ |
| 12 | 3 | 1 | 1 | 3 | —C₂H₄OCH₃ | —C₂H₄OCH₃ |
| 13 | 3 | 1 | 1 | 4 | —C₂H₄OCH₃ | —C₂H₄OCH₃ |
| 14 | 3 | 1 | 1 | 2 | —C₄H₉ | —C₄H₉ |
| 15 | 3 | 1 | 1 | 1 | H | 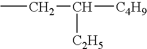 |
| 16 | 3 | 1 | 1 | 2 | H | 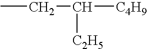 |
| 17 | 3 | 1 | 1 | 3 | H | 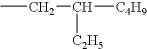 |
| 18 | 3 | 1 | 1 | 4 | H | 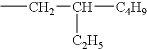 |
| 19 | 3 | 1 | 1 | 1 | H | 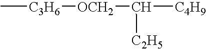 |
| 20 | 3 | 1 | 1 | 2 | H | 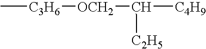 |
| 21 | 3 | 1 | 1 | 3 | H | 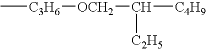 |
| 22 | 3 | 1 | 4 | 4 | H | 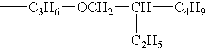 |
| 23 | 3 | 1 | 5 | 3 | H | —C₂H₄OC₂H₄OC₂H₅ |
| 24 | 3 | 1 | 6 | 4 | —C₂H₅ | —C₂H₄OC₂H₅ |
| 25 | 3 | 1 | 8 | 1 | -i-C₃H₇ | 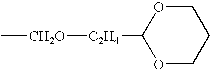 |
| 26 | 3 | 1 | 3 | 3 | H | 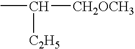 |
| 27 | 3 | 1 | 1 | 1 | H | 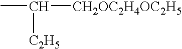 |
| 28 | 3 | 1 | 1 | 2 | H | 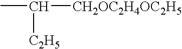 |
| 29 | 3 | 1 | 2 | 3 | H | 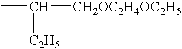 |
| 30 | 3 | 1 | 3 | 4 | H | 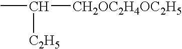 |
| 31 | 3 | 1 | 1 | 1 | H | 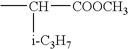 |
| 32 | 3 | 1 | 1 | 2 | H | 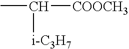 |
| 33 | 3 | 1 | 1 | 3 | H | 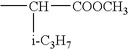 |
| 34 | 3 | 1 | 1 | 4 | H | 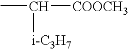 |
| 35 | 3 | 1 | 3 | 3 | -n-C₈H₁₇ | 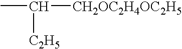 |
| 36 | 3 | 1 | 4 | 4 | H | 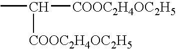 |
| 37 | 3 | 1 | 1 | 1 | —C₂H₄OC₂H₄OC₂H₅ | —C₂H₄OC₂H₄OC₂H₅ |
| 38 | 2 | 2 | 1 | 1 | H | —C₂H₄OC₂H₅ |
| 39 | 2 | 2 | 1 | 2 | H | —C₂H₄OC₂H₅ |
| 40 | 2 | 2 | 1 | 3 | H | —C₂H₄OC₂H₅ |
| 41 | 2 | 2 | 1 | 4 | H | —C₂H₄OC₂H₅ |
| 42 | 2 | 2 | 1 | 2 | —C₂H₄OC₂H₅ | —C₂H₄OC₂H₅ |
| 43 | 2 | 2 | 1 | 1 | H | —C₃H₆OC₄H₉ |
| 44 | 2 | 2 | 1 | 2 | H | —C₃H₆OC₄H₉ |
| 45 | 2 | 2 | 1 | 3 | H | —C₃H₆OC₄H₉ |
| 46 | 2 | 2 | 1 | 4 | H | —C₃H₆OC₄H₉ |
| 47 | 2 | 2 | 1 | 1 | —C₂H₄OCH₃ | —C₂H₄OCH₃ |
| 48 | 2 | 2 | 1 | 2 | —C₂H₄OCH₃ | —C₂H₄OCH₃ |
| 49 | 2 | 2 | 1 | 3 | —C₂H₄OCH₃ | —C₂H₄OCH₃ |
| 50 | 2 | 2 | 1 | 4 | —C₂H₄OCH₃ | —C₂H₄OCH₃ |
| 51 | 2 | 2 | 1 | 3 | —C₄H₉ | —C₄H₉ |
| 52 | 2 | 2 | 1 | 1 | H | 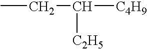 |
| 53 | 2 | 2 | 1 | 2 | H | 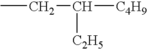 |
| 54 | 2 | 2 | 1 | 3 | H | 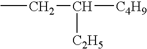 |
| 55 | 2 | 2 | 1 | 4 | H | 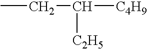 |
| 56 | 2 | 2 | 1 | 1 | H | 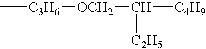 |
| 57 | 2 | 2 | 1 | 2 | H | 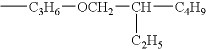 |
| 58 | 2 | 2 | 1 | 3 | H | 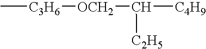 |
| 59 | 2 | 2 | 1 | 4 | H | 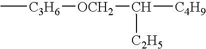 |
| 60 | 2 | 2 | 1 | 4 | H | —C₂H₄OC₂H₄OC₂H₅ |
| 61 | 2 | 2 | 1 | 1 | —C₂H₅ | —C₂H₄OC₂H₅ |
| 62 | 2 | 2 | 2 | 2 | -i-C₃H₇ | 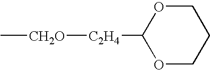 |
| 63 | 2 | 2 | 3 | 3 | H | 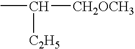 |
| 64 | 2 | 2 | 1 | 1 | H | 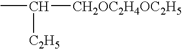 |
| 65 | 2 | 2 | 1 | 2 | H | 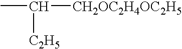 |
| 66 | 2 | 2 | 3 | 3 | H | 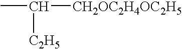 |
| 67 | 2 | 2 | 1 | 4 | H | 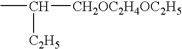 |
| 68 | 2 | 2 | 1 | 1 | H | 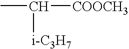 |
| 69 | 2 | 2 | 2 | 2 | H | 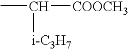 |
| 70 | 2 | 2 | 3 | 3 | H | 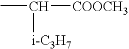 |
| 71 | 2 | 2 | 1 | 4 | H | 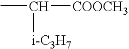 |
| 72 | 2 | 2 | 1 | 4 | -n-C₈H₁₇ | 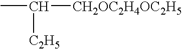 |
| 73 | 2 | 2 | 1 | 1 | H | 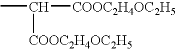 |
| 74 | 2 | 2 | 2 | 2 | —C₂H₄OC₂H₄OC₂H₅ | —C₂H₄OC₂H₄OC₂H₅ |
| 75 | 1 | 3 | 1 | 1 | H | —C₂H₄OC₂H₅ |
| 76 | 1 | 3 | 2 | 2 | H | —C₂H₄OC₂H₅ |
| 77 | 1 | 3 | 1 | 3 | H | —C₂H₄OC₂H₅ |
| 78 | 1 | 3 | 1 | 4 | H | —C₂H₄OC₂H₅ |
| 79 | 1 | 3 | 1 | 3 | —C₂H₄OC₂H₅ | —C₂H₄OC₂H₅ |
| 80 | 1 | 3 | 1 | 1 | H | —C₃H₆OC₄H₉ |
| 81 | 1 | 3 | 1 | 2 | H | —C₃H₆OC₄H₉ |
| 82 | 1 | 3 | 1 | 3 | H | —C₃H₆OC₄H₉ |
| 83 | 1 | 3 | 1 | 4 | H | —C₃H₆OC₄H₉ |
| 84 | 1 | 3 | 1 | 1 | —C₂H₄OCH₃ | —C₂H₄OCH₃ |
| 85 | 1 | 3 | 1 | 2 | —C₂H₄OCH₃ | —C₂H₄OCH₃ |
| 86 | 1 | 3 | 1 | 3 | —C₂H₄OCH₃ | —C₂H₄OCH₃ |
| 87 | 1 | 3 | 1 | 4 | —C₂H₄OCH₃ | —C₂H₄OCH₃ |
| 88 | 1 | 3 | 1 | 4 | —C₄H₉ | —C₄H₉ |
| 89 | 1 | 3 | 1 | 1 | H | 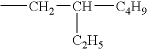 |
| 90 | 1 | 3 | 1 | 2 | H | 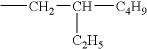 |
| 91 | 1 | 3 | 1 | 3 | H | 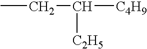 |
| 92 | 1 | 3 | 1 | 4 | H | 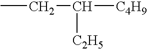 |
| 93 | 1 | 3 | 1 | 1 | H | 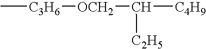 |
| 94 | 1 | 3 | 1 | 2 | H | 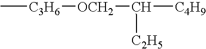 |
| 95 | 1 | 3 | 1 | 3 | H | 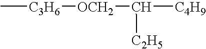 |
| 96 | 1 | 3 | 1 | 4 | H | 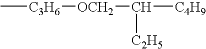 |
| 97 | 1 | 3 | 1 | 1 | H | —C₂H₄OC₂H₄OC₂H₅ |
| 98 | 1 | 3 | 1 | 2 | —C₂H₅ | —C₂H₄OC₂H₅ |
| 99 | 1 | 3 | 3 | 3 | -i-C₃H₇ | 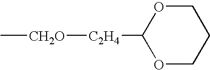 |
| 100 | 1 | 3 | 1 | 4 | H | 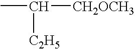 |
| 101 | 1 | 3 | 1 | 1 | H | 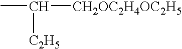 |
| 102 | 1 | 3 | 4 | 2 | H | 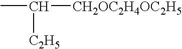 |
| 103 | 1 | 3 | 4 | 3 | H | 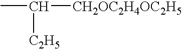 |
| 104 | 1 | 3 | 4 | 4 | H | 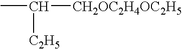 |
| 105 | 1 | 3 | 1 | 1 | H | —CH—C₂H₄COCH₃ |
| 106 | 1 | 3 | 2 | 2 | H | —CH—C₂H₄COCH₃ |
| 107 | 1 | 3 | 3 | 3 | H | —CH—C₂H₄COC₃H₇ |
| 108 | 1 | 3 | 1 | 4 | H | —CH—C₂H₄COC₃H₇ |
| 109 | 1 | 3 | 1 | 1 | -n-C₈H₁₇ | 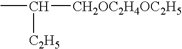 |
| 110 | 1 | 3 | 2 | 2 | H | 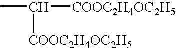 |
| 111 | 1 | 3 | 1 | 3 | —C₂H₄OC₂H₄OC₂H₅ | —C₂H₄OC₂H₄OC₂H₅ |
| 112 | 0 | 4 | 1 | 1 | H | —C₂H₄OC₂H₅ |
| 113 | 0 | 4 | 1 | 2 | H | —C₂H₄OC₂H₅ |
| 114 | 0 | 4 | 1 | 3 | H | —C₂H₄OC₂H₅ |
| 115 | 0 | 4 | 1 | 4 | H | —C₂H₄OC₂H₅ |
| 116 | 0 | 4 | 1 | 4 | —C₂H₄OC₂H₅ | —C₂H₄OC₂H₅ |
| 117 | 0 | 4 | 1 | 1 | H | —C₃H₆OC₄H₉ |
| 118 | 0 | 4 | 1 | 2 | H | —C₃H₆OC₄H₉ |
| 119 | 0 | 4 | 1 | 3 | H | —C₃H₆OC₄H₉ |
| 120 | 0 | 4 | 1 | 4 | H | —C₃H₆OC₄H₉ |
| 121 | 0 | 4 | 1 | 1 | —C₂H₄OCH₃ | —C₂H₄OCH₃ |
| 122 | 0 | 4 | 1 | 2 | —C₂H₄OCH₃ | —C₂H₄OCH₃ |
| 123 | 0 | 4 | 1 | 3 | —C₂H₄OCH₃ | —C₂H₄OCH₃ |
| 124 | 0 | 4 | 1 | 4 | —C₂H₄OCH₃ | —C₂H₄OCH₃ |
| 125 | 0 | 4 | 1 | 1 | —C₄H₉ | —C₄H₉ |
| 126 | 0 | 4 | 1 | 1 | H | 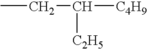 |
| 127 | 0 | 4 | 1 | 2 | H | 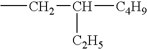 |
| 128 | 0 | 4 | 1 | 3 | H | 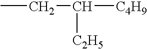 |
| 129 | 0 | 4 | 1 | 4 | H | 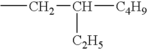 |
| 130 | 0 | 4 | 1 | 1 | H | —CHCOCH₃ |
| 131 | 0 | 4 | 1 | 2 | H | —CHCOCH₃ |
| 132 | 0 | 4 | 1 | 3 | H | —CHCOOC₃H₇ |
| 133 | 0 | 4 | 1 | 4 | H | —CHCOOC₃H₇ |
| 134 | 0 | 4 | 1 | 2 | H | —C₂H₄OC₂H₄OC₂H₅ |
| 135 | 0 | 4 | 1 | 3 | —C₂H₅ | —C₂H₄OC₂H₅ |
| 136 | 0 | 4 | 1 | 4 | -i-C₃H₇ | 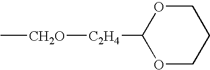 |
| 137 | 0 | 4 | 1 | 1 | H | 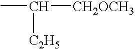 |
| 138 | 0 | 4 | 1 | 1 | H | 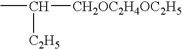 |
| 139 | 0 | 4 | 1 | 2 | H | 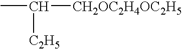 |
| 140 | 0 | 4 | 1 | 3 | H | 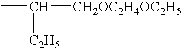 |
| 141 | 0 | 4 | 1 | 4 | H | 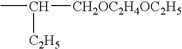 |
| 142 | 0 | 4 | 1 | 1 | H | 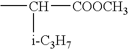 |
| 143 | 0 | 4 | 1 | 2 | H | 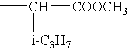 |
| 144 | 0 | 4 | 1 | 3 | H | 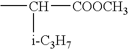 |
| 145 | 0 | 4 | 1 | 4 | H | 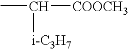 |
| 146 | 0 | 4 | 1 | 2 | -n-C₈H₁₇ | 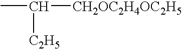 |
| 147 | 0 | 4 | 1 | 3 | H | 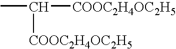 |
| 148 | 0 | 4 | 1 | 4 | —C₂H₄OC₂H₄OC₂H₅ | —C₂H₄OC₂H₄OC₂H₅ |
| 149 | 3 | 1 | 1 | 4 | —C₁₀H₂₁ | H |
| 150 | 3 | 1 | 1 | 3 | —C₁₂H₂₅ | —C₁₂H₂₅ |
| 151 | 3 | 1 | 1 | 4 | —C₁₂H₂₅ | —C₂H₄OC₂H₅ |
| 152 | 3 | 1 | 1 | 1 | 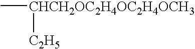 | H |
| 153 | 3 | 1 | 1 | 3 | 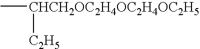 | —C₂H₅ |
| 154 | 3 | 1 | 1 | 1 | 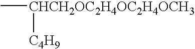 | H |
| 155 | 3 | 1 | 1 | 1 | 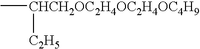 | H |
| 156 | 3 | 1 | 1 | 2 | 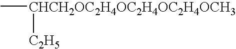 | H |
| 157 | 3 | 1 | 1 | 3 | 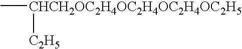 | H |

From the viewpoints of an absorbance and a film curing property due to the dye, the concentration of the phthalocyanine dye(s) soluble in an organic solvent in the solid matter of the negative curable dye-containing composition of the invention is preferably 10 to 80 mass %, more preferably 20 to 70 mass %, and most preferably 25 to 65 mass %.

Organic Solvent-Soluble Dye

The negative curable dye-containing composition of the invention may further contain any of known organic solvent-soluble dyes for color filters as well as the phthalocyanine dye soluble in an organic solvent.

Examples thereof include those disclosed in JP-A Nos. S64-90403, S64-91102, H01-94301 and H06-11614, Japanese Patent No. 2592207, U.S. Pat. Nos. 4,808,501, 5,667,920 and 5,059,500, and JP-A No. H06-35183. These dyes are triphenyl methane dyes, anthraquinone dyes, benzylidene dyes, oxonol dyes, cyanine dyes, phenothiazine dyes, pyrrolopyrazoleazomethine dyes, xanthene dyes, phthalocyanine dyes, benzopyrane dyes, and indigo dyes. The organic solvent-soluble dye is preferably a pyrazoleazo dye, an anilinoazo dye, a pyrazolotriazoleazo dye, a pyridoneazo dye or an anthrapyridone dye.

Alternatively, the organic solvent-soluble dye may be a direct dye, a basic dye, a mordant dye, an acidic mordant dye, an azoic dye or a disperse dye.

<Acidic Dye>

Among them, the acidic dye will be specifically described. The acidic dye has at least one acidic group, such as a sulfonic group, a carboxylic group, or a phenolic hydroxyl group, and otherwise there is no particular limit thereto. The type of the acidic dye to be used is selected in consideration of all required properties including solubility in an organic solvent or a developing solution, a salt-forming property of the dye with a basic compound, absorbance, interaction with other components of the negative curable dye-containing composition, light fastness, and heat resistance.

Specific examples of the acidic dye are described below, but the invention is not limited by these examples. acid alizarin violet N;

acid black 1, 2, 24, and 48;

acid blue 1, 7, 9, 15, 18, 23, 25, 27, 29, 40, 42, 45, 51, 62, 70, 74, 80, 83, 86, 87, 90, 92, 96, 103, 112, 113, 120, 129, 138, 147, 150, 158, 171, 182, 192, 210, 242, 243, 256, 259, 267, 278, 280, 285, 290, 296, 315, 324: 1, 335, and 340;

acid chrome violet K;

acid Fuchsin;

acid green 1, 3, 5, 9, 16, 25, 27, 50, 58, 63, 65, 80, 104, 105, 106, and 109;

acid orange 6, 7, 8, 10, 12, 26, 50, 51, 52, 56, 62, 63, 64, 74, 75, 94, 95, 107, 108, 169, and 173;

acid red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150,151, 158, 176, 182, 183, 198, 206, 211, 215, 216, 217, 227, 228, 249, 252, 257, 258, 260, 261, 266, 268, 270, 274, 277, 280, 281, 195, 308, 312, 315, 316, 339, 341, 345, 346, 349, 382, 383, 394, 401, 412, 417, 418, 422, and 426;

acid violet 6B, 7, 9, 17, and 19;

acid yellow 1, 3, 7, 9, 11, 17, 23, 25, 29, 34, 36, 38, 40, 42, 54, 65, 72,73, 76, 79, 98, 99, 111, 112, 113, 114, 116, 119, 123, 128, 134, 135, 138, 139, 140, 144, 150, 155, 157, 160, 161, 163, 168, 169, 172, 177, 178, 179, 184, 190, 193, 196, 197, 199, 202, 203, 204, 205, 207, 212, 214, 220, 221, 228, 230, 232, 235, 238, 240, 242, 243, and 251;

Direct Yellow 2, 33, 34, 35, 38, 39, 43, 47, 50, 54, 58, 68, 69, 70, 71, 86, 93, 94, 95, 98, 102, 108, 109, 129, 136, 138, and 141;

Direct Orange 34, 39, 41, 46, 50, 52, 56, 57, 61, 64, 65, 68, 70, 96, 97, 106, and 107;

Direct Red 79, 82, 83, 84, 91, 92, 96, 97, 98, 99, 105, 106, 107, 172, 173, 176, 177, 179, 181, 182, 184, 204, 207, 211, 213, 218, 220, 221, 222, 232, 233, 234, 241, 243, 246,and 250;

Direct Violet 47, 52, 54, 59, 60, 65, 66, 79, 80, 81, 82, 84, 89, 90, 93, 95, 96, 103, and 104;

Direct Blue 57, 77, 80, 81, 84, 85, 86, 90, 93, 94, 95, 97, 98, 99, 100, 101, 106, 107, 108, 109, 113, 114, 115, 117, 119, 137, 149, 150, 153, 155, 156,158, 159,160, 161, 162, 163, 164, 166, 167, 170, 171, 172, 173, 188, 189, 190, 192, 193, 194, 196, 198, 199,200, 207, 209, 210, 212, 213, 214, 222, 228, 229, 237, 238, 242, 243, 244, 245, 247, 248, 250, 251, 252, 256, 257, 259, 260, 268, 274, 275, and 293;

Direct Green 25, 27, 31, 32, 34, 37, 63, 65, 66, 67, 68, 69, 72, 77, 79, and 82;

Mordant Yellow 5, 8, 10, 16, 20, 26, 30, 31, 33, 42, 43, 45, 56, 50, 61, 62, and 65;

Mordant Orange 3, 4, 5, 8, 12, 13, 14, 20, 21, 23, 24, 28, 29, 32, 34, 35, 36, 37, 42, 43, 47, and 48;

Mordant Red 1, 2, 3, 4, 9, 11, 12, 14, 17, 18, 19, 22, 23, 24, 25, 26, 30, 32, 33, 36, 37, 38, 39, 41, 43, 45, 46, 48, 53, 56, 63, 71, 74, 85, 86, 88, 90, 94, and 95;

Mordant Violet 2, 4, 5, 7, 14, 22, 24, 30, 31, 32, 37, 40, 41, 44, 45, 47,48, 53, and 58;

Mordant Blue 2, 3, 7, 8, 9, 12, 13, 15, 16, 19, 20, 21, 22, 23, 24, 26, 30, 31, 32, 39, 40, 41, 43, 44, 48, 49, 53, 61, 74, 77, 83, and 84;

Mordant Green 1, 3, 4, 5, 10, 15, 19, 26, 29, 33, 34, 35, 41, 43, and 53;

Food Yellow 3; and

derivatives of these dyes.

The acidic dye is preferably acid black 24; acid blue 23, 25, 29, 62, 80, 86, 87, 92, 138, 158, 182, 243, or 324:1; acid orange 8, 51, 56, 74, or 63; acid red 1, 4, 8, 34, 37, 42, 52, 57, 80, 97, 114, 143, 145, 151, 183, 217, or 249; acid violet 7; acid yellow 17, 25, 29, 34, 42, 72, 76, 99, 111, 112, 114, 116, 134, 155, 169, 172, 184, 220, 228, 230, 232, or 243; or Acid Green 25; or a derivative thereof.

The derivatives of acidic dyes may be inorganic salts of acidic dyes having at least one sulfonic group or carboxylic group, and salts of acidic dyes and nitrogen-containing compounds. The derivatives may be soluble in the negative curable dye-containing composition, which is a solution, and otherwise there is no particular limit thereto. The type of the derivative to be used is selected in consideration of all required properties including solubility in an organic solvent or a developing solution, absorbance, interaction of the derivative with other components in the negative curable dye-containing composition, light fastness, and heat resistance.

The salt of an acidic dye and a nitrogen-containing compound will be explained.

Formation of the salt between an acidic dye and a nitrogen-containing compound is effective in improving the solubility of the acidic dye (providing the acidic dye with solubility in an organic solvent), or improving heat resistance or light fastness of the acidic dye.

The type of the nitrogen-containng compound that, together with the acidic dye, forms a salt or an amide bond is selected in consideration of all required properties including the solubility of the salt or the amide compound in an organic solvent or a developing solution, a salt-forming property, the absorbance and the color value of the dye, interaction of the salt with other components of the negative curable dye-containing composition, and heat resistance and light fastness. From the viewpoints of absorbance and color value only, the nitrogen-containing compound preferably has as low a molecular weight as possible. The molecular weight of the nitrogen-containing compound is preferably 300 or less, more preferably 280 or less, and most preferably 250 or less.

The molar ratio (i.e., n) of the nitrogen-containing compound to the acidic dye in forming the salt of the acidic dye and the nitrogen-containing compound will be explained. The ratio n affects the molar ratio of acidic dye molecules to an amine compound serving as a counter ion, and can be selected freely according to conditions of formation of a salt between the acidic dye and the amine compound. Specifically, the molar ratio n numerical value is mostly so selected as to satisfy the relationship of 0<n≦5, on the basis of the number of the acidic functional groups of the acidic dye. The molar ratio n is selected in consideration of all required properties including solubility of the salt in an organic solvent or a developing solution, a salt-forming property, absorbance, interaction of the salt with other components of the negative curable dye-containing composition, light fastness, and heat resistance. From the viewpoint of absorbance only, the molar ratio n preferably satisfies the relationship of 0<n≦4.5, more preferably 0<n≦4, and most preferably 0<n≦3.5.

The concentration of the dye(s) soluble in an organic solvent will be explained. When the negative curable dye-containing composition of the invention contains at least one dye soluble in an organic solvent, a desired concentration of the dye(s) in the solid matter of the negative curable dye-containing composition depends on the type(s) of the dye(s). The concentration is preferably 20 to 80 mass %, more preferably 25 to 70 mass %, and most preferably 30 to 65 mass %.

<Photopolymerization Initiator>

The negative curable dye-containing composition of the invention contains at least one polymerization initiator. Each of the at least one polymerization initiator causes at least one polymerizable monomer to polymerize and otherwise there is no particular limit thereto. The polymerization initiator is preferably selected from the viewpoints of characteristics, initialization efficiency, absorption wavelength, availability and cost.

Examples of the polymerization initiator include active halogen compounds such as halomethyl oxadiazole compounds and halomethyl-s-triazine compounds, 3-aryl-substituted coumarine compounds, lophine dimers, benzophenone compounds, acetophenone compounds and derivatives thereof, cyclopentadiene-benzene-iron complexes and salts thereof, and oxime compounds.

Examples of the halomethyl oxadiazole compounds, which are active halogen compounds, include 2-halomethyl-5-vinyl-1,3,4-oxadiazole compounds disclosed in Japanese Patent Application Publication (JP-B) No. S57-6096, 2-trichloromethyl-5 -styryl-1,3,4-oxadiazole, 2-trichloromethyl-5-(p-cyanostyryl)-1,3,4-oxadiazole, and 2-trichloromethyl-5-(p-methoxystyryl)-1,3,4-oxadiazole.

Examples of the halomethyl-s-triazine compounds, which are active halogen compounds, include vinyl-halomethyl-s-triazine compounds disclosed in JP-B No. S59-1281, and a 2-(naphtho-1-yl)-4,6-bis-halomethyl-s-triazine compound and a 4-(p-aminophenyl)-2,6-di-halomethyl-s-triazine compound disclosed in JP-A No. S53-133428.

Other examples of the photopolymerization initiator include
2,4-bis(trichloromethyl)-6-p-methoxystyryl-s-triazine,
2,6-bis(trichloromethyl)-4-(3,4-methylenedioxyphenyl)-1,3,5-triazine,
2,6-bis(trichloromethyl)-4-(4-methoxyphenol)-1,3,5 -triazine,
2,4-bis(trichloromethyl)-6-(1-p-dimethylaminophenyl-1,3 -butadienyl)-s-triazine,
2-trichloromethyl-4-amino-6-p-methoxystyryl-s-triazine,
2-(naphtho-1-yl)-4,6-bis-trichloromethyl-s-triazine,
2-(4-methoxy-naphtho-1-yl)-4,6-bis-trichloromethyl-s-triazine,
2-(4-ethoxy-naphtho-1-yl)-4,6-bis-trichloromethyl-s-triazine,
2-(4-butoxy-naphtho-1-yl)-4,6-bis-trichloromethyl-s-triazine,
2-[4-(2-methoxyethyl)-naphtho-1-yl]-4,6-bis-trichloromethyl-s-triazine,
2-[4-(2-ethoxyethyl)-naphtho-1-yl]-4,6-bis-trichloromethyl-s-triazine,
2-[4-(2-butoxyethyl)-naphtho-1-yl]-4,6-bis-trichloromethyl-s-triazine,
2-(2-methoxy-naphtho-1-yl)-4,6-bis-trichloromethyl-s-triazine,
2-(6-methoxy-5-methyl-naphtho-2-yl)-4,6-bis-trichloromethyl-s-triazine,
2-(6-methoxy-naphtho-2-yl)-4,6-bis-trichloromethyl-s-triazine,
2-(5-methoxy-naphtho-1-yl)-4,6-bis-trichloromethyl-s-triazine,
2-(4,7-dimethoxy-naphto-1-yl)-4,6-bis-trichloromethyl-s-triazine,
2-(6-ethoxy-naphtho-2-yl)-4,6-bis-trichloromethyl-s-triazine,
2-(4,5-dimethoxy-naphtho-1-yl)-4,6-bis-trichloromethyl-s-triazine,
4-[p-N,N-di(ethoxycarbonylmethyl)aminophenyl]-2,6-di(trichloromethyl)-s-triazine,
4-[o-methyl-p-N,N-di(ethoxycarbonylmethyl)aminophenyl]-2,6-di(trichloromethyl)-s-triazine,
4-[p-N,N-di(chloroethyl)aminophenyl]-2,6-di(trichloromethyl)-s-triazine,
4-[o-methyl-p-N,N-di(chloroethyl)aminophenyl]-2,6-di(trichloromethyl)-s-triazine,
4-(p-N-chloroethylaminophenyl)-2,6-di(trichloromethyl)-s-triazine,
4-(p-N-ethoxycarbonylmethylaminophenyl)-2,6-di(trichloromethyl)-s-triazine,
4-[p-N,N-di(phenyl)aminophenyl]-2,6-di(trichloromethyl)-s-triazine,
4-(p-N-chloroethylcarbonylaminophenyl)-2,6-di(trichloromethyl)-s-triazine,
4-[p-N-(p-methoxyphenyl)carbonylaminophenyl]-2,6-di(trichloromethyl)-s-triazine,
4-[m-N,N-di(ethoxycarbonylmethyl)aminophenyl]-2,6-di(trichloromethyl)-s-triazine,
4-[m-bromo-p-N,N-di(ethoxycarbonylmethyl)aminophenyl]-2,6-di(trichloromethyl)-s-triazine,
4-[m-chloro-p-N,N-di(ethoxycarbonylmethyl)aminophenyl]-2,6-di(trichloromethyl)-s-triazine,
4-[m-fluoro-p-N,N-di(ethoxycarbonylmethyl)aminophenyl]-2,6-di(trichloromethyl)-s-triazine
4-[o-bromo-p-N,N-di(ethoxycarbonylmethyl)aminophenyl]-2,6-di(trichloromethyl)-s-triazine,
4-[o-chloro-p-N,N-di (ethoxycarbonylmethyl)aminophenyl-2,6-di(trichloromethyl)-s-triazine,
4-[o-fluoro-p-N,N-di(ethoxycarbonylmethyl)aminophenyl]-2,6-di(trichloromethyl)-s-triazine,
4-[o-bromo-p-N,N-di(chloroethyl)aminophenyl]-2,6-di(trichloromethyl)-s-triazine,
4-[o-chloro-p-N,N-di(chloroethyl)aminophenyl]-2,6-di(trichloromethyl)-s-triazine,
4-[o-fluoro-p-N,N-di(chloroethyl)aminophenyl]-2,6-di(trichloromethyl)-s-triazine,
4-[m-bromo-p-N,N-di(chloroethyl)aminophenyl]-2,6-di(trichloromethyl)-s-triazine,
4-[m-chloro-p-N,N-di(chloroethyl)aminophenyl]-2,6-di(trichloromethyl)-s-triazine,
4-[m-fluoro-p-N,N-di(chloroethyl)aminophenyl]-2,6-di(trichloromethyl)-s-triazine,
4-(m-bromo-p-N-ethoxycarbonylmethylaminophenyl)-2,6-di(trichloromethyl)-s-triazine,
4-(m-chloro-p-N-ethoxycarbonylmethylaminophenyl)-2,6-di(trichloromethyl)-s-triazine,
4-(m-fluoro-p-N-ethoxycarbonylmethylaminophenyl)-2,6-di(trichloromethyl)-s-triazine,
4-(o-bromo-p-N-ethoxycarbonylmethylaminophenyl)-2,6-di(trichloromethyl)-s-triazine,
4-(o-chloro-p-N-ethoxycarbonylmethylaminophenyl)-2,6-di(trichloromethyl)-s-triazine,
4-(o-fluoro-p-N-ethoxycarbonylmethylaminophenyl)-2,6-di(trichloromethyl)-s-triazine,
4-(m-bromo-p-N-chloroethylaminophenyl)-2,6-di(trichloromethyl)-s-triazine,
4-(m-chloro-p-N-chloroethylaminophenyl)-2,6-di(trichloromethyl)-s-triazine,
4-(m-fluoro-p-N-chloroethylaminophenyl)-2,6-di(trichloromethyl)-s-triazine,
4-(o-bromo-p-N-chloroethylaminophenyl)-2,6-di(trichloromethyl)-s-triazine,
4-(o-chloro-p-N-chloroethylaminophenyl)-2,6-di(trichloromethyl)-s-triazine, and
4-(o-fluoro-p-N-chloroethylaminophenyl)-2,6-di(trichloromethyl)-s-triazine.

The photopolymerization initiator may also be one of TAZ series of Midori Kagaku Co., Ltd., such as TAZ-107, TAZ-110, TAZ-104, TAZ-109, TAZ-140, TAZ-204, TAZ-113, TAZ-123, and TAX-104, T series of PANCHIM Ltd., such as T-OMS, T-BMP, T-R, and T-B, IRGACURE Series of Ciba Specialty Chemicals, such as IRGACURE 651, IRGACURE 184, IRGACURE 500, IRGACURE 1000, IRGACURE 149, IRGACURE 819, IRGACURE 261, DAROCURE Series of Ciba Specialty Chemicals, such as DAROCURE 1173, 4,4′-bis(diethylamino)-benzophenone, 2-(O-benzoyloxime)-1-[4-(phenylthio)phenyl]-1,2-octanedione, 2-benzyl-2-dimethylamino-4-morpholinobutylophenone, 2,2-dimethoxy-2-phenylacetophenone, 2-(o-chlorophenyl)-4,5-diphenylimidazolyl dimer, 2-(o-fluorophenyl)-4,5-diphenylimidazolyl dimer, 2-(o-methoxyphenyl)-4,5-diphenylimidazolyl dimer, 2-(p-methoxyphenyl)-4,5-diphenylimidazolyl dimer, 2-(p-dimethoxyphenyl)-4,5-diphenylimidazolyl dimer, 2-(2,4-dimethoxyphenyl)-4,5-diphenylimidazolyl dimer, 2-(p-methylmercaptophenyl)-4,5-diphenyl imidazolyl dimer, and benzoin isopropyl ether.

Among those, the photopolymerization initiator is preferably an oxime compound, and more preferably 2-(O-benzoyloxime)-1-[4-(phenylthio)phenyl]-1,2-octanedione, or 1-(O-acetyloxime)-1-[9-ethyl-6-(2-methylbenzoyl)-9H-carbazole-3-yl]ethanone.

The negative curable dye-containing composition of the invention may further contain other known photopolymerization initiator(s) as well as the aforementioned photopolymerization initiator(s).

Specific examples thereof include vicinal polyketol aldonyl compounds disclosed in U.S. Pat. No. 2,367,660, α-carbonyl compounds disclosed in U.S. Pat. Nos. 2,367,661 and 2,367,670, acyloin ether disclosed in U.S. Pat. No. 2,448,828, α-hydrocarbon-substituted aromatic acyloin compounds disclosed in U.S. Pat. No. 2,722,512, polynuclear quinone compounds disclosed in U.S. Pat. Nos. 3,046,127 and 2,951,758, a combination of triallylimidazole dimer and p-aminophenyl ketone disclosed in U.S. Pat. No. 3,549,367, and benzothiazole compounds and trihalomethyl-s-triazine compounds disclosed in JP-B No. S51-48516.

These photopolymerization initiators can be used together with at least one sensitizer and/or at least one light stabilizer.

Specific examples thereof include benzoin, benzoin methyl ether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, thioxanthone, 2,4-diethylthioxanthone, acridone, 10-butyl-2-chloroacridone, benzil, dibenzalacetone, p-(dimethylamino)phenyl styryl ketone, p-(dimethylamino)phenyl p-methylstyryl ketone, benzophenone, p-(dimethylamino)benzophenone (or Michler's ketone), p-(diethylamino)benzophenone, benzoanthrone, benzothiazole compounds disclosed in JP-B No. S51-48516, and TINUVIN 1130 and 400.

The content of the photopolymerization initiator(s) in the solid matter of the negative curable dye-containing composition is preferably 1.0 to 40.0 mass %, more preferably 2.5 to 30.0 mass %, and most preferably 5.0 to 20.0 mass %. When the content of the photopolymerization initiator(s) is less than 1.0 mass %, progress of polymerization may slow. When the content exceeds 40.0 mass %, the rate of polymerization may become high, but the molecular weight of the resultant polymer may lower, resulting in weakened film strength.

<Radical Polymerizable Monomer>

The negative curable dye-containing composition of the invention contains at least one radical polymerizable monomer. The radical polymerizable monomer is preferably a compound having at least one ethylenic unsaturated double bond capable of addition-polymerizing and a boiling point of 100° C. or higher at normal pressure.

Examples thereof include monofunctional acrylates and methacrylates such as polyethylene glycol mono(meth)acrylate, polypropylene glycol mono(meth)acrylate, phenoxyethyl (meth)acrylate; polyfunctional acrylates and methacrylates such as polyethylene glycol di(meth)acrylate, trimethylolethane tri(meth)acrylate, neopentyl glycol di(meth)acrylate, pentaerythrytol tri(meth)acrylate, pentaerythrytol tetra(meth)acrylate, dipentaerythrytol penta(meth)acrylate, dipentaerythrytol hexa(meth)acrylate, hexane diol (meth)acrylate, trimethylolpropane tri(acryloyloxypropyl) ether, tri(acryloyloxyethyl) isocyanurate, products obtained by adding ethylene oxide or propylene oxide to multifunctional alcohols, such as glycerine, or trimethylolethane, and (meth)acrylating the resultant adducts, urethane acrylates disclosed in JP-B Nos. S48-41708 and S50-6034, and JP-A No. S51-37193, polyester acrylates disclosed in JP-A No. S48-64183, and JP-B Nos. S49-43191 and 52-30490, epoxy acrylates including reaction products of epoxy resin and (meth)acrylic acid; and mixtures thereof. Alternatively, the polymerizable monomer may also be photocurable monomer or oligomer described in Journal of The Adhesion Society of Japan, vol. 20, No. 7, pages 300 to 308.

Alternatively, the radical polymerizable monomer may also be a compound having at least one carboxyl group and represented by Formula (V-1) or (V-2). When T or G is an oxyalkylene group in Formulas (V-1) and (V-2), the terminal carbon atom thereof is bonded to R, X or W.

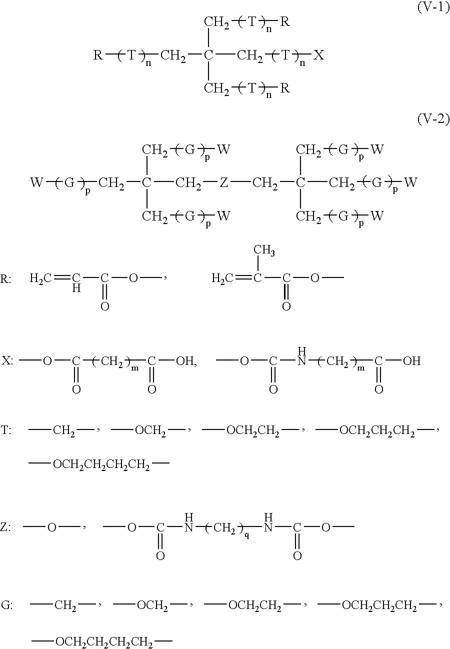

In Formula (V-1), n is 0 to 14, and m is 1 to 8. W in Formula (V-2) has the same meaning as R or X in Formula (V-1), and three or more of six Ws are R. p is 0 to 14, and q is 1 to 8. Plural Rs in one molecule may be the same or different, plural Xs may be the same or different, plural Ts may be the same or eifferent, and plural Gs may be the same or different.

Typical examples (M-1) to (M-12) of the radical polymerizable monomers represented by Formulas (V-1) and (V-2) are shown below. The radical polymerizable monomer is preferably a compound shown by Formula (M-2), (M-3), or (M-5).

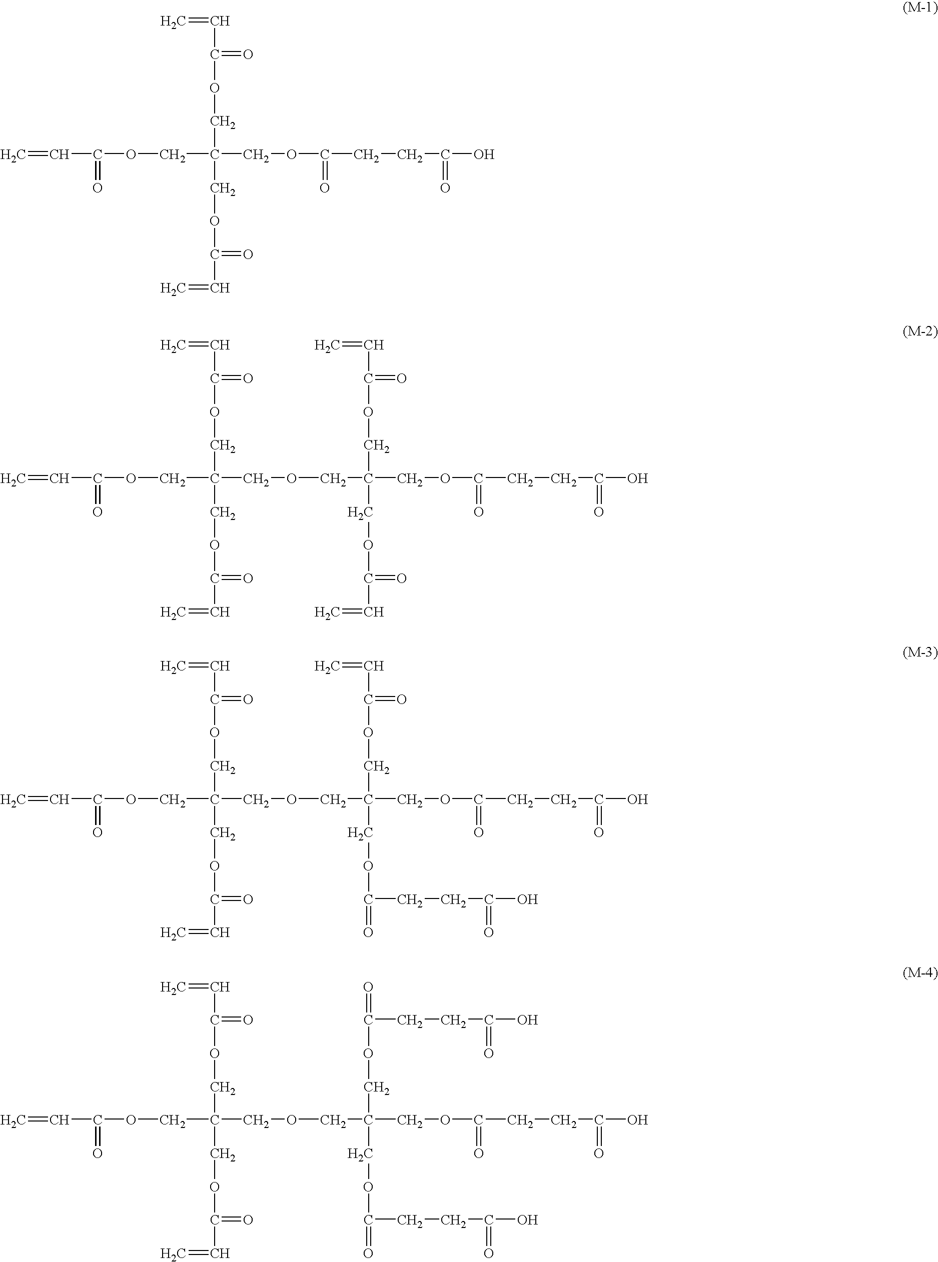

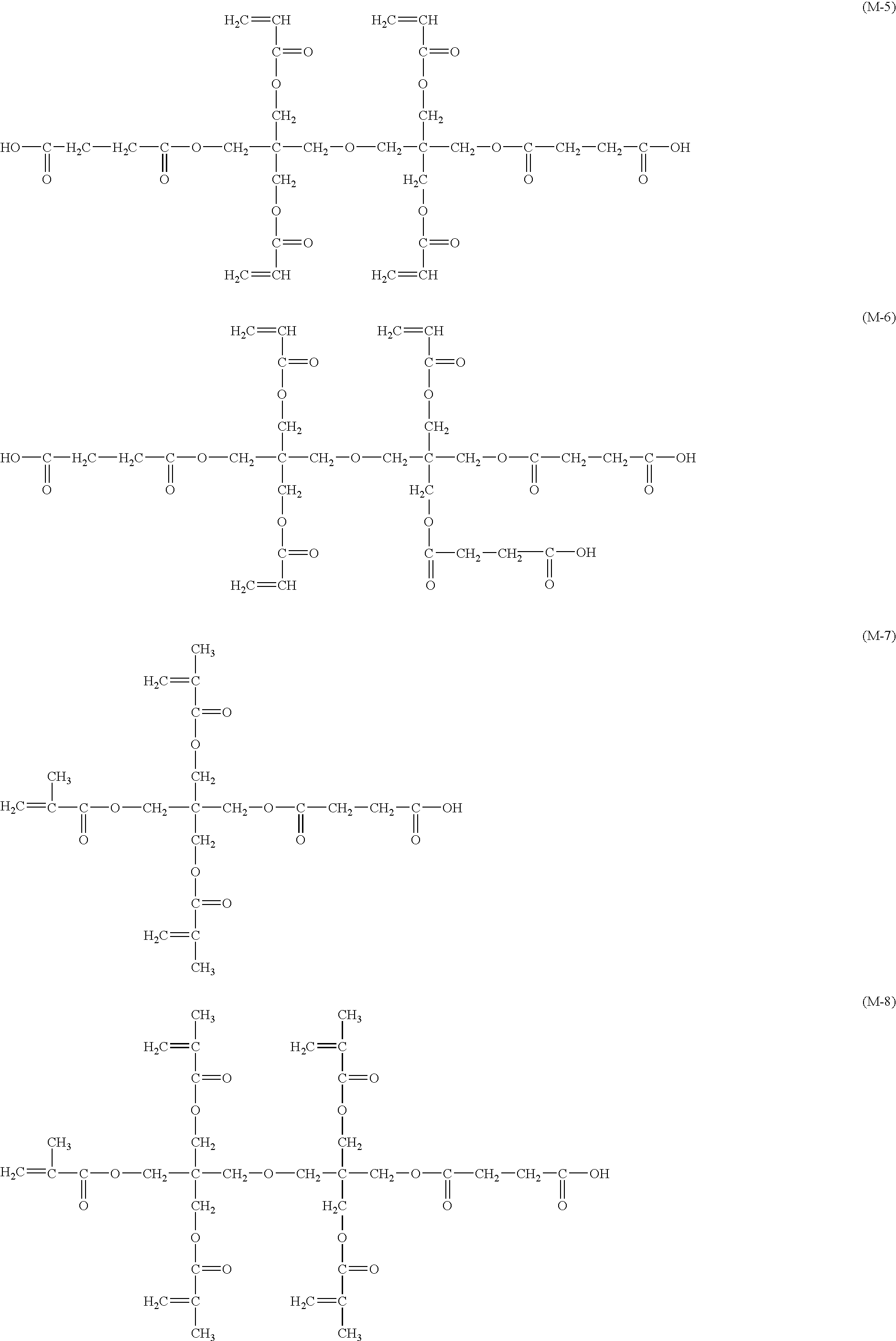

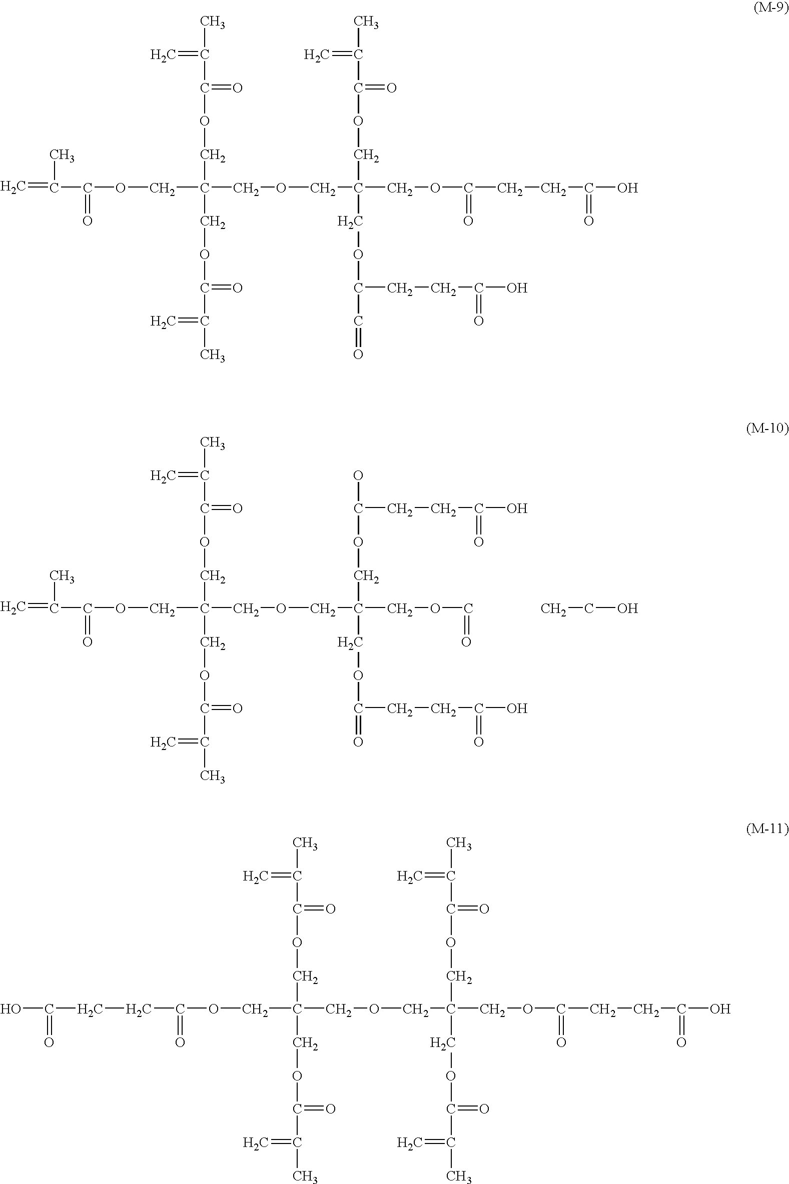

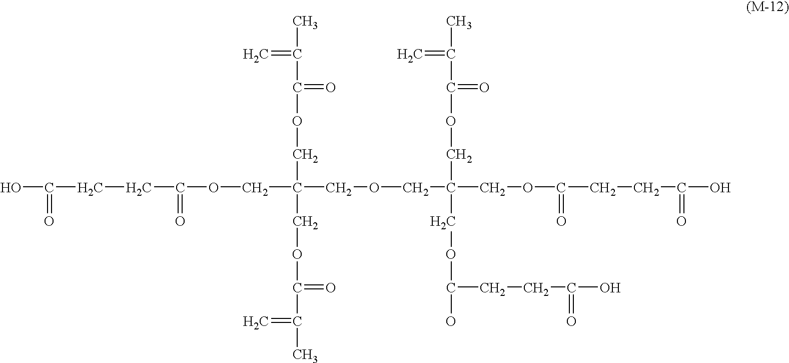

The content of the radical polymerizable monomer(s) in the solid matter of the negative curable dye-containing composition is preferably 20 mass % or more, more preferably 30 mass % or more, and most preferably 35 mass % or more.

<Alkali-Soluble Binder>

The negative curable dye-containing composition of the invention may contain at least one alkali-soluble binder, if necessary. The alkali-soluble binder is soluble in water or alkali, and otherwise there is no particular limit thereto. The type of the alkali-soluble binder is preferably selected from the viewpoints of heat resistance, developability, and availability thereof.

The alkali-soluble binder is preferably a linear organic high molecular weight polymer that is soluble in an organic solvent and that can be developed with a weak alkaline aqueous solution. The linear organic high molecular polymer is, for example, a polymer having at least one carboxylic acid on at least one side chain thereof such as a methacrylic acid copolymer, an acrylic acid copolymer, an itaconic acid copolymer, a crotonic acid copolymer, a maleic acid copolymer or a partially esterified maleic acid copolymer disclosed in JP-A No. S59-44615, JP-B No. S54-34327, S58-12577, or S54-25957, or JP-A No. S59-53836 or S59-71048, or an acidic cellulose derivative having at least one carboxylic acid on at least one side chain thereof.

In addition to the above-mentioned compounds, a product obtained by adding an acid anhydride to a polymer having hydroxyl groups, polyhydroxystyrene resin, polysiloxane resin, poly(2-hydroxyethyl (meth)acrylate), polyvinyl pyrrolidone, polyethylene oxide, or polyvinyl alcohol is useful as the alkali-soluble binder.

Moreover, the alkali-soluble binder may be a copolymer whose raw materials include at least one hydrophilic monomer. Examples of the hydrophilic monomer include alkoxyalkyl (meth)acrylate, hydroxyalkyl (meth)acrylate, glycerol (meth)acrylate, (meth)acrylamide, N-methylolacrylamide, secondary-or tertiary-alkylacrylamides, dialkylaminoalkyl (meth)acrylate, morpholin (meth)acrylate, N-vinylpyrrolidone, N-vinylcaprolactam, vinylimidazole, vinyltriazole, methyl (meth)acrylate, ethyl (meth)acrylate, branched or n-propyl (meth)acrylate, branched or n-butyl (meth)acrylate and phenoxyhydroxypropyl (meth)acrylate.

Alternatively, a monomer having a tetrahydrofurfuryl group, a phosphoric group, a phosphate group, a quaternary ammonium salt, an ethyleneoxy chain, a propyleneoxy chain, s sulfonic group, a sulfonate group, or a morpholinoethyl group is also useful as the hydrophilic monomer.

Moreover, in order to improve the cross-linking efficiency of the polymer, the alkali-soluble binder may have at least one polymerizable group in at least one side chain thereof, and, for example, polymers having at least one allyl group, at least one (meth)acrylic group and/or at least one allyloxyalkyl group in at least one side chain thereof are useful as such. Examples of the polymer having at least one polymerizable group include KS resist-106 manufactured by Osaka Organic Chemical Industry Ltd. and CYCLOMER P Series available from Daicel Chemical Industries, Ltd. Furthermore, in order to increase the strength of the cured coating film, alcohol-soluble nylon, and polyether of 2,2-bis-(4-hydroxyphenyl)-propane and epichlorohydrin are also useful.

Among those, the alkali-soluble binder is preferably polyhydroxystyrene resin, polysiloxane resin, acrylic resin, acrylamide resin or acrylic acid/acrylamide copolymer resin from the viewpoint of heat resistance. Moreover, the alkali-soluble binder is preferably acrylic resin, acrylamide resin or acrylic acid/acrylamide copolymer resin to severely control developability of the binder.

Examples of the acrylic resin include copolymers whose raw materials include at least one monomer selected from benzyl (meth)acrylate, (meth)acrylic acid, hydroxyethyl (meth)acrylate and (meth)acrylic amide, KS RESIST-106 manufactured by Osaka Organic Chemical Industry Ltd., and CYCLOMER P series available from Daicel Chemical Industries, Ltd.

The weight-average molecular weight, measured by GPC method using polystyrene standard, of the alkali-soluble binder is preferably 1,000 to 2×10⁵, more preferably 2,000 to 1×10⁵, and most preferably 5,000 to 5×10⁴.

The content of the alkali-soluble binder(s) in the solid matter of the negative curable dye-containing composition is preferably 0 to 50% by mass, more preferably 0 to 30% by mass, and most preferably 0 to 10% by mass.

Cross-Linking Agent

The negative curable dye-containing composition of the invention may further contain at least one cross-linking agent to enable formation of a film that has been more highly cured. Hereinafter, the cross-linking agent will be explained in detail.

The cross-linking agent usable in the invention allows film curing due to cross-linking reaction and otherwise there is no particular limit thereto. Examples thereof include (a) epoxy compounds; (b) melamine compounds, guanamine compounds, glycoluryl compounds and urea compounds each having at least one substituent selected from a methylol group, an alkoxymethyl group and an acyloxymethyl group (cross-linking agent (b)); and (c) phenol compounds, naphthol compounds and hydroxyanthracenes each having at least one substituent selected from a methylol group, an alkoxymethyl group and an acyloxymethyl group (cross-linking agent (c)). Among these, the cross-linking agent is preferably a polyfunctional epoxy compound.

The epoxy compound (a) has at least one epoxy group and a cross-linking property, and otherwise there is no particular limit thereto. Examples thereof include divalent glycidyl group-containing low molecular compounds, such as bisphenol A diglycidyl ether, ethylene glycol diglycidyl ether, butanediol diglycidyl ether, hexanediol diglycidyl ether, dihydroxybiphenyl diglycidyl ether, diglycidyl phthalate and N,N-diglycidylaniline; trivalent glycidyl group-containing low molecular compounds, such as trimethylolpropane triglycidyl ether, trimethylolphenol triglycidyl ether, and TrisP-PA triglycidyl eter; tetravalent glycidyl group-containing low molecular compounds, such as pentaerythritol tetraglycidyl ether and tetramethylolbisphenol A tetraglycidyl ether; polyvalent glycidyl group-containing low molecular compounds, such as dipentaerythritol pentaglycidyl ether and dipentaerythritol hexaglycidyl ether; and glycidyl group-containing polymer compounds, such as polyglycidyl (meth)acrylate and an adduct obtained by adding 1,2-epoxy-4-(2-oxiranyl)cyclohexane to 2,2-bis(hydroxymethyl)-1-butanol.

The number of methylol groups, alkoxymethyl groups and/or acyloxymethyl groups in the cross-linking agent (b) is preferably 2 to 6 in the case of a melamine compound, and 2 to 4 in the case of a glycoluryl compound, a guanamine compound or an urea compound. More preferably, the number is 5 to 6 in the case of a melamine compound, and 3 to 4 in the case of a glycoluryl compound, a guanamine compound or an urea compound.

A methylol group-containing compound serving as the cross-linking agent (b) can be obtained by heating an alkoxymethyl group-containing compound serving as the cross-linking agent (b) in alcohol in the presence of an acidic catalyst such as hydrochloric acid, sulfuric acid, nitric acid, or methanesulfonic acid. An acyloxymethyl group-containing compound serving as the cross-linking agent (b) can be obtained by mixing the methylol group-containing compound with acyl chloride in the presence of a basic catalyst.

Specific examples of the cross-linking agent (b) include the following compounds.

Examples of the melamine compound include hexamethylolmelarnine, hexamethoxymethylmelamine, compounds obtained by methoxy-methylating 1 to 5 methylol groups of hexamethylolmelamine and mixtures thereof, hexamethoxyethylmelamine, hexaacyloxymethylmelamine, and compounds obtained by acyloxy-methylating 1 to 5 methylol groups of hexamethylolmelamine and mixtures thereof.

Examples of the guanamine compound include tetramethylolguanamine, tetramethoxymethylguanamine, compounds obtained by methoxy-methylating 1 to 3 methylol groups of tetramethylolguanamine and mixtures thereof, tetramethoxyethylguanamine, tetraacyloxymethylguanamine, and compounds obtained by acyloxy-methylating 1 to 3 methylol groups of tetramethylolguanamine and mixtures thereof.

Examples of the glycoluryl compound include tetramethylolglycoluryl, tetramethoxymethylglycoluryl, compounds obtained by methoxy-methylating 1 to 3 methylol groups of tetramethylolglycoluryl and mixtures thereof, and compounds obtained by acyloxy-methylating 1 to 3 methylol groups of tetramethylolglycoluryl and mixtures thereof.

Examples of the urea compound include tetramethylolurea, tetramethoxymethylurea, compounds obtained by methoxy-methylating 1 to 3 methylol groups of tetramethylolurea and mixtures thereof, and tetramethoxyethylurea.

One of those cross-linking agents (b) may be used alone, or two or more of them may be used together.

The aforementioned cross-linking agent (c), that is, a phenol compound, a naphthol compound or a hydroxyanthracene compound having at least one substituent selected from a methylol group, an alkoxymethyl group and an acyloxymethyl group, makes it possible to prevent inter-mixing between a layer containing the cross-linking agent and an uppercoat photoresist due to thermal cross-linking, and to further improve a film strength, as in the cross-linking agent (b).

It is necessary that the cross-linking agent (c) has at least two substituents selected from methylol, acyloxymethyl, and alkoxymethyl groups in the molecule. From the viewpoints of thermal cross-linking property and storage stability, the phenol compound preferably has the substituents at 2- and 4-positions. Moreover, the naphthol and hydroxyanthracene compounds preferably have the substituents at all ortho- and para-positions with respect to the OH group. The phenol compound may or may not have a substituent at 3- or 5-position.

The naphthol compound may or may not have a substituent or substituents at positions other than the ortho positions with respect to the OH group.

A methylol group-containing compound serving as the cross-linking agent (c) can be obtained by reacting a compound having a hydrogen atom at 2- or 4-position with respect to a phenolic OH group and serving as a raw material with formalin in the presence of a basic catalyst, such as sodium hydroxide, potassium hydroxide, ammonia, or tetraalkyl ammonium hydroxide.

An alkoxymethyl group-containing compound serving as the cross-linking agent (c) may be obtained by heating the methylol group-containing compound in alcohol in the presence of an acidic catalyst such as hydrochloric acid, sulfuric acid, nitric acid, or methanesulfonic acid.

An acyloxymethyl group-containing compound serving as the cross-linking agent (c) may be obtained by reacting the methylol group-containing compound with acyl chloride in the presence of a basic catalyst.

Examples of the basic skeleton compound of the cross-linking agent (c) include a phenol compound, a naphthol compound and a hydroxyanthracene compound each having no substituent at the ortho- or para-position with respect to the phenolic OH group. Specific examples thereof include phenol, isomers of cresol, 2,3-xylenol, 2,5-xylenol, 3,4-xylenol, 3,5-xylenol, bisphenols such as bisphenol A, 4,4′-bishydroxybiphenyl, Tris P-PA manufactured by Honshu Chemical Industry Co., Ltd., naphthol, dihydroxynaphthalene and 2,7-dihydroxyanthracene.

Examples of the cross-linking agent (c) include trimethylolphenol, tri(methoxymethyl)phenol, compounds obtained by methoxy-methylating 1 to 2 methylol groups of trimethylolphenol, trimethylol-3-cresol, tri(methoxymethyl)-3-cresol, compounds obtained by methoxy-methylating 1 to 2 methylol groups of trimethylol-3-cresol, dimethylol cresol such as 2,6-dimethylol-4-cresol, tetramethylolbisphenol A, tetramethoxymethylbisphenol A, compounds obtained by methoxy-methylating 1 to 3 methylol groups of tetramethylolbisphenol A, tetramethylol-4,4′-bishydroxybiphenyl, tetramethoxymethyl-4,4′-bishydroxybiphenyl, a hexamethylol compound of Tris P-PA, a hexamethoxymethyl compound of Tris P-PA, compounds obtained by methoxy-methylating 1 to 5 methylol groups of the hexamethylol compound of Tris P-PA, and bishydroxymethylnaphthalenediol.

The hydroxyanthracene compound is, for example, 1,6-dihydroxymethyl-2,7-dihydroxyanthracene. Examples of the acyloxymethyl group-containing compound include compounds obtained by acyloxy-methylating a part or all of the methylol groups of the aforementioned methylol group-containing compounds.

Among those compounds, the cross-linking agent (c) is preferably trimethylolphenol, bishydroxymethyl-p-cresol, tetramethylolbisphenol A, a hexamethylol compound of Tris P-PA manufactured by Honshu Chemical Industry Co., Ltd. or a phenol compound obtained by changing a part or all of the methylol groups of these compounds to alkoxymethyl groups.

One of those cross-linking agents (c) may be used alone, or two or more of them can be used together.

A desired content of the cross-linking agent(s) in the solid matter of the negative curable dye-containing composition of the invention depends on the type(s) of the cross-linking agent(s). However, the content of the cross-linking agent(s) in the solid matter of the negative curable dye-containing composition is preferably 1 to 70 mass %, more preferably 5 to 50 mass %, and most preferably 7 to 30 mass %.

<Thermal Photopolymerization Inhibitor>

The negative curable dye-containing composition of the invention preferably contains at least one thermal polymerization inhibitor. Examples thereof include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and 2-mercaptobenzimidazole.

<Solvent>

The negative curable dye-containing composition of the invention generally contains at least one solvent. The type of the solvent is so selected as to obtain good solubility of each of the other components and the application property of the negative curable dye-containing composition, and otherwise there is no particular limit to the solvent. It is preferable to select the type of the solvent in consideration of, especially, the solubility, the application property and safety of each of the dye(s) and the binder(s).

Typical examples of the solvent include esters, such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, and ethyl ethoxyacetate; alkyl 3-oxypropionates, such as methyl 3-oxypropionate, ethyl 3-oxypropionate, methyl 3-methoxypropionate, ethyl 3-methoxypropionate, methyl 3-ethoxypropionate, ethyl 3-ethoxypropionate; alkyl 2-oxypropionates, such as methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate; methyl pyruvate, ethyl pyruvate, propyl pyruvate, methyl acetoacetate, ethyl acetoacetate, methyl 2-oxobutanate, and ethyl 2-oxobutanate; ethers, such as diethylene glycol dimethyl ether, tetrahydrofuran, ethylene glycol monomethyl ether, ethylene glycol monoethyl ether, methylcellosolve acetate, ethylcellosolve acetate, diethylene glycol monomethyl ether, diethylene glycol monoethyl ether, diethylene glycol monobutyl ether, propylene glycol methyl ether, propylene glycol methyl ether acetate, propylene glycol ethyl ether acetate, and propylene glycol propyl ether acetate; ketones, such as methyl ethyl ketone, cyclohexanone, cyclopentanone, 2-heptanone, 3-heptanone; and aromatic hydrocarbons, such as toluene and xylene.

Among them, the solvent is preferably methyl 3-ethoxypropionate, ethyl 3-ethoxypropionate, ethylcellosolve acetate, ethyl lactate, diethylene glycol dimethyl ether, butyl acetate, methyl 3-methoxypropionate, 2-heptanone, cyclohexanone, cyclopentanone, ethylcarbitol acetate, butylcarbitol acetate, propylene glycol methyl ether, or prolylene glycol methyl ether acetate.

<Various Additives>

The negative curable dye-containing composition of the invention may contain other additive(s) such as at least one filler, at least one polymer compound other than those aforementioned, at least one surfactant, at least one adhesion accelerating agent, at least one antioxidant, at least one ultraviolet ray absorbent, and/or at least one agglomeration preventive agent, if necessary.

Specific examples of the filler include glass and alumina. Specific examples of the polymer compound other than the binder polymer include polyvinyl alcohol, polyacrylic acid, polyethylene glycol monoalkyl ether, and polyfluoroalkyl acrylate. The surfactant may be nonionic, cationic or anionic. Specific examples of the adhesion accelerating agent include vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, and 3-mercaptopropyltrimethoxysilane. Specific examples of the antioxidant include 2,2-thiobis(4-methyl-6-t-butylphenol), and 2,6-di-t-butylphenol. Specific examples of the ultraviolet ray absorbent include 2-(3-t-butyl-5-methyl-2-hydroxyphenyl)-5-chlorobenzotriazole, and alkoxybenzophenone. The agglomeration preventing agent may be sodium polyacrylate.

The negative curable dye-containing composition of the invention may further contain at least one organic carboxylic acid, which preferably has low molecular weight of 1,000 or less, to accelerate dissolution of non-image portions in alkali and further improve the developing property of the negative curable dye-containing composition.

Specific examples thereof include aliphatic monocarboxylic acid, such as formic acid, acetic acid, propionic acid, butyric acid, valeric acid, pivalic acid, caproic acid, diethylacetic acid, enanthic acid, and caprylic acid; aliphatic dicarboxylic acid, such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; aliphatic tricarboxylic acid, such as tricarballylic acid, aconitic acid, and camphoronic acid; aromatic monocarboxylic acid, such as benzoic acid, toluic acid, cuminic acid, hemellitic acid, and mesitylenic acid; aromatic polycarboxylic acid, such as phthalic acid, isophthalic acid, terephthalic acid, trimellitic acid, trimesic acid, mellophanic acid, and pyromellitic acid; and other carboxylic acid, such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid, and umbellic acid.

<<Color Filter and Manufacturing Method Thereof>>

The color filter of the invention will be explained in detail below, together with the manufacturing method thereof.

In the method for manufacturing a color filter of the invention, the negative curable dye-containing composition described above is used.

Firstly, the negative curable dye-containing composition of the invention is applied onto a support by a coating method such as a rotation coating method, a flow coating method, or a roller coating method to form a radiation-sensitive composition layer. Secondly, the layer is exposed to light through a predetermined mask pattern, and developed with a developing solution. Thus, a negative colored pattern is formed (image-forming step). The method may further include a curing step, in which the colored pattern is heated and/or exposed to light to cure the pattern, if necessary.

In manufacturing a color filter, a color filter having desired hues can be produced by conducting (repeating) the image-forming step (and, if necessary, curing step) for each color hue. Ultraviolet rays such as g-rays, h-rays or i-rays are preferably used as the light or radiation.

Examples of the the material of the support include soda glass, PYREX (Registered Mark) glass, quartz glass, and those having a transparent conductive film on these glass layers, which may be used in liquid crystal display devices, photoelectric transfer device substrates used in image pickup devices, such as silicon substrates, and complementary metal oxide film semiconductors (CMOS). In some cases, such a substrate may have thereon a black stripe that is used to separate each pixel.

In order to improve the adhesion between the support and a layer adjacent to the support, to prevent diffusion of a substance, and/or to flatten the substrate surface, an undercoat layer may be formed on the support, if necessary.

The developeing solution dissolves uncured portions of the negative curable dye-containing composition of the invention without dissolving cured portions of the composition, and otherwise there is no particular limit thereto. Specific examples thereof include various combinations of organic solvents and alkaline aqueous solutions. Examples of the organic solvent include those of the solvent containable in the negative curable dye-containing composition of the invention.

The alkaline aqueous solution is preferably a solution in which at least one alkaline compound such as sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, choline, pyrrole, piperidine, or 1,8-diazabicyclo[5.4.0]-7-undecene is dissolved in water. The concentration of the alkaline compound(s) in the alkaline solution is generally 0.001 to 10% by mass, and preferably 0.01 to 1% by mass. When the developing solution is such an alkaline aqueous solution, the color filter is, in general, washed with water after the development.

The color filter of the invention can be used in liquid crystal display devices and solid-state image pickup devices such as CCDS, and is preferably used in CCD elements and CMOS which have a high degree of resolution exceeding 1,000,000 pixels. The color filter of the invention may be used as a color filter placed between the light-receiving unit of each of the pixels of CCDs and a microlens used to condense light.

### EXAMPLES

The invention is described in detail below while referring to examples. However, the invention is not limited thereto. In the examples, the term “part” means “part by mass”, unless otherwise indicated.

### Example 1

1) Preparation of Resist Solution

A resist solution was prepared by sufficiently mixing the following components.

| | |
|---|---|
| propylene glycol monomethyl ether acetate (PGMEA) | 19.20 parts |
| ethyl lactate | 36.67 parts |
| resin | 30.51 parts |
| [41% PGMEA solution of benzyl methacrylate/ | |
| methacrylic acid/2-hydroxyethyl methacrylate | |
| copolymer (molar rate of those monomers being | |
| 60:20:20)] | |
| dipentaerythritol hexaacrylate | 12.20 parts |
| (photopolymerizable compound) | |
| polymerization inhibitor (p-methoxyphenyl) | 0.0061 parts |
| fluorinated surfactant (F-475 manufactured by Dainippon | 0.83 parts |
| Ink Chemical Industries) | |
| photopolymerization initiator (TAZ-107 | 0.586 parts |
| (trihalomethyltriazine compound manufactured | |
| by Midori Kagaku Co., Ltd.) | |

2) Preparation of Silicon Substrate with Undercoat Layer

A silicon wafer with a square area having an edge length of 6 inch was heated in an oven at 200° C. for 30 minutes or more. The resist solution was applied to the silicon wafer, and the silicon wafer was heated and dried in the oven at 220° C. for one hour to form an undercoat layer having a dry thickness of 2 μm. Thus, a silicon substrate with an undercoat layer was obtained.

3) Preparation of Colored Photosensitive Resin Composition

The compounds of the following composition A-1 were sufficiently mixed to prepare a colored photosensitive resin composition A-1.

<Composition A-1>

| | |
|---|---|
| cyclohexanone | 80 parts |
| alkali-soluble binder | 1.2 parts |
| (benzyl methacrylate/methacrylic acid copolymer (molar ratio | |
| of those monomers of 70/30 [molar ratio], and Mw of 30,000) | |
| phthalocyanine dye soluble in organic solvent | 6.0 parts |
| (exemplary compound C-1) | |
| organic solvent-soluble dye (a) shown below | 4.0 parts |
| mixture of exemplary compound (M-2) of radical | 5.8 parts |
| polymerizable monomer and dipentaerythritol | |
| hexaacrylate at a molar ratio of 3:7 | |
| photopolymerization initiator | 2.5 parts |
| (CGI-242 manufactured by Ciba Specialty Chemicals) | |
| tributylamine (amine compound in the invention) | 0.5 parts |

4) Exposure, development, and evaluation of colored photosensitive resin composition

The colored photosensitive resin composition A-1 was applied to the undercoat layer formed on the silicon wafer substrate to prepare a photocurable coating film. The coating film was heated (prebaked) with a hot plate kept at 100° C. for 120 seconds, so that the dry thickness of the coating film became 0.8 μm. The entire surface of the coating film was exposed to light emitted by an exposure device and having a wavelength of 365 nm at an exposure amount of 2000 mJ/cm². The thickness of the exposed coating film was measured with a film thickness mesurring device having a stylus, or DEKTAK 6M manufactured by Veeco Instruments. The colored photosensitive resin composition A-1 was then stored at room temperature for 1 month. Another coating film was prepared by using the stored composition, heated and exposed to light, and the thickness thereof was measured in the same manner as the above. The change ratio (%) of the thickness of the coating film formed by using the composition after the storage (excluding the thickness of the undercoat) to the thickness of the coating film formed by using the composition before the storage (excluding the thickness of the undercoat) was calculated (B/A×100), and the change ratio was used as an index to evaluate film thickening suppression over time. The results are shown in Table 1.

### Examples 2 to 10 and Comparative Example 1

Colored photosensitive resin compositions A-2 to A-11 were prepared, coating films were prepared, and thickening suppression of each of the coating films was evaluated in the same manner as in Example 1, except that at least one of the phthalocyanine dye soluble in an organic solvent, the dye soluble in an organic solvent, and the amine compound in the invention used in the colored photosensitive resin composition A-1 were changed as shown in Table 1. The results are shown in Table 1.

TABLE 1

| | | | | Amine | Film |
|---|---|---|---|---|---|
| | | Phthalocyanine | Dye soluble | compound/ | thickness |
| | | dye soluble in | in organic | pyridine | change rate |
| | Composition | organic solvent | solvent | compound | (%) |
| Example 1 | A-1 | C-1 | a | Tributylamine | 100 |
| Example 2 | A-2 | C-2 | b | Dicyclohexyl | 103 |
| | | | | amine | |
| Example 3 | A-3 | C-10 | a | N-ethyl | 100 |
| | | | | dicyclohexyl | |
| | | | | amine | |
| Example 4 | A-4 | C-14 | b | Cyclohexyl | 105 |
| | | | | amine | |
| Example 5 | A-5 | C-45 | a | Picolinic acid | 100 |
| Example 6 | A-6 | 1 | c | Nicotinic acid | 104 |
| Example 7 | A-7 | 21 | d | 4-phenyl | 100 |
| | | | | morpholine | |
| Example 8 | A-8 | 28 | d | N-butyl | 102 |
| | | | | aniline | |
| Example 9 | A-9 | C.I. Acid Blue | c | 4-t-butyl | 104 |
| | | 249 | | aniline | |
| Example 10 | A-10 | C.I. Acid Blue | d | Isoleucine | 105 |
| | | 249 | | | |
| Comparative | A-11 | C.I. Acid Blue | d | None | 125 |
| Example 1 | | 249 | | | |

Note)
Compounds in the column of “phthalocyanine dye soluble in organic solvent” (except C.I. Acid Blue 249) are aforementioned exemplary compounds or specific examples.
Compounds in the column of “dye soluble in organic solvent” are the following compounds.
The dyes soluble in an organic solvent a to d used in Examples and Comparative Example are shown below.

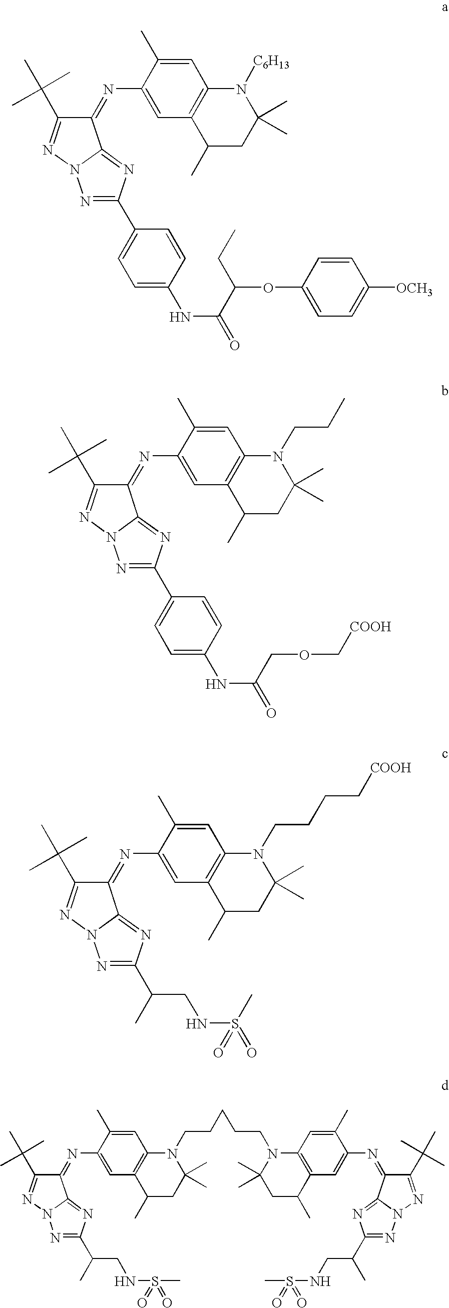

Silicon wafer substrates with an undercoat layer were prepared in the same manner as in Example 1. The colored photosensitive resin compositions prepared in Examples 1 to 10 were stored for one month, and then applied to the undercoat layer formed on the silicon wafer to prepare photocurable coating films. The films were heated (prebaked) with a hot plate kept at 100° C. for 120 seconds, so that the dry thickness of each of the coating films became 0.8 μm. The dried coating films were exposed to light emitted by an i-ray stepper exposure device FPA-3000i5+ manufactured by Canon and having a wavelength of 365 nm through an Island pattern mask for yellow with square openeings having an edge length of 2 μm at an exposure amount within the range of 40 to 520 mJ/cm². The silicon wafer substrates on each of which the exposed coating film was disposed was placed on the horizontal turntable of a spin shower developing machine (DW-30 manufactured by Chemitronics), and developed by a paddle method for 60 seconds at 23° C. to form a colored pattern on each of the silicon wafer substrates. In the development, CD-2000 (manufactured by Fuji Film Electronics Materials) was used.

The colored photosensitive resin composition prepared in Comparative Example 1 was stored, and a coating film was formed in the same manner as the above. However, the coating film could not be developed, and therefore a colored pattern could not be formed.

What is claimed is:

1. A negative curable dye-containing composition comprising at least one compound selected from amine and pyridine compounds, a phthalocyanine dye soluble in an organic solvent, a photopolymerization initiator, and a radical polymerizable monomer.

2. The negative curable dye-containing composition of claim 1, wherein the at least one compound has a molecular weight of from 85 to 500.

3. The negative curable dye-containing composition of claim 1, wherein the at least one compound contains at least one of tertiary aniline and aliphatic tertiary amine compounds.

4. The negative curable dye-containing composition of claim 1, wherein the at least one compound contains a pyridine compound having a substituent at 2-position.

5. The negative curable dye-containing composition of claim 1, wherein the content of at the least one compound in the solid matter of the negative curable dye-containing composition is from 0.05 to 10.0 mass %.

6. The negative curable dye-containing composition of claim 1, wherein the phthalocyanine dye soluble in an organic solvent is copper phthalocyanine.

7. The negative curable dye-containing composition of claim 1, wherein the phthalocyanine dye soluble in an organic solvent is represented by Formula (I): 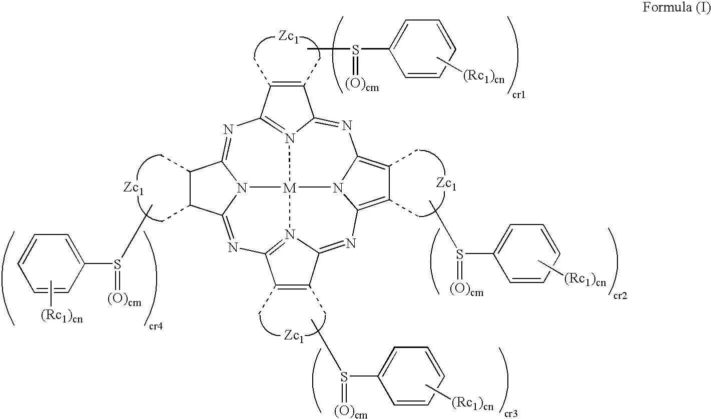
wherein, in formula (I), Rc₁ is a halogen atom, an aliphatic group, an aryl group, a hetero cyclic group, a cyano group, a carboxyl group, a carbamoyl group, an aliphatic oxycarbonyl group, an aryloxycarbonyl group, an acyl group, a hydroxy group, an aliphatic oxy group, an aryloxy group, an acyloxy group, a carbamoyloxy group, a hetero cyclic oxy group, an aliphatic oxycarbonyloxy group, an N-alkylacylamino group, a carbamoylamino group, a sulfamoylamino group, an aliphatic oxycarbonylamino group, an aryloxycarbonylamino group, an aliphatic sulfonylamino group, an arylsulfonylamino group, an aliphatic thio group, an arylthio group, an aliphatic sulfonyl group, an arylsulfonyl group, a sulfamoyl group, a sulfo group, an imide group, or a hetero cyclic thio group; Zc₁ denotes a nonmetallic atomic group that, together with carbon atoms, form a six-membered ring and four Zc₁s may be the same or different; M denotes two hydrogen atoms, a divalent metal atom, a divalent metal oxide, a divalent metal hydroxide, or a divalent metal chloride; cm is 0, 1 or 2; cn is 0 or an integer of 1 to 5 and four cns may be the same or different, provided one of cns is an integer of 1 to 5 and plural Rc₁s, if any, in a molecule may be the same or different; and each of cr1, cr2, cr3, and cr4 represents 0 or 1, provided a relation of cr1+cr2+cr3+cr4≧1 is satisfied.

8. The negative curable dye-containing composition of claim 1, wherein the phthalocyanine dye soluble in an organic solvent is represented by Formula (II): 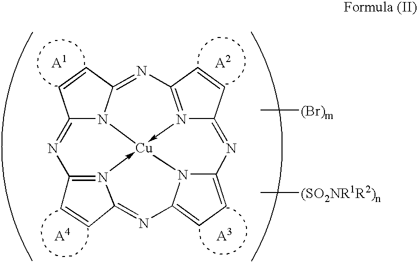
wherein, in formula (II), ring A¹, ring A², ring A³, and ring A⁴ represent independently the following aromatic ring; 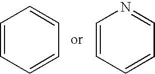
at least one of ring A¹, ring A², ring A³, and ring A⁴ represents the following aromatic ring; and 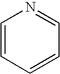
R¹ and R² independently a hydrogen atom or a substituted or unsubstituted alkyl group, m is an integer of 1 to 8, and n is an integer of 1 to 4, provided R¹ and R² do not both represent a hydrogen atom.

9. The negative curable dye-containing composition of claim 1, wherein the content of the phthalocyanine dye soluble in an organic solvent in the solid matter of the negative curable dye-containing composition is from 25.0 to 70.0 mass %.

10. The negative curable dye-containing composition containing a dye of claim 1, wherein the content of the radical polymerizable monomer in the solid matter of the negative curable dye-containing composition is from 20.0 to 50.0 mass %.

11. A color filter comprising a layer obtained by using the negative curable dye-containing composition of claim 1.

12. A method for manufacturing a color filter, comprising applying the negative curable dye-containing composition of claim 1 onto a support to form a coating, exposing the coating to light through a mask, and developing the coating to form a pattern.

13. The method of claim 12, further comprising curing the pattern by heating and/or light exposing.

14. The method of claim 12, wherein the applying, exposing and developing are repeated for a desired number of hues by changing the phthalocyanine dye soluble in an organic solvent and contained in the negative curable dye-containing composition.

15. The method of claim 13, wherein the applying, exposing and developing are repeated for a desired number of hues by changing the phthalocyanine dye soluble in an organic solvent and contained in the negative curable dye-containing composition.
